(19) United States
(12) Patent Application Publication
(10) Pub. No.: US 2015/0025239 A1
(43) Pub. Date: Jan. 22, 2015

(54) NOVEL ORGANIC ELECTROLUMINESCENT COMPOUNDS AND ORGANIC ELECTROLUMINESCENT DEVICE USING THE SAME

(71) Applicants: Hee-Choon Ahn, Suwon-si (KR); Hyo-Jung Lee, Hwaseong-si (KR); Mi-Ja Lee, Hwaseong-si (KR); Soo-Jin Yang, Hwaseong-si (KR); Chi-Sik Kim, Hwaseong-si (KR); Su-Hyun Lee, Suwon-si (KR); Hee-Sook Kim, Suwon-si (KR); Hyo-Nim Shin, Seongnam-si (KR); Kyoung-Jin Park, Seongnam-si (KR); Kyung-Joo Lee, Mapo-gu (KR); Hyuck-Joo Kwon, Gangnam-gu (KR); Bong-Ok Kim, Gangnam-gu (KR)

(72) Inventors: Hee-Choon Ahn, Suwon-si (KR); Hyo-Jung Lee, Hwaseong-si (KR); Mi-Ja Lee, Hwaseong-si (KR); Soo-Jin Yang, Hwaseong-si (KR); Chi-Sik Kim, Hwaseong-si (KR); Su-Hyun Lee, Suwon-si (KR); Hee-Sook Kim, Suwon-si (KR); Hyo-Nim Shin, Seongnam-si (KR); Kyoung-Jin Park, Seongnam-si (KR); Kyung-Joo Lee, Mapo-gu (KR); Hyuck-Joo Kwon, Gangnam-gu (KR); Bong-Ok Kim, Gangnam-gu (KR)

(21) Appl. No.: 14/379,493

(22) PCT Filed: Feb. 14, 2013
(86) PCT No.: PCT/KR2013/001162

§ 371 Date: Aug. 18, 2014

(30) Foreign Application Priority Data
Feb. 17, 2012 (KR) 10-2012-0016159

(51) Int. Cl. H01L 51/00

(52) U.S. Cl. CPC H01L 51/0067; H01L 51/0072; H01L 51/0074; H01L 51/0071; H01L 51/5012
USPC 544/331; 544/333

(57) ABSTRACT

The present invention relates to a novel organic electroluminescent compound and an organic electroluminescent device comprising the same. The organic electroluminescent compound according to the present invention is better in luminous efficiency and lifespan characteristics compared to conventional materials. Using the compounds of the present invention, it is possible to manufacture an OLED device with a long operational lifespan. In addition, the compounds can improve the power efficiency of the device to reduce overall power consumption.

### TECHNICAL FIELD

The present invention relates to novel organic electroluminescent compounds and organic electroluminescent device using the same.

### BACKGROUND ART

An electroluminescent (EL) device is a self-light-emitting device. When a charge is applied between an anode and a cathode, a hole and an electron are injected from the anode and the cathode, respectively. The hole and the electron are reunited to form an exciton. The EL device emits light corresponding to the wavelength of the energy gap that occurred from the transition of the exciton to a ground state.

The light emission is categorized as fluorescence which is the use of an exciton in a singlet state; and phosphorescence which is the use of an exciton in a triplet state. In view of quantum mechanics, phosphorescent light emitting materials enhance luminous efficiency by about four (4) times compared to fluorescent light emitting materials.

Meanwhile, in the EL device, a luminescent dye (dopant) can be used in combination with a host material as a light emitting material to improve color purity, luminous efficiency, and stability. Since, host materials greatly influence the efficiency and the performance of the EL device when using a host material/dopant system as a light emitting material, their selection is important.

Though the conventional phosphorescent host material such as 4,4-N,N-dicarbazolebiphenyl (CBP) provides a current efficiency higher than fluorescent materials, the driving voltage is high. Thus, there are less advantages in terms of power efficiency. Further, the luminous efficiency and operating lifespan of the device still need improvement.

WO 2009/148015 discloses a compound in which two pentacyclic heteroaryl groups wherein benzofuran is fused to a carbazolyl group, are linked to each other via a pyrimidinylene at the nitrogen position of the carbazolyl structure; and an EL device comprising the compound.

WO 2010/136109 discloses a compound in which two indenocarbazole groups are linked to each other via a heteroarylene group containing a nitrogen atom(s); a compound in which indenocarbazole and carbazole are linked to each other via a heteroarylene group containing a nitrogen atom(s) at each nitrogen position; and EL devices comprising each compound.

However, the above prior art references do not disclose a compound in which a pentacyclic heteroaryl group wherein indene, indole, benzofuran, benzothiophene, or benzosilole is fused to a carbazolyl group; and a tricyclic (hetero)aryl group such as fluorene, carbazole, dibenzofuran, dibenzothiophene, or dibenzosilole is linked to each other via a heteroarylene group containing a nitrogen atom(s), at the nitrogen position of the pentacyclic heteroaryl group, and the carbon position of the tricyclic (hetero)aryl group. In addition, the EL devices comprising the compounds disclosed in the above references still need improvement in aspects of their luminous efficiency, lifespan characteristic, and driving voltage.

### DISCLOSURE OF INVENTION

### Technical Problem

The present invention is accomplished to fulfill the above needs in the field. The objective of the present invention is to provide an organic electroluminescent compound imparting low driving voltage, high luminous and power efficiency, and a long lifespan to a device.

### Solution to Problem

The present inventors found that the objective above is achievable by an organic electroluminescent compound represented by the following formula 1:

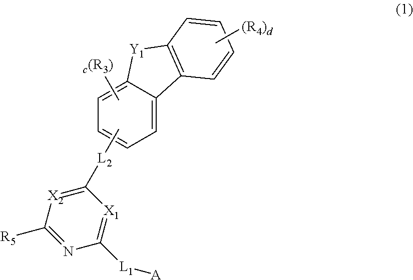

wherein

A represents

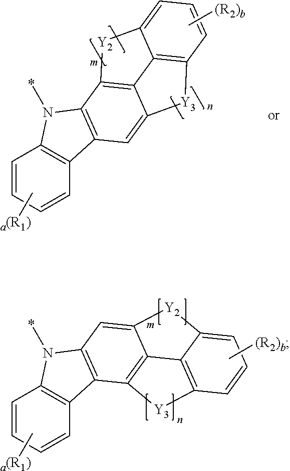

L₁ and L₂ each independently represent a single bond, a substituted or unsubstituted 5- to 30-membered heteroarylene group, or a substituted or unsubstituted (C6-C30)arylene group;

X₁ and X₂ each independently represent CH or N;

Y₁ to Y₃ each independently represent —O—, —S—, —C(R₁₁)(R₁₂)—, —Si(R₁₃)(R₁₄)— or —N(R₁₅)—;

m and n each independently represent 0 or 1; where m+n=1;

R₁ to R₄ each independently represent hydrogen, deuterium, a halogen, a cyano group, a carboxyl group, a nitro group, a hydroxyl group, a substituted or unsubstituted (C1-C30)alkyl group, a substituted or unsubstituted (C2-C30)alkenyl group, a substituted or unsubstituted (C2-C30)alkynyl group, a substituted or unsubstituted (C1-C30)alkoxy group, a substituted or unsubstituted (C3-C30)cycloalkyl group, a substituted or unsubstituted (C3-C30)cycloalkenyl group, a substituted or unsubstituted 3- to 7-membered heterocycloalkyl group, a substituted or unsubstituted (C6-C30)aryl group, a substituted or unsubstituted 5- to 30-membered heteroaryl group, —NR₁₆R₁₇, —SiR₁₈R₁₉R₂₀, —SR₂₁, —OR₂₂, —COR₂₃, or —B(OR₂₄)(OR₂₅);

R₅ represents hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₁₆R₁₇, or —SiR₁₈R₁₉R₂₀;

R₁₁ to R₂₅ each independently represent hydrogen, deuterium, a halogen, a cyano group, a carboxyl group, a nitro group, a hydroxyl group, a substituted or unsubstituted (C1-C30)alkyl group, a substituted or unsubstituted (C2-C30)alkenyl group, a substituted or unsubstituted (C2-C30)alkynyl group, a substituted or unsubstituted (C1-C30)alkoxy group, a substituted or unsubstituted (C3-C30)cycloalkyl group, a substituted or unsubstituted (C3-C30)cycloalkenyl group, a substituted or unsubstituted 3- to 7-membered heterocycloalkyl group, a substituted or unsubstituted (C6-C30)aryl group, or a substituted or unsubstituted 5- to 30-membered heteroaryl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;

a, b and d each independently represent an integer of 1 to 4; where a, b or d is an integer of 2 or more, each of R₁, each of R₂, or each of R₄ may be same or different;

c represents an integer of 1 to 3; where c is an integer of 2 or more, each of R₃ may be same or different;

the heteroarylene group and the heteroaryl group contain at least one hetero atom selected from B, N, O, S, P(═O), Si and P; and

the heterocycloalkyl group contains at least one hetero atom selected from O, S and N.

### Advantageous Effects of Invention

The organic electroluminescent compounds according to the present invention can provide high luminous efficiency and power efficiency, good lifespan characteristics, and low driving voltage. Therefore, using the compounds of the present invention, it is possible to manufacture an OLED device with high current efficiency, long operational lifespan, and low power consumption.

### Mode for the Invention

Hereinafter, the present invention will be described in detail. However, the following description is intended to explain the invention, and is not meant in any way to restrict the scope of the invention.

The present invention relates to an organic electroluminescent compound represented by formula 1, above, an organic electroluminescent material comprising the compound, and an organic electroluminescent device comprising the material.

Hereinafter, the organic electroluminescent compound represented by the above formula 1 will be described in detail.

Herein, “alkyl” includes methyl, ethyl, n-propyl, isopropyl, n-butyl, isobutyl, tert-butyl, etc.; “alkenyl” includes vinyl, 1-propenyl, 2-propenyl, 1-butenyl, 2-butenyl, 3-butenyl, 2-methylbut-2-enyl, etc.; “alkynyl” includes ethynyl, 1-propynyl, 2-propynyl, 1-butynyl, 2-butynyl, 3-butynyl, 1-methylpent-2-ynyl, etc.; “cycloalkyl” includes cyclopropyl, cyclobutyl, cyclopentyl, cyclohexyl, etc.; “3- to 7-membered heterocycloalkyl” is a cycloalkyl having at least one heteroatom selected from B, N, O, S, P(═O), Si and P, preferably O, S and N, and 5 to 7 ring backbone atoms, and includes tetrahydrofuran, pyrrolidine, thiolan, tetrahydropyran, etc.; “aryl(ene)” is a monocyclic or fused ring derived from an aromatic hydrocarbon, and includes phenyl, biphenyl, terphenyl, naphthyl, binaphthyl, phenyl naphthyl, naphthyl phenyl, fluorenyl, phenyl fluorenyl, benzofluorenyl, dibenzofluorenyl, phenanthrenyl, phenyl phenanthrenyl, anthracenyl, indenyl, indanyl, triphenylenyl, pyrenyl, tetracenyl, perylenyl, chrysenyl, naphthacenyl, fluoranthenyl, etc.; “5- to 30-membered heteroaryl(ene)” is an aryl group having at least one, preferably 1 to 4 heteroatom selected from the group consisting of B, N, O, S, P(═O), Si and P, and 5 to 30 ring backbone atoms; is a monocyclic ring, or a fused ring condensed with at least one benzene ring; may be partially saturated; may be one formed by linking at least one heteroaryl or aryl group to a heteroaryl group via a single bond(s); and includes a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, C, Br and I.

In formula (1) above, A represents

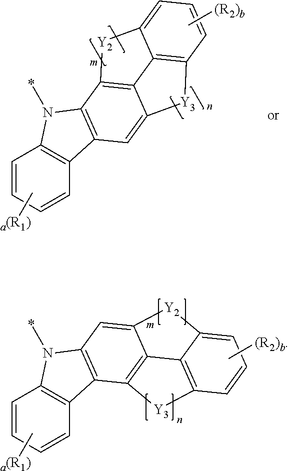

L₁ and L₂ each independently represent a single bond, a substituted or unsubstituted 5- to 30-membered heteroarylene group, or a substituted or unsubstituted (C6-C30)arylene group, preferably each independently represent a single bond, or a substituted or unsubstituted (C6-C20)arylene group, more preferably each independently represent a single bond, or a (C6-C15)arylene group.

X₁ and X₂ each independently represent CH or N.

Y₁ to Y₃ each independently represent —O—, —S—, —C(R₁₁)(R₁₂)—, —Si(R₁₃)(R₁₄)— or —N(R₁₅)—, preferably each independently represent —O—, —S—, —C(R₁₁)(R₁₂)— or —N(R₁₅)—.

m and n each independently represent 0 or 1; where m+n=1.

R₁ to R₄ each independently represent hydrogen, deuterium, a halogen, a cyano group, a carboxyl group, a nitro group, a hydroxyl group, a substituted or unsubstituted (C1-C30)alkyl group, a substituted or unsubstituted (C2-C30)alkenyl group, a substituted or unsubstituted (C2-C30)alkynyl group, a substituted or unsubstituted (C1-C30)alkoxy group, a substituted or unsubstituted (C3-C30)cycloalkyl group, a substituted or unsubstituted (C3-C30)cycloalkenyl group, a substituted or unsubstituted 3- to 7-membered heterocycloalkyl group, a substituted or unsubstituted (C6-C30)aryl group, a substituted or unsubstituted 5- to 30-membered heteroaryl group, —NR₁₆R₁₇, —SiR₁₈R₁₉R₂₀, —SR₂₁, —OR₂₂, —COR₂₃, or —B(OR₂₄)(OR₂₅), preferably each independently represent hydrogen, a substituted or unsubstituted (C6-C20)aryl group, a substituted or unsubstituted 5- to 20-membered heteroaryl group, or —NR₁₆R₁₇, more preferably each independently represent hydrogen, a (C6-C15)aryl group, a 5- to 15-membered heteroaryl group, or —NR₁₆R₁₇.

R₅ represents hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₁₆R₁₇, or —SiR₁₈R₁₉R₂₀, preferably hydrogen, or a substituted or unsubstituted (C6-C20)aryl group, more preferably hydrogen, or a (C6-C15)aryl group unsubstituted or substituted with a halogen or a (C1-C6)alkyl group.

R₁₁ to R₂₅ each independently represent hydrogen, deuterium, a halogen, a cyano group, a carboxyl group, a nitro group, a hydroxyl group, a substituted or unsubstituted (C1-C30)alkyl group, a substituted or unsubstituted (C2-C30)alkenyl group, a substituted or unsubstituted (C2-C30)alkynyl group, a substituted or unsubstituted (C1-C30)alkoxy group, a substituted or unsubstituted (C3-C30)cycloalkyl group, a substituted or unsubstituted (C3-C30)cycloalkenyl group, a substituted or unsubstituted 3- to 7-membered heterocycloalkyl group, a substituted or unsubstituted (C6-C30)aryl group, or a substituted or unsubstituted 5- to 30-membered heteroaryl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur.

Preferably, R₁₁ to R₂₅ each independently represent a substituted or unsubstituted (C1-C10)alkyl group, or a substituted or unsubstituted (C6-C20)aryl group; or are linked to an adjacent substituent(s) to form a mono- or polycyclic, 5- to 20-membered alicyclic or aromatic ring.

More preferably, R₁₁ to R₂₅ each independently represent a (C1-C6)alkyl group; a (C6-C15)aryl group unsubstituted or substituted with deuterium, or are linked to an adjacent substituent(s) to form a mono- or polycyclic, 5- to 15-membered alicyclic or aromatic ring.

According to one embodiment of the present invention in formula (1) above, A represents

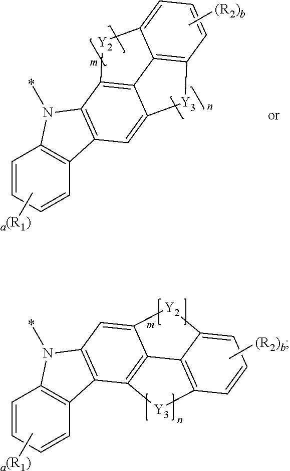

L₁ and L₂ each independently represent a single bond, or a substituted or unsubstituted (C6-C20)arylene group; X₁ and X₂ each independently represent CH or N; Y₁ to Y₃ each independently represent —O—, —S—, —C(R₁₁)(R₁₂)— or —N(R₁₅)—; m and n each independently represent 0 or 1, where m+n=1; R₁ to R₄ each independently represent hydrogen, a substituted or unsubstituted (C6-C20)aryl group, a substituted or unsubstituted 5- to 20-membered heteroaryl group, or —NR₁₆R₁₇; R₅ represents hydrogen, or a substituted or unsubstituted (C6-C20)aryl group; and R₁₁ to R₂₅ each independently represent a substituted or unsubstituted (C1-C10)alkyl group, or a substituted or unsubstituted (C6-C20)aryl group, or are linked to an adjacent substituent(s) to form a mono- or polycyclic, 5- to 20-membered alicyclic or aromatic ring.

According to another embodiment of the present invention in formula (1) above, A represents

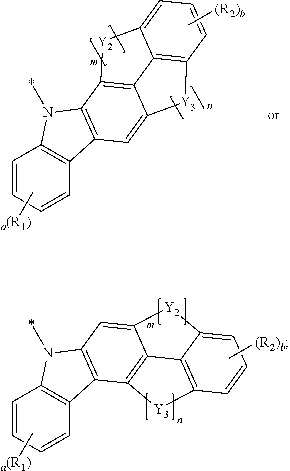

L₁ and L₂ each independently represent a single bond, or a (C6-C15)arylene group; X₁ and X₂ each independently represent CH or N; Y₁ to Y₃ each independently represent —O—, —S—, —C(R₁₁)(R₁₂)— or —N(R₁₅)—; m and n each independently represent 0 or 1, where m+n=1; R₁ to R₄ each independently represent hydrogen, a (C6-C15)aryl group, a 5- to 15-membered heteroaryl group, or —NR₁₆R₁₇; R₅ represents hydrogen, or a (C6-C15)aryl group unsubstituted or substituted with a halogen or a (C1-C6)alkyl group; and R₁₁ to R₂₅ each independently represent a (C1-C6)alkyl group; a (C6-C15)aryl group unsubstituted or substituted with deuterium, or are linked to an adjacent substituent(s) to form a mono- or polycyclic, 5- to 15-membered alicyclic or aromatic ring.

Specifically, in formula (1) above, preferably, L₁ and L₂ each independently represent a single bond, a phenyl group, a biphenyl group, a naphthyl group, a fluorenyl group, a phenanthrenyl group, a pyridyl group, a pyrazinyl group, a pyrimidinyl group, or a pyridazinyl group; Y₁ to Y₃ each independently represent —O—, —S—, —C(R₁₁)(R₁₂)— or —N(R₁₅)—; R₁ to R₄ each independently represent hydrogen, deuterium, a halogen, a substituted or unsubstituted (C1-C30)alkyl group, a substituted or unsubstituted (C3-C30)cycloalkyl group, a substituted or unsubstituted (C6-C30)aryl group, a substituted or unsubstituted 5- to 30-membered heteroaryl group, —NR₁₆R₁₇, or —SiR₁₈R₁₉R₂₀; R₅ represents hydrogen, deuterium, a substituted or unsubstituted (C6-C30)aryl group, or a substituted or unsubstituted 5- to 30-membered heteroaryl group; R₁₁ to R₂₅ each independently represent hydrogen, deuterium, a halogen, a substituted or unsubstituted (C1-C30)alkyl group, a substituted or unsubstituted (C3-C30)cycloalkyl group, a substituted or unsubstituted (C6-C30)aryl group, or a substituted or unsubstituted 5- to 30-membered heteroaryl group; or are linked to an adjacent substituent(s) to form a mono- or polycyclic, 3- to 30-membered alicyclic or aromatic ring.

Herein, “substituted” in the expression “substituted or unsubstituted” means that a hydrogen atom in a certain functional group is replaced with another atom or group, i.e., a substituent.

In L₁, L₂, R₁ to R₅, and R₁₁ to R₂₅, the substituents of the substituted (C1-C30)alkyl group, substituted (C2-C30)alkenyl group, substituted (C2-C30)alkynyl group, substituted (C1-C30)alkoxy group, substituted (C3-C30)cycloalkyl group, substituted (C3-C30)cycloalkenyl group, substituted 3- to 7-membered heterocycloalkyl group, substituted (C6-C30)aryl group, substituted (C6-C30)arylene group, substituted 5- to 30-membered heteroaryl group, and substituted 5- to 30-membered heteroarylene group each independently are at least one selected from the group consisting of deuterium; a halogen; a cyano group; a carboxyl group; a nitro group; a hydroxyl group; a (C1-C30)alkyl group; a halo(C1-C30)alkyl group; a (C2-C30)alkenyl group; a (C2-C30)alkynyl group; a (C1-C30)alkoxy group; a (C1-C30)alkylthio group; a (C3-C30)cycloalkyl group; a (C3-C30)cycloalkenyl group; a 3- to 7-membered heterocycloalkyl group; a (C6-C30)aryl group unsubstituted or substituted with a 5- to 30-membered heteroaryl group; a (C6-C30)aryloxy group; a (C6-C30)arylthio group; a 5- to 30-membered heteroaryl group unsubstituted or substituted with a (C6-C30)aryl group; a tri(C1-C30)alkylsilyl group; a tri(C6-C30)arylsilyl group; a di(C1-C30)alkyl(C6-C30)arylsilyl group; a (C1-C30)alkyl di(C6-C30)arylsilyl group; an amino group; a mono- or di-(C1-C30)alkylamino group; a mono- or di-(C6-C30)arylamino group; a (C1-C30)alkyl(C6-C30)arylamino group; a (C1-C30)alkylcarbonyl group; a (C1-C30)alkoxycarbonyl group; a (C6-C30)arylcarbonyl group; a di(C6-C30)arylboronyl group; a di(C1-C30)alkylboronyl group; a (C1-C30)alkyl(C6-C30)arylboronyl group; a (C6-C30)aryl(C1-C30)alkyl group; and a (C1-C30)alkyl(C6-C30)aryl group, preferably are at least one selected from the group consisting of deuterium; a halogen; a (C1-C30)alkyl group; a halo(C1-C30)alkyl group; a (C6-C30)aryl group; a 5- to 30-membered heteroaryl group; a tri(C1-C30)alkylsilyl group; a tri(C6-C30)arylsilyl group; a di(C1-C30)alkyl(C6-C30)arylsilyl group; a (C1-C30)alkyl di(C6-C30)arylsilyl group; an amino group; a mono- or di-(C1-C30)alkylamino group; a mono- or di-(C6-C30)arylamino group; a (C1-C30)alkyl(C6-C30)arylamino group; a hydroxyl group; and a (C1-C30)alkoxy group, more preferably are at least one selected from the group consisting of deuterium, a halogen, and a (C1-C6)alkyl group.

The representative organic electroluminescent compounds of the present invention include the following compounds, but are not limited thereto:

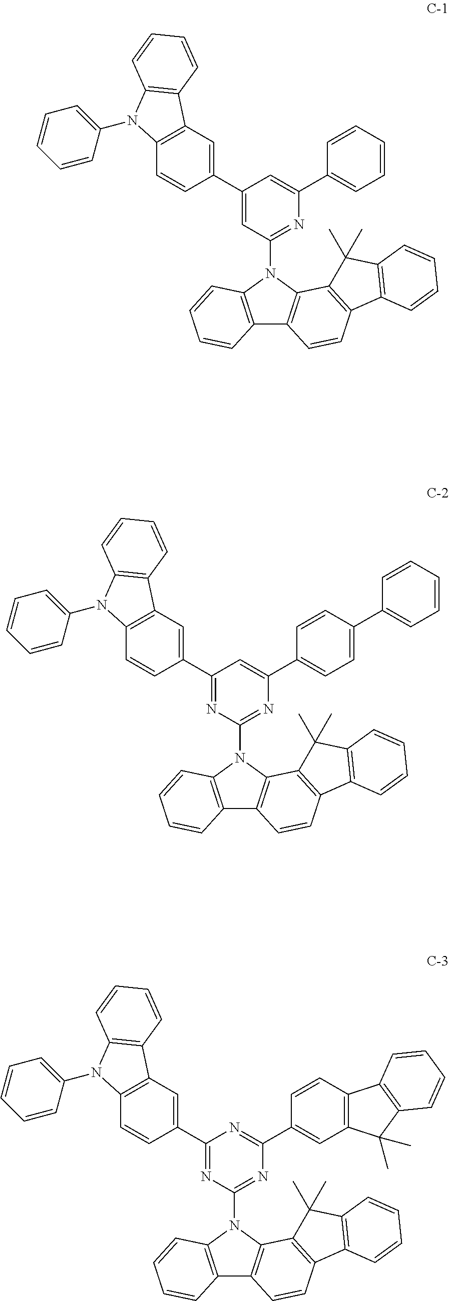 [SMILES: CC1(C)c2ccccc2-c2ccc3c4ccccc4n(-c4cc(-c5ccc6c(c5)c5ccccc5n6-c5ccccc5)cc(-c5ccccc5)n4)c3c21 ; CC1(C)c2ccccc2-c2ccc3c4ccccc4n(-c4nc(-c5ccc(-c6ccccc6)cc5)cc(-c5ccc6c(c5)c5ccccc5n6-c5ccccc5)n4)c3c21 ; CC1(C)c2ccccc2-c2ccc(-c3nc(-c4ccc5c(c4)c4ccccc4n5-c4ccccc4)nc(-n4c5ccccc5c5ccc6c(c54)C(C)(C)c4ccccc4-6)n3)cc21]

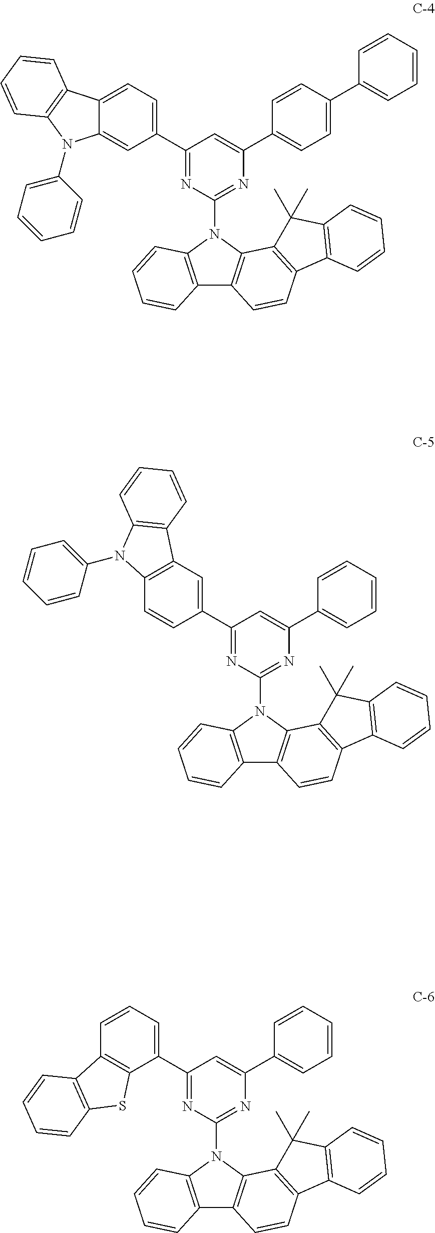 [SMILES: CC1(C)c2ccccc2-c2ccc3c4ccccc4n(-c4nc(-c5ccc(-c6ccccc6)cc5)cc(-c5ccc6c7ccccc7n(-c7ccccc7)c6c5)n4)c3c21 ; CC1(C)c2ccccc2-c2ccc3c4ccccc4n(-c4nc(-c5ccccc5)cc(-c5ccc6c(c5)c5ccccc5n6-c5ccccc5)n4)c3c21 ; CC1(C)c2ccccc2-c2ccc3c4ccccc4n(-c4nc(-c5ccccc5)cc(-c5cccc6c5sc5ccccc56)n4)c3c21]

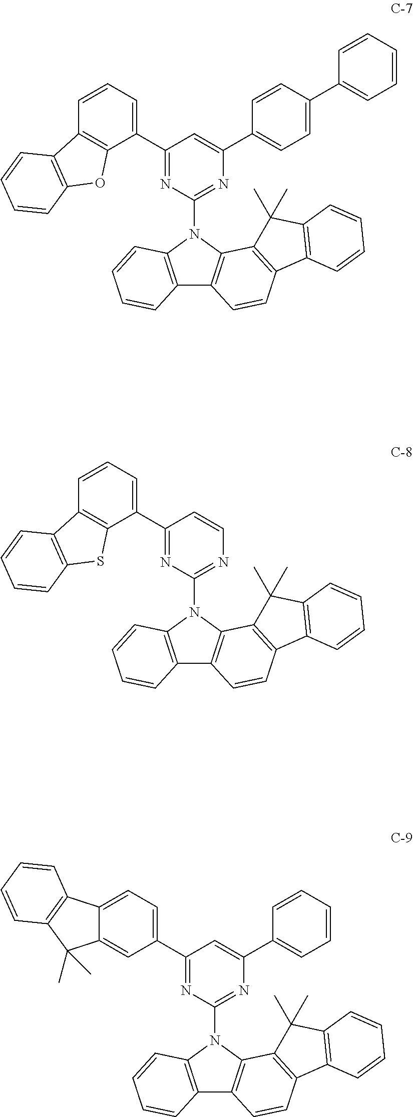 [SMILES: CC1(C)c2ccccc2-c2ccc3c4ccccc4n(-c4nc(-c5ccc(-c6ccccc6)cc5)cc(-c5cccc6c5oc5ccccc56)n4)c3c21 ; CC1(C)c2ccccc2-c2ccc3c4ccccc4n(-c4nccc(-c5cccc6c5sc5ccccc56)n4)c3c21 ; CC1(C)c2ccccc2-c2ccc(-c3cc(-c4ccccc4)nc(-n4c5ccccc5c5ccc6c(c54)C(C)(C)c4ccccc4-6)n3)cc21]

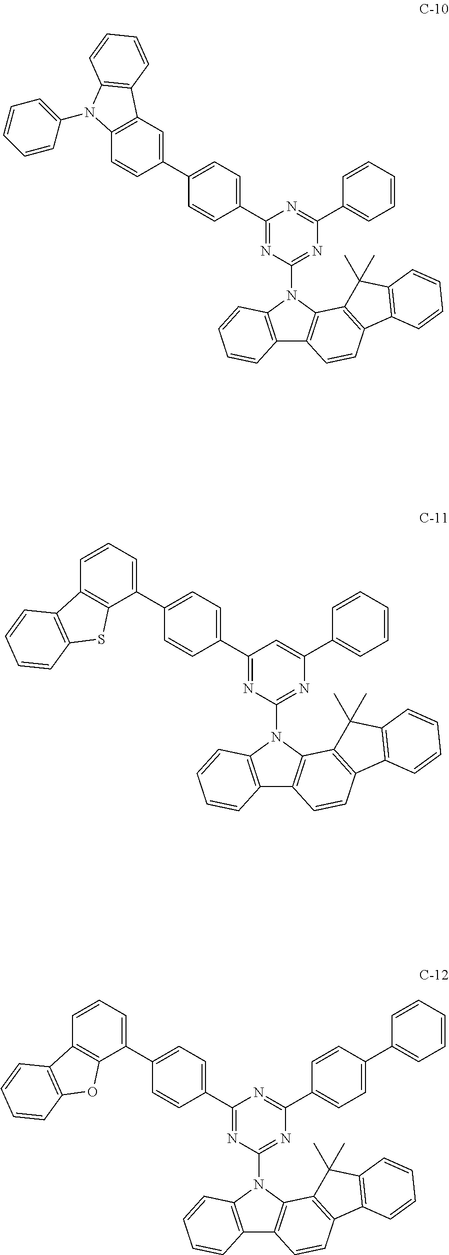 [SMILES: CC1(C)c2ccccc2-c2ccc3c4ccccc4n(-c4nc(-c5ccccc5)nc(-c5ccc(-c6ccc7c(c6)c6ccccc6n7-c6ccccc6)cc5)n4)c3c21 ; CC1(C)c2ccccc2-c2ccc3c4ccccc4n(-c4nc(-c5ccccc5)cc(-c5ccc(-c6cccc7c6sc6ccccc67)cc5)n4)c3c21 ; CC1(C)c2ccccc2-c2ccc3c4ccccc4n(-c4nc(-c5ccc(-c6ccccc6)cc5)nc(-c5ccc(-c6cccc7c6oc6ccccc67)cc5)n4)c3c21]

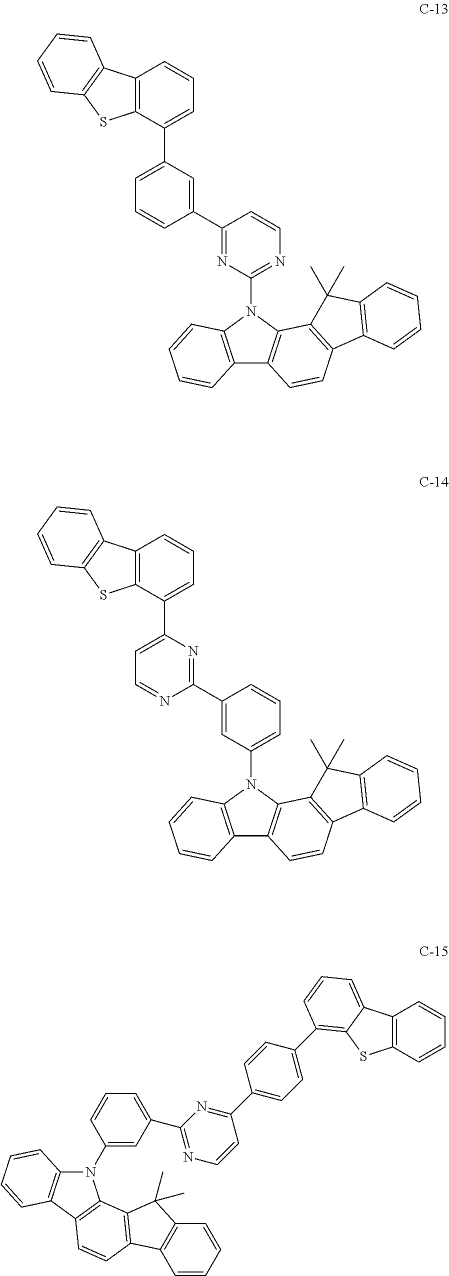 [SMILES: CC1(C)c2ccccc2-c2ccc3c4ccccc4n(-c4nccc(-c5cccc(-c6cccc7c6sc6ccccc67)c5)n4)c3c21 ; CC1(C)c2ccccc2-c2ccc3c4ccccc4n(-c4cccc(-c5nccc(-c6cccc7c6sc6ccccc67)n5)c4)c3c21 ; CC1(C)c2ccccc2-c2ccc3c4ccccc4n(-c4cccc(-c5nccc(-c6ccc(-c7cccc8c7sc7ccccc78)cc6)n5)c4)c3c21]

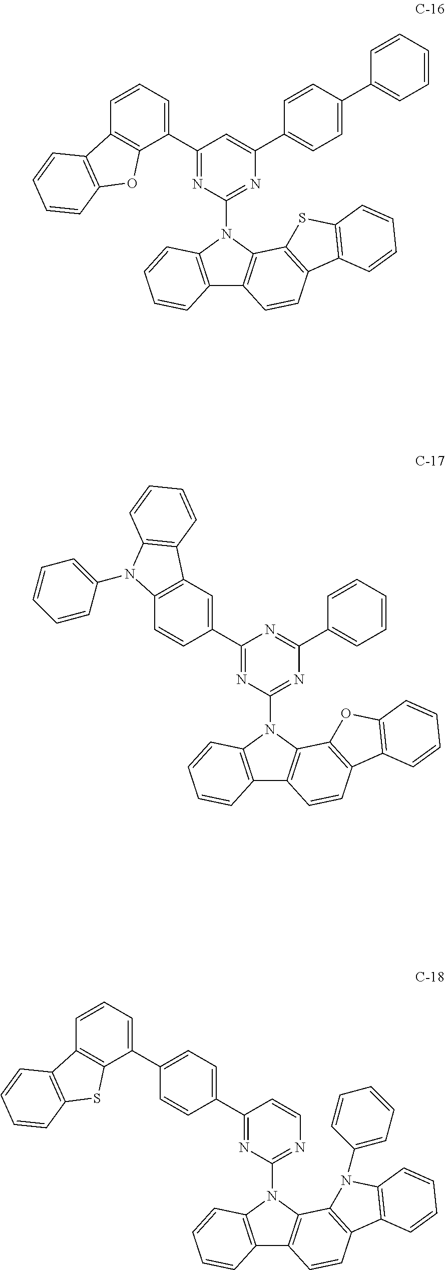 [SMILES: c1ccc(-c2ccc(-c3cc(-c4cccc5c4oc4ccccc45)nc(-n4c5ccccc5c5ccc6c7ccccc7sc6c54)n3)cc2)cc1 ; c1ccc(-c2nc(-c3ccc4c(c3)c3ccccc3n4-c3ccccc3)nc(-n3c4ccccc4c4ccc5c6ccccc6oc5c43)n2)cc1 ; c1ccc(-n2c3ccccc3c3ccc4c5ccccc5n(-c5nccc(-c6ccc(-c7cccc8c7sc7ccccc78)cc6)n5)c4c32)cc1]

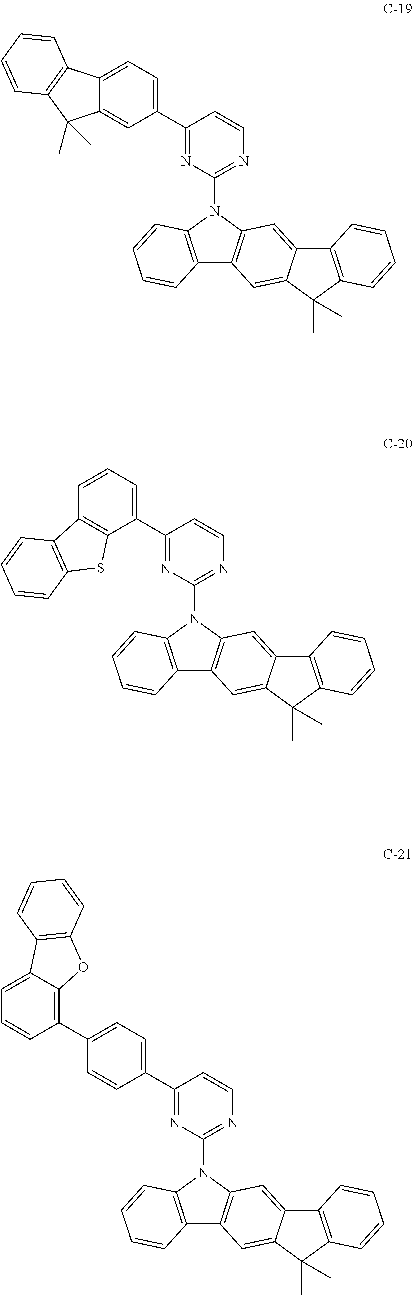 [SMILES: CC1(C)c2ccccc2-c2ccc(-c3ccnc(-n4c5ccccc5c5cc6c(cc54)-c4ccccc4C6(C)C)n3)cc21 ; CC1(C)c2ccccc2-c2cc3c(cc21)c1ccccc1n3-c1nccc(-c2cccc3c2sc2ccccc23)n1 ; CC1(C)c2ccccc2-c2cc3c(cc21)c1ccccc1n3-c1nccc(-c2ccc(-c3cccc4c3oc3ccccc34)cc2)n1]

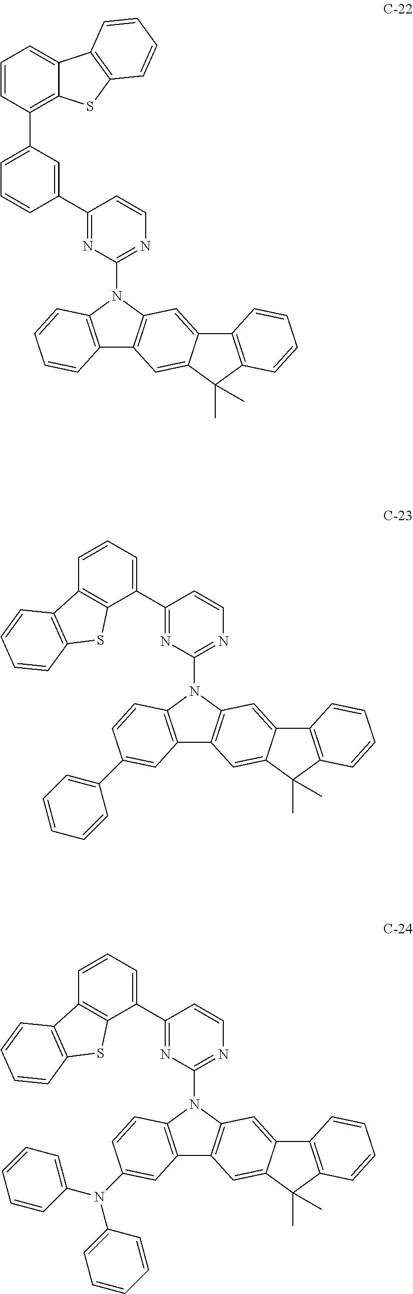 [SMILES: CC1(C)c2ccccc2-c2cc3c(cc21)c1ccccc1n3-c1nccc(-c2cccc(-c3cccc4c3sc3ccccc34)c2)n1 ; CC1(C)c2ccccc2-c2cc3c(cc21)c1cc(-c2ccccc2)ccc1n3-c1nccc(-c2cccc3c2sc2ccccc23)n1 ; CC1(C)c2ccccc2-c2cc3c(cc21)c1cc(N(c2ccccc2)c2ccccc2)ccc1n3-c1nccc(-c2cccc3c2sc2ccccc23)n1]

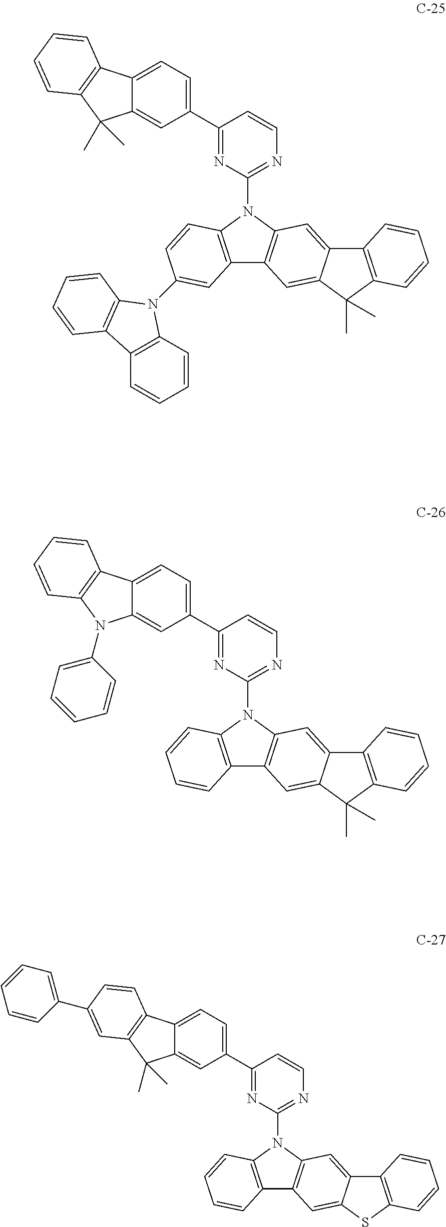 [SMILES: CC1(C)c2ccccc2-c2ccc(-c3ccnc(-n4c5ccc(-n6c7ccccc7c7ccccc76)cc5c5cc6c(cc54)-c4ccccc4C6(C)C)n3)cc21 ; CC1(C)c2ccccc2-c2cc3c(cc21)c1ccccc1n3-c1nccc(-c2ccc3c4ccccc4n(-c4ccccc4)c3c2)n1 ; CC1(C)c2cc(-c3ccccc3)ccc2-c2ccc(-c3ccnc(-n4c5ccccc5c5cc6sc7ccccc7c6cc54)n3)cc21]

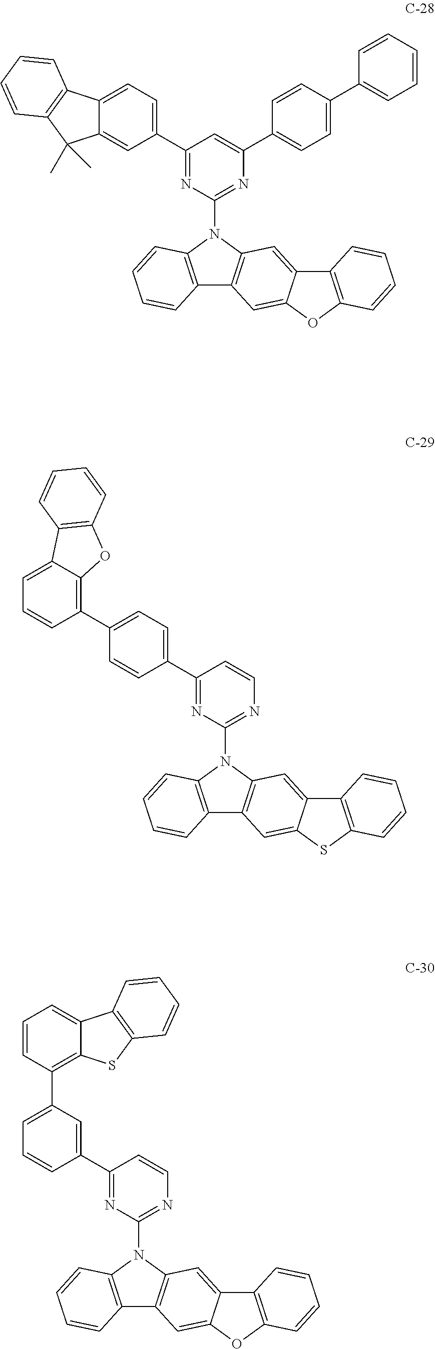 [SMILES: CC1(C)c2ccccc2-c2ccc(-c3cc(-c4ccc(-c5ccccc5)cc4)nc(-n4c5ccccc5c5cc6oc7ccccc7c6cc54)n3)cc21 ; c1ccc2c(c1)oc1c(-c3ccc(-c4ccnc(-n5c6ccccc6c6cc7sc8ccccc8c7cc65)n4)cc3)cccc12 ; c1cc(-c2ccnc(-n3c4ccccc4c4cc5oc6ccccc6c5cc43)n2)cc(-c2cccc3c2sc2ccccc23)c1]

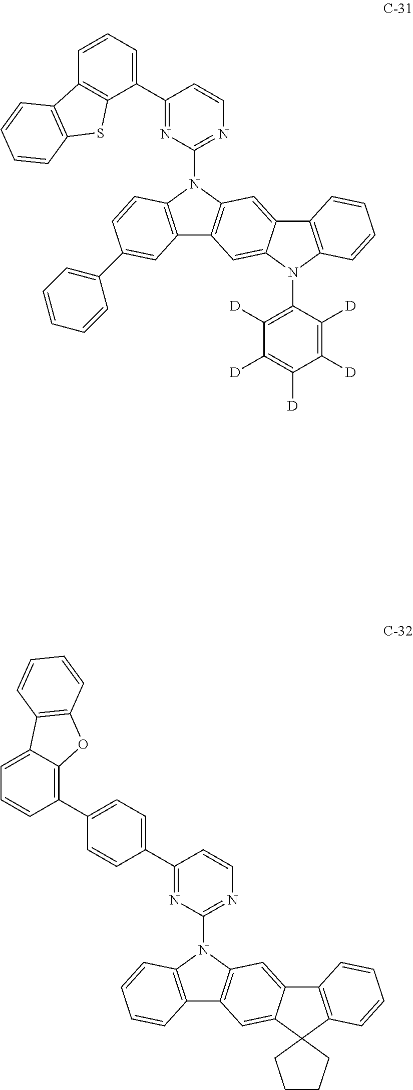 [SMILES: [2H]c1c([2H])c([2H])c(-n2c3ccccc3c3cc4c(cc32)c2cc(-c3ccccc3)ccc2n4-c2nccc(-c3cccc4c3sc3ccccc34)n2)c([2H])c1[2H] ; c1ccc2c(c1)-c1cc3c(cc1C21CCCC1)c1ccccc1n3-c1nccc(-c2ccc(-c3cccc4c3oc3ccccc34)cc2)n1]

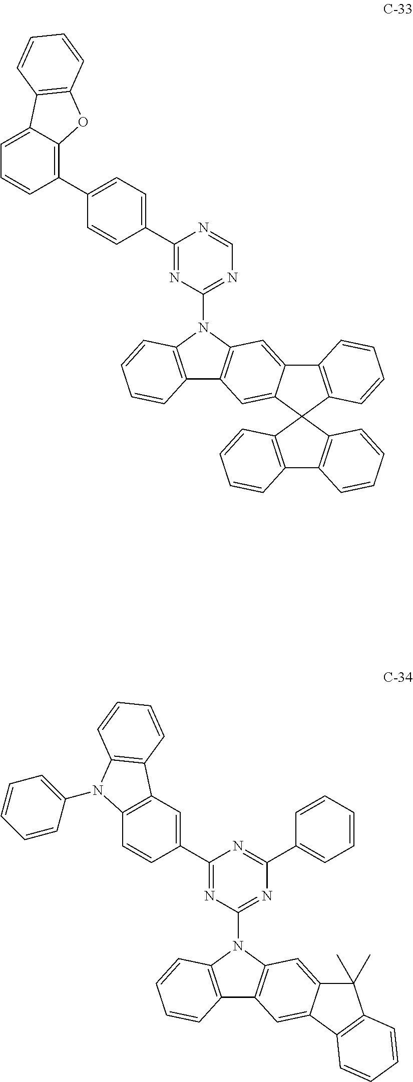 [SMILES: c1ccc2c(c1)-c1ccccc1C21c2ccccc2-c2cc3c(cc21)c1ccccc1n3-c1ncnc(-c2ccc(-c3cccc4c3oc3ccccc34)cc2)n1 ; CC1(C)c2ccccc2-c2cc3c4ccccc4n(-c4nc(-c5ccccc5)nc(-c5ccc6c(c5)c5ccccc5n6-c5ccccc5)n4)c3cc21]

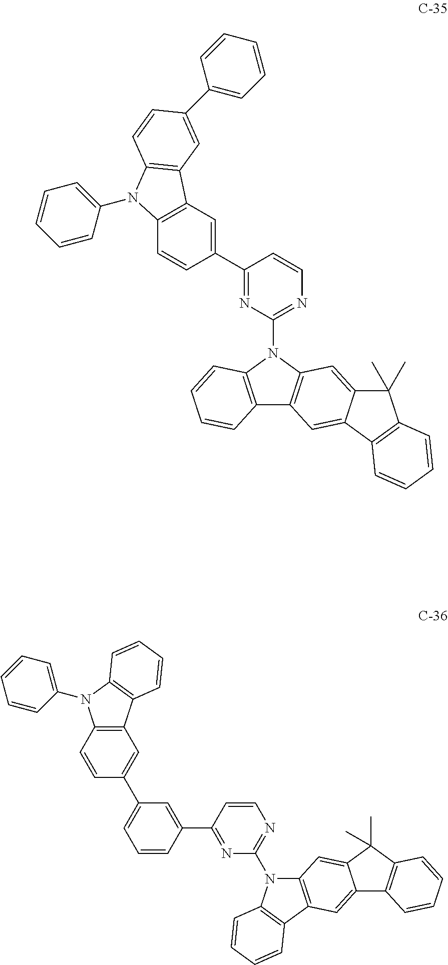 [SMILES: CC1(C)c2ccccc2-c2cc3c4ccccc4n(-c4nccc(-c5ccc6c(c5)c5cc(-c7ccccc7)ccc5n6-c5ccccc5)n4)c3cc21 ; CC1(C)c2ccccc2-c2cc3c4ccccc4n(-c4nccc(-c5cccc(-c6ccc7c(c6)c6ccccc6n7-c6ccccc6)c5)n4)c3cc21]

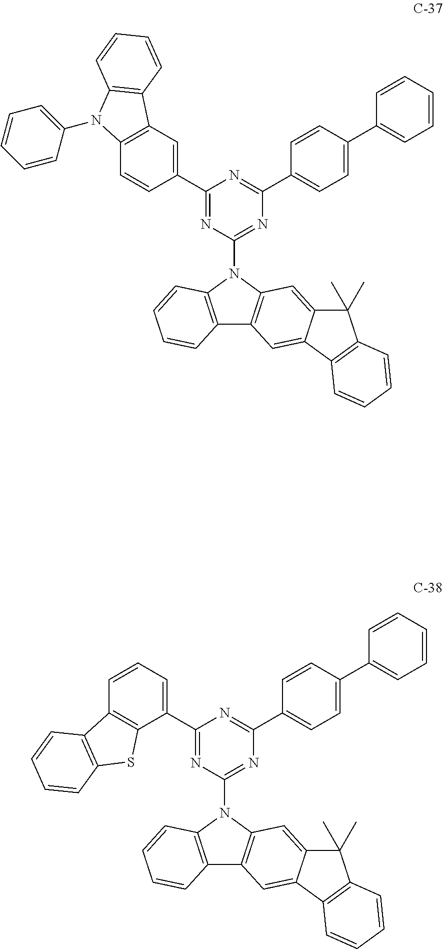 [SMILES: CC1(C)c2ccccc2-c2cc3c4ccccc4n(-c4nc(-c5ccc(-c6ccccc6)cc5)nc(-c5ccc6c(c5)c5ccccc5n6-c5ccccc5)n4)c3cc21 ; CC1(C)c2ccccc2-c2cc3c4ccccc4n(-c4nc(-c5ccc(-c6ccccc6)cc5)nc(-c5cccc6c5sc5ccccc56)n4)c3cc21]

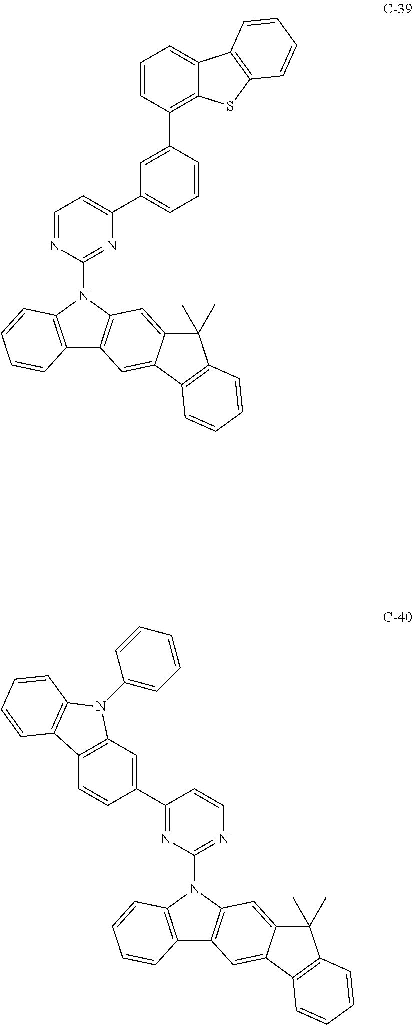 [SMILES: CC1(C)c2ccccc2-c2cc3c4ccccc4n(-c4nccc(-c5cccc(-c6cccc7c6sc6ccccc67)c5)n4)c3cc21 ; CC1(C)c2ccccc2-c2cc3c4ccccc4n(-c4nccc(-c5ccc6c7ccccc7n(-c7ccccc7)c6c5)n4)c3cc21]

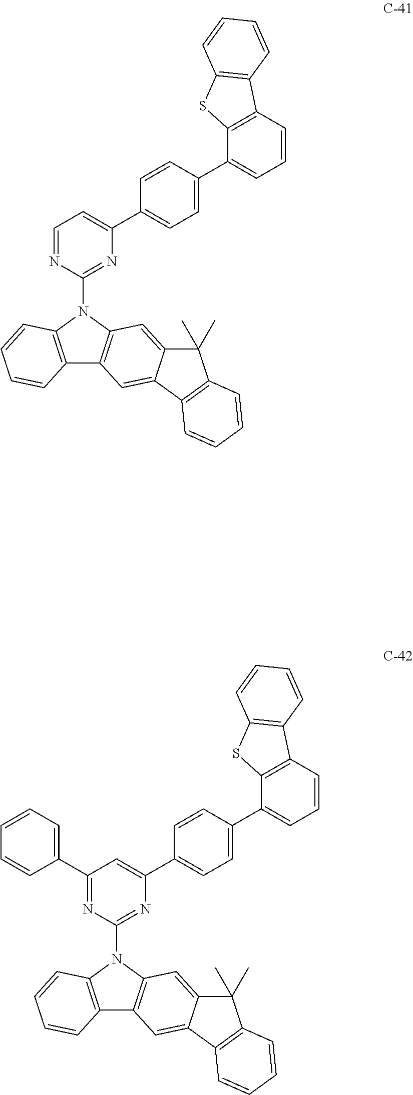 [SMILES: CC1(C)c2ccccc2-c2cc3c4ccccc4n(-c4nccc(-c5ccc(-c6cccc7c6sc6ccccc67)cc5)n4)c3cc21 ; CC1(C)c2ccccc2-c2cc3c4ccccc4n(-c4nc(-c5ccccc5)cc(-c5ccc(-c6cccc7c6sc6ccccc67)cc5)n4)c3cc21]

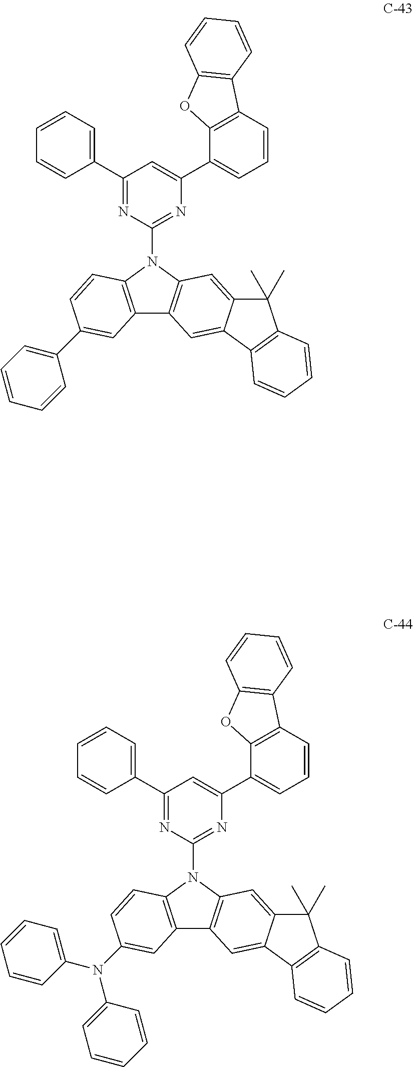 [SMILES: CC1(C)c2ccccc2-c2cc3c4cc(-c5ccccc5)ccc4n(-c4nc(-c5ccccc5)cc(-c5cccc6c5oc5ccccc56)n4)c3cc21 ; CC1(C)c2ccccc2-c2cc3c4cc(N(c5ccccc5)c5ccccc5)ccc4n(-c4nc(-c5ccccc5)cc(-c5cccc6c5oc5ccccc56)n4)c3cc21]

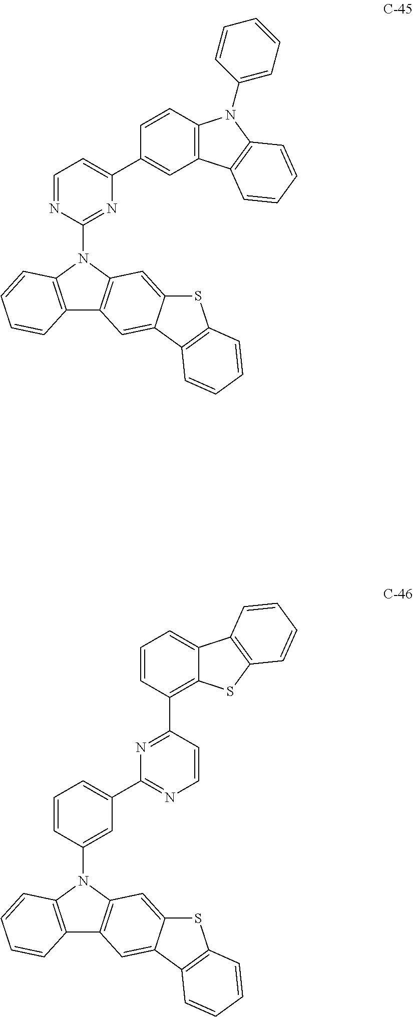 [SMILES: c1ccc(-n2c3ccccc3c3cc(-c4ccnc(-n5c6ccccc6c6cc7c(cc65)sc5ccccc57)n4)ccc32)cc1 ; c1cc(-c2nccc(-c3cccc4c3sc3ccccc34)n2)cc(-n2c3ccccc3c3cc4c(cc32)sc2ccccc24)c1]

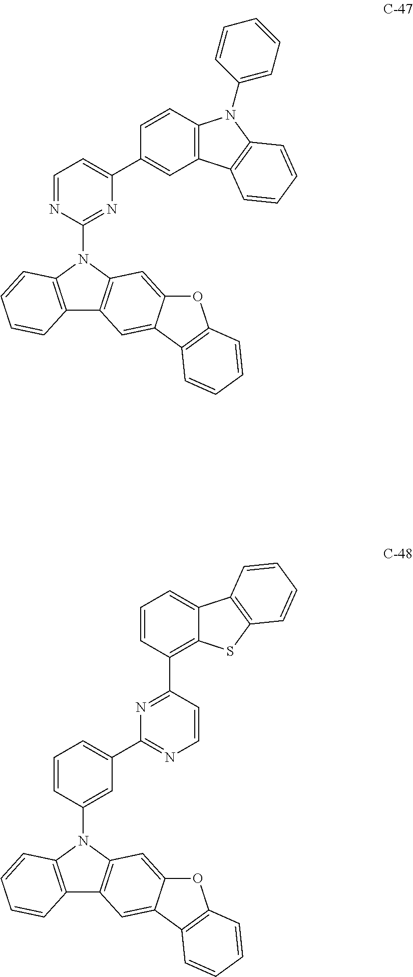 [SMILES: c1ccc(-n2c3ccccc3c3cc(-c4ccnc(-n5c6ccccc6c6cc7c(cc65)oc5ccccc57)n4)ccc32)cc1 ; c1cc(-c2nccc(-c3cccc4c3sc3ccccc34)n2)cc(-n2c3ccccc3c3cc4c(cc32)oc2ccccc24)c1]

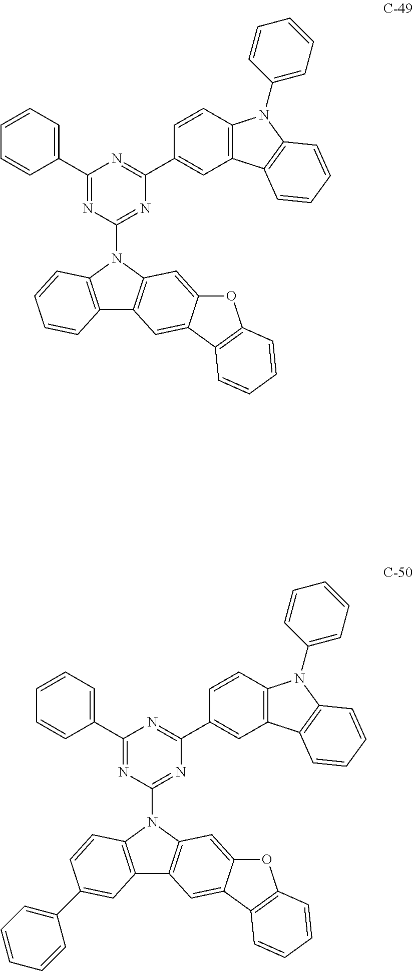 [SMILES: c1ccc(-c2nc(-c3ccc4c(c3)c3ccccc3n4-c3ccccc3)nc(-n3c4ccccc4c4cc5c(cc43)oc3ccccc35)n2)cc1 ; c1ccc(-c2ccc3c(c2)c2cc4c(cc2n3-c2nc(-c3ccccc3)nc(-c3ccc5c(c3)c3ccccc3n5-c3ccccc3)n2)oc2ccccc24)cc1]

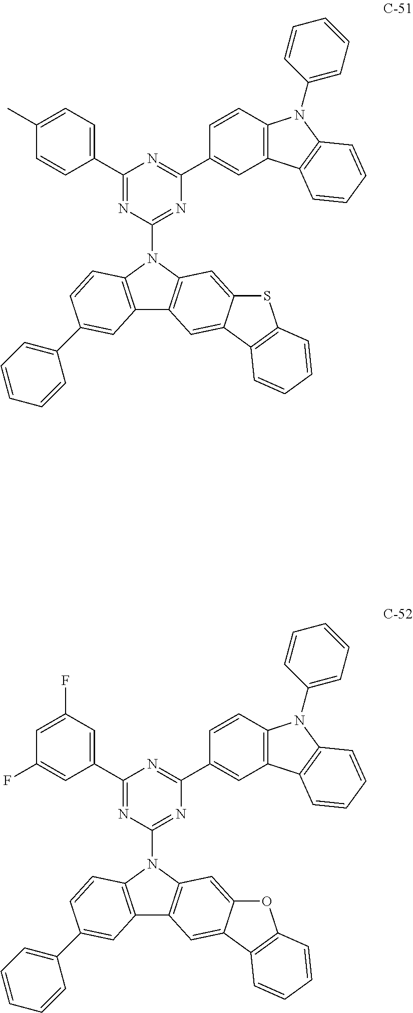 [SMILES: Cc1ccc(-c2nc(-c3ccc4c(c3)c3ccccc3n4-c3ccccc3)nc(-n3c4ccc(-c5ccccc5)cc4c4cc5c(cc43)sc3ccccc35)n2)cc1 ; Fc1cc(F)cc(-c2nc(-c3ccc4c(c3)c3ccccc3n4-c3ccccc3)nc(-n3c4ccc(-c5ccccc5)cc4c4cc5c(cc43)oc3ccccc35)n2)c1]

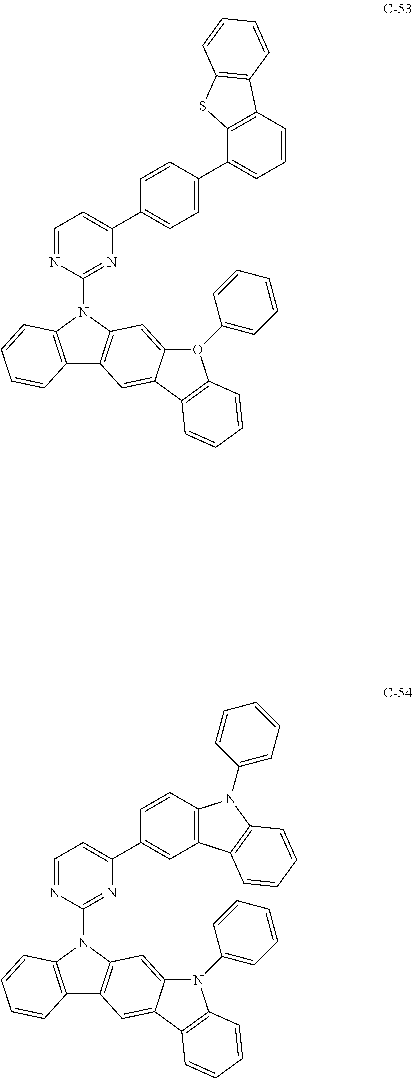

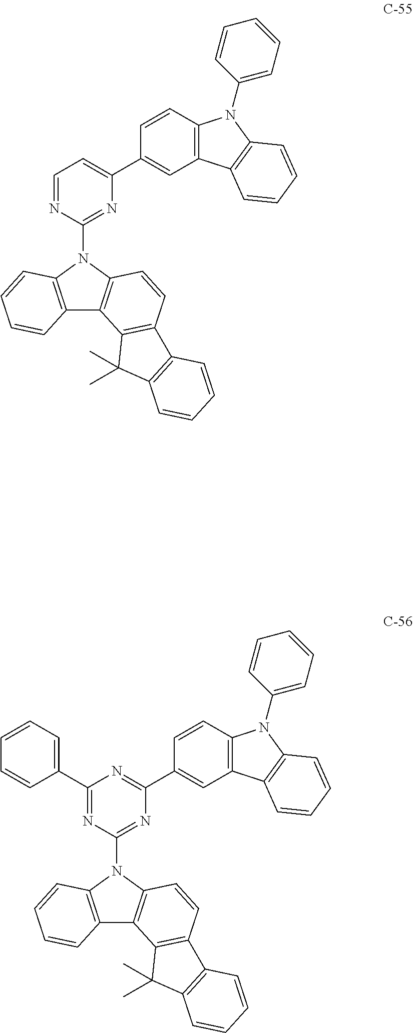 [SMILES: CC1(C)c2ccccc2-c2ccc3c(c21)c1ccccc1n3-c1nccc(-c2ccc3c(c2)c2ccccc2n3-c2ccccc2)n1 ; CC1(C)c2ccccc2-c2ccc3c(c21)c1ccccc1n3-c1nc(-c2ccccc2)nc(-c2ccc3c(c2)c2ccccc2n3-c2ccccc2)n1]

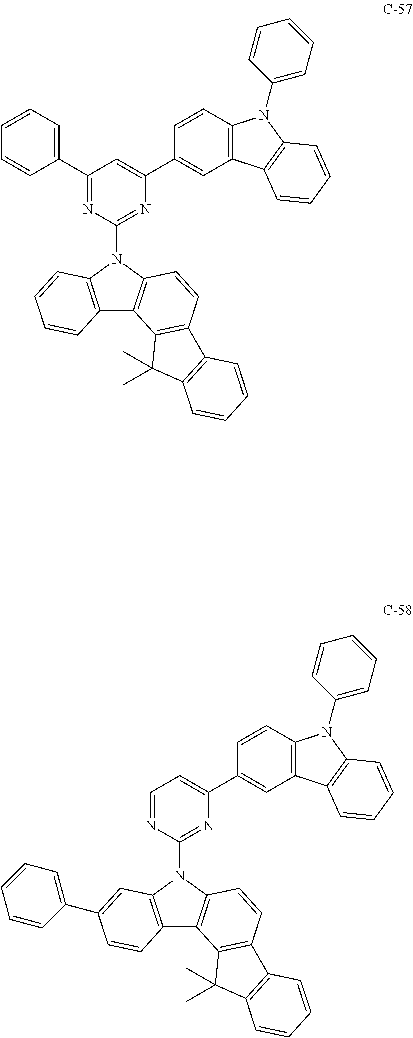 [SMILES: CC1(C)c2ccccc2-c2ccc3c(c21)c1ccccc1n3-c1nc(-c2ccccc2)cc(-c2ccc3c(c2)c2ccccc2n3-c2ccccc2)n1 ; CC1(C)c2ccccc2-c2ccc3c(c21)c1ccc(-c2ccccc2)cc1n3-c1nccc(-c2ccc3c(c2)c2ccccc2n3-c2ccccc2)n1]

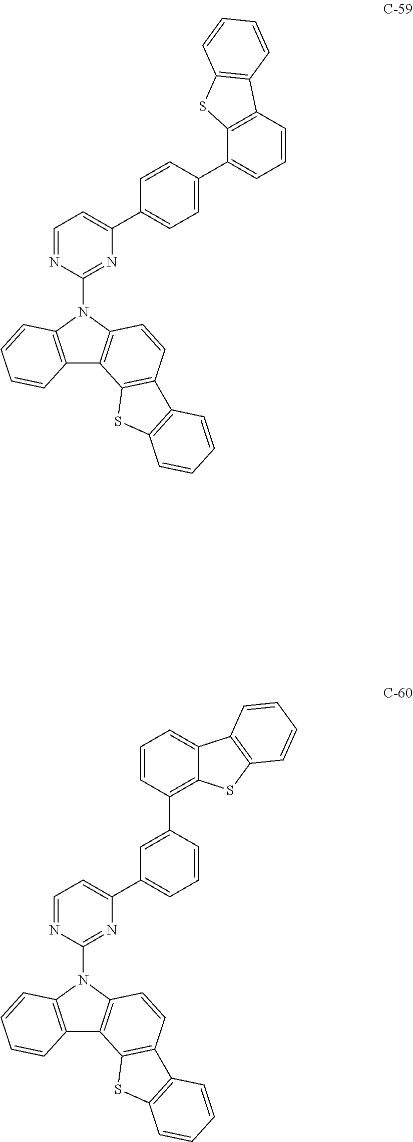 [SMILES: c1ccc2c(c1)sc1c(-c3ccc(-c4ccnc(-n5c6ccccc6c6c7sc8ccccc8c7ccc65)n4)cc3)cccc12 ; c1cc(-c2ccnc(-n3c4ccccc4c4c5sc6ccccc6c5ccc43)n2)cc(-c2cccc3c2sc2ccccc23)c1]

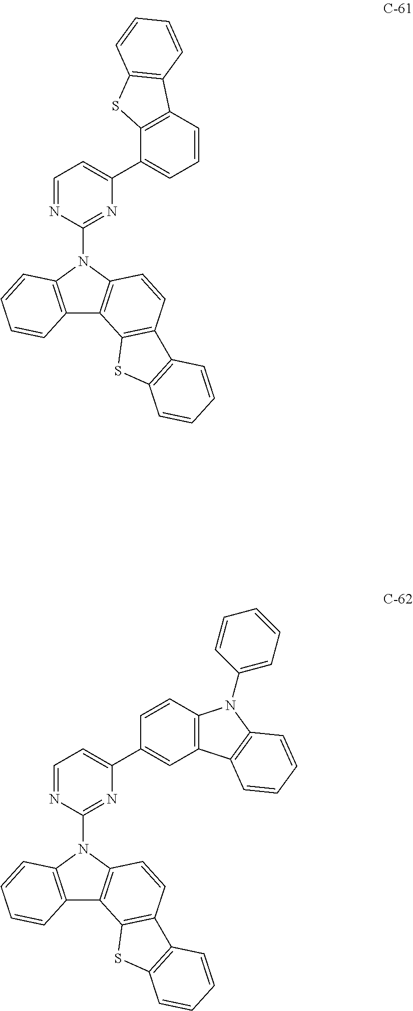 [SMILES: c1ccc2c(c1)sc1c(-c3ccnc(-n4c5ccccc5c5c6sc7ccccc7c6ccc54)n3)cccc12 ; c1ccc(-n2c3ccccc3c3cc(-c4ccnc(-n5c6ccccc6c6c7sc8ccccc8c7ccc65)n4)ccc32)cc1]

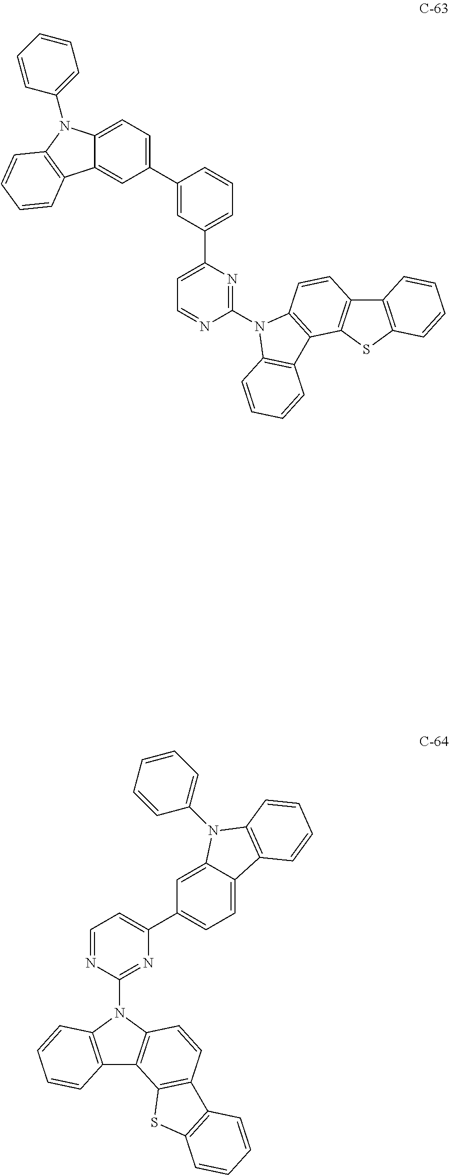 [SMILES: c1ccc(-n2c3ccccc3c3cc(-c4cccc(-c5ccnc(-n6c7ccccc7c7c8sc9ccccc9c8ccc76)n5)c4)ccc32)cc1 ; c1ccc(-n2c3ccccc3c3ccc(-c4ccnc(-n5c6ccccc6c6c7sc8ccccc8c7ccc65)n4)cc32)cc1]

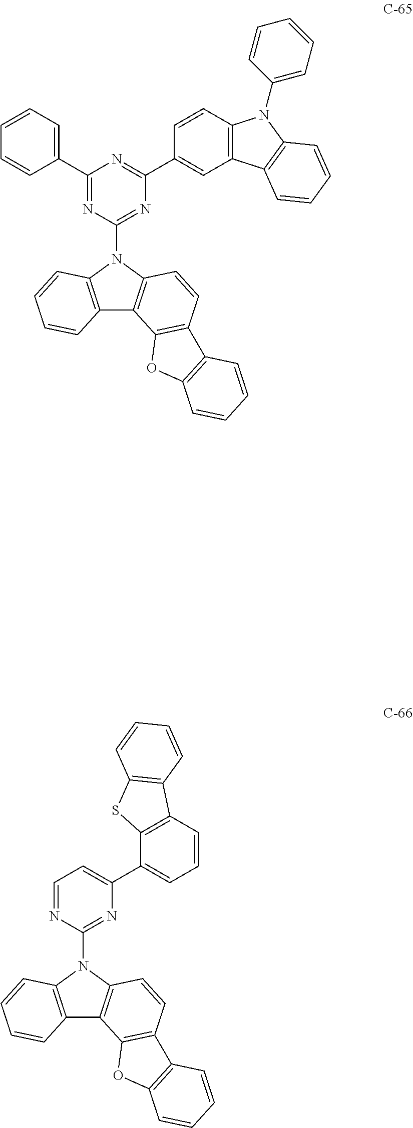 [SMILES: c1ccc(-c2nc(-c3ccc4c(c3)c3ccccc3n4-c3ccccc3)nc(-n3c4ccccc4c4c5oc6ccccc6c5ccc43)n2)cc1 ; c1ccc2c(c1)oc1c2ccc2c1c1ccccc1n2-c1nccc(-c2cccc3c2sc2ccccc23)n1]

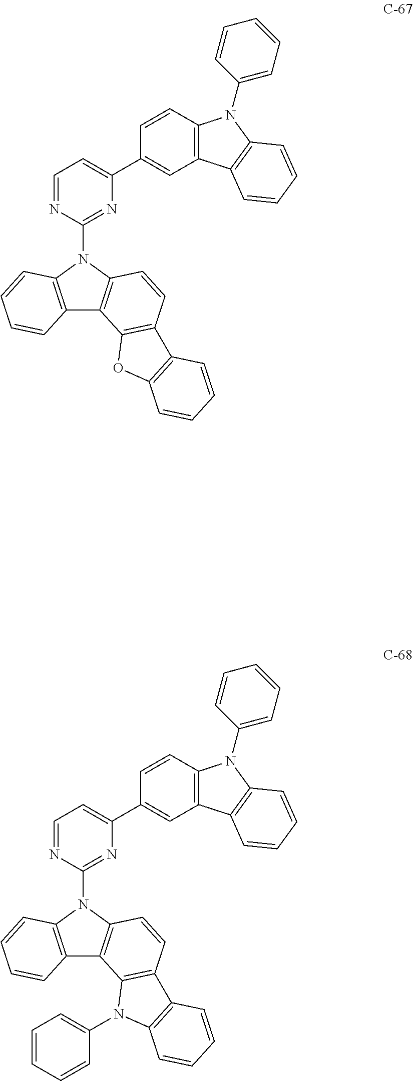 [SMILES: c1ccc(-n2c3ccccc3c3cc(-c4ccnc(-n5c6ccccc6c6c7oc8ccccc8c7ccc65)n4)ccc32)cc1 ; c1ccc(-n2c3ccccc3c3cc(-c4ccnc(-n5c6ccccc6c6c5ccc5c7ccccc7n(-c7ccccc7)c56)n4)ccc32)cc1]

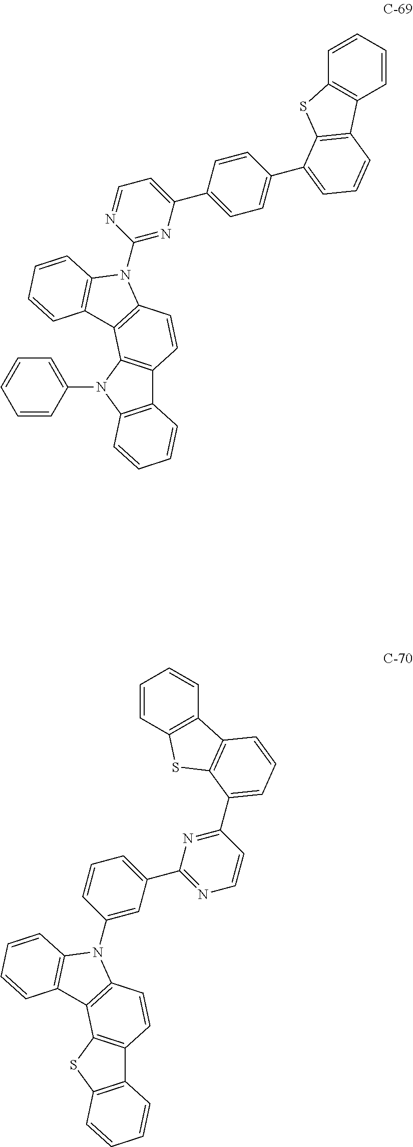 [SMILES: c1ccc(-n2c3ccccc3c3ccc4c(c5ccccc5n4-c4nccc(-c5ccc(-c6cccc7c6sc6ccccc67)cc5)n4)c32)cc1 ; c1cc(-c2nccc(-c3cccc4c3sc3ccccc34)n2)cc(-n2c3ccccc3c3c4sc5ccccc5c4ccc32)c1]

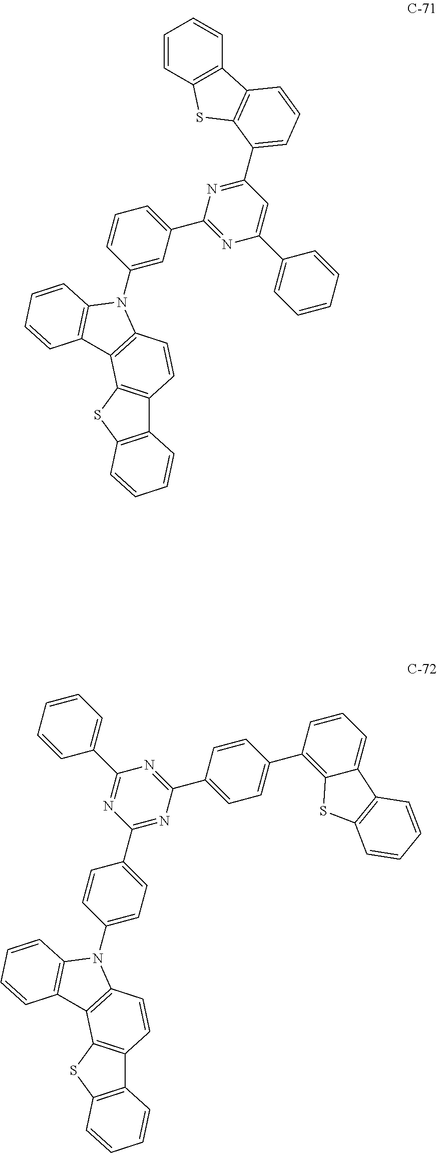 [SMILES: c1ccc(-c2cc(-c3cccc4c3sc3ccccc34)nc(-c3cccc(-n4c5ccccc5c5c6sc7ccccc7c6ccc54)c3)n2)cc1 ; c1ccc(-c2nc(-c3ccc(-c4cccc5c4sc4ccccc45)cc3)nc(-c3ccc(-n4c5ccccc5c5c6sc7ccccc7c6ccc54)cc3)n2)cc1]

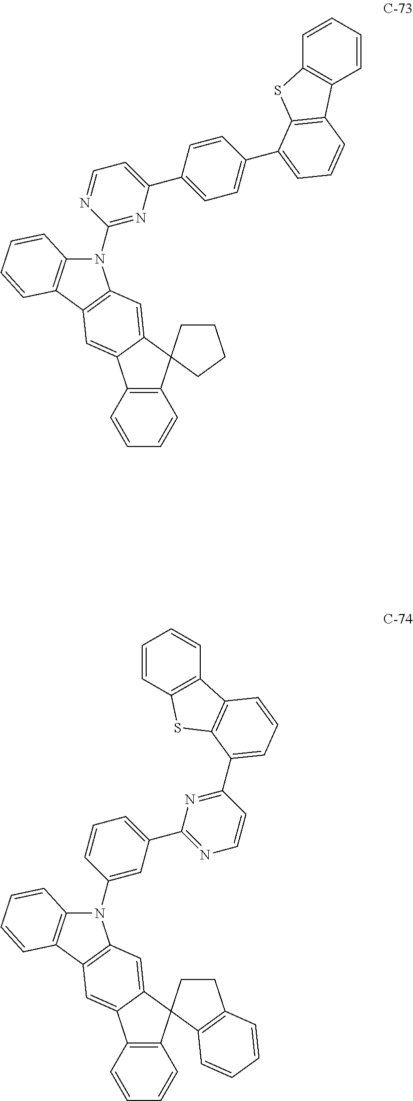 [SMILES: c1ccc2c(c1)-c1cc3c4ccccc4n(-c4nccc(-c5ccc(-c6cccc7c6sc6ccccc67)cc5)n4)c3cc1C21CCCC1 ; c1cc(-c2nccc(-c3cccc4c3sc3ccccc34)n2)cc(-n2c3ccccc3c3cc4c(cc32)C2(CCc3ccccc32)c2ccccc2-4)c1]

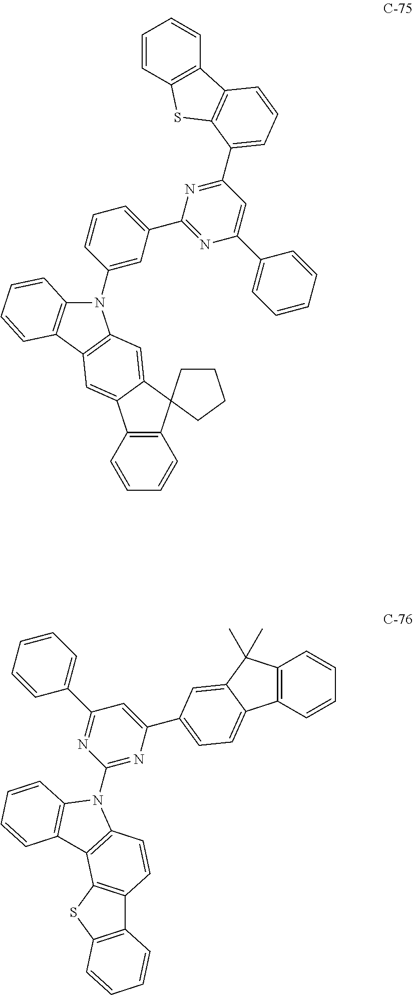 [SMILES: c1ccc(-c2cc(-c3cccc4c3sc3ccccc34)nc(-c3cccc(-n4c5ccccc5c5cc6c(cc54)C4(CCCC4)c4ccccc4-6)c3)n2)cc1 ; CC1(C)c2ccccc2-c2ccc(-c3cc(-c4ccccc4)nc(-n4c5ccccc5c5c6sc7ccccc7c6ccc54)n3)cc21]

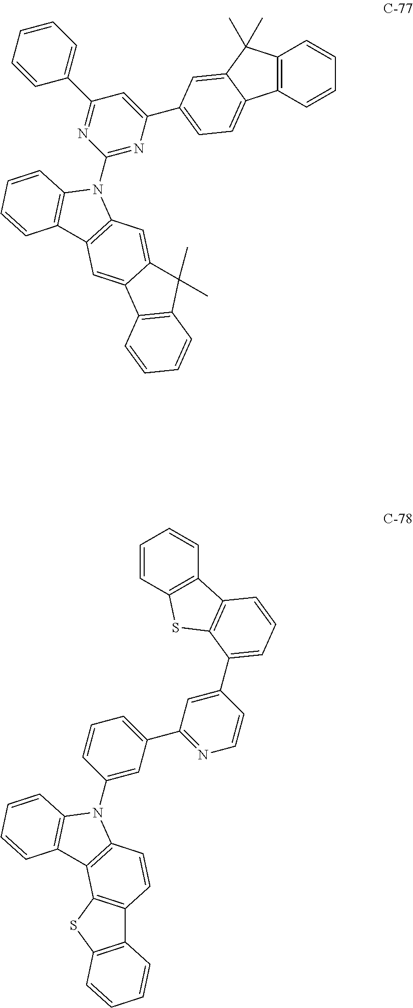 [SMILES: CC1(C)c2ccccc2-c2ccc(-c3cc(-c4ccccc4)nc(-n4c5ccccc5c5cc6c(cc54)C(C)(C)c4ccccc4-6)n3)cc21 ; c1cc(-c2cc(-c3cccc4c3sc3ccccc34)ccn2)cc(-n2c3ccccc3c3c4sc5ccccc5c4ccc32)c1]

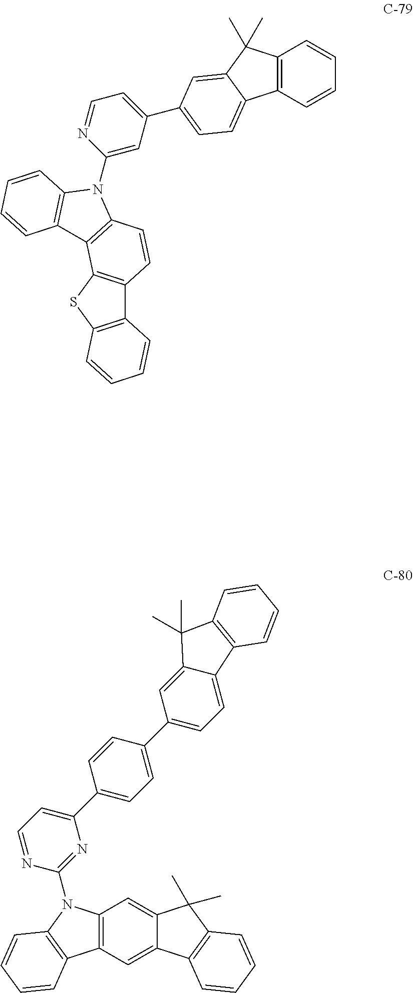 [SMILES: CC1(C)c2ccccc2-c2ccc(-c3ccnc(-n4c5ccccc5c5c6sc7ccccc7c6ccc54)c3)cc21 ; CC1(C)c2ccccc2-c2ccc(-c3ccc(-c4ccnc(-n5c6ccccc6c6cc7c(cc65)C(C)(C)c5ccccc5-7)n4)cc3)cc21]

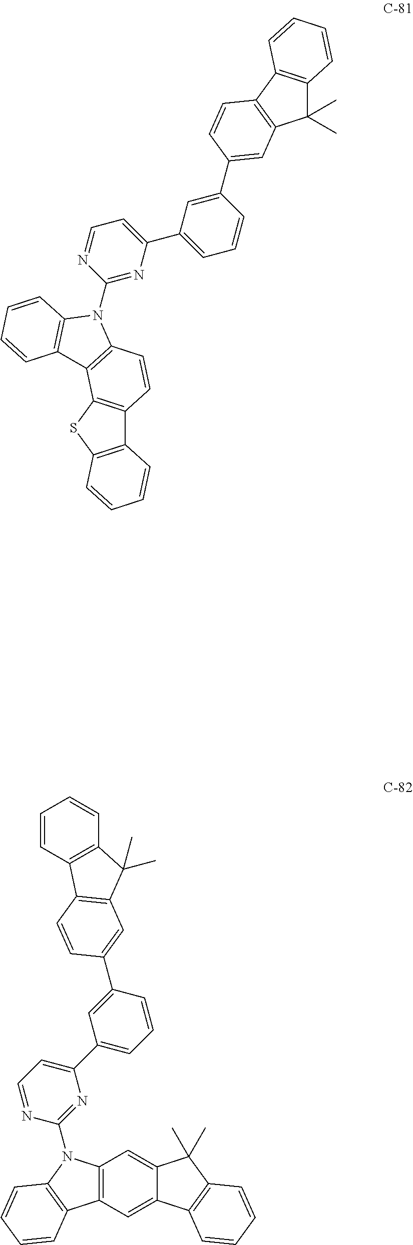 [SMILES: CC1(C)c2ccccc2-c2ccc(-c3cccc(-c4ccnc(-n5c6ccccc6c6c7sc8ccccc8c7ccc65)n4)c3)cc21 ; CC1(C)c2ccccc2-c2ccc(-c3cccc(-c4ccnc(-n5c6ccccc6c6cc7c(cc65)C(C)(C)c5ccccc5-7)n4)c3)cc21]

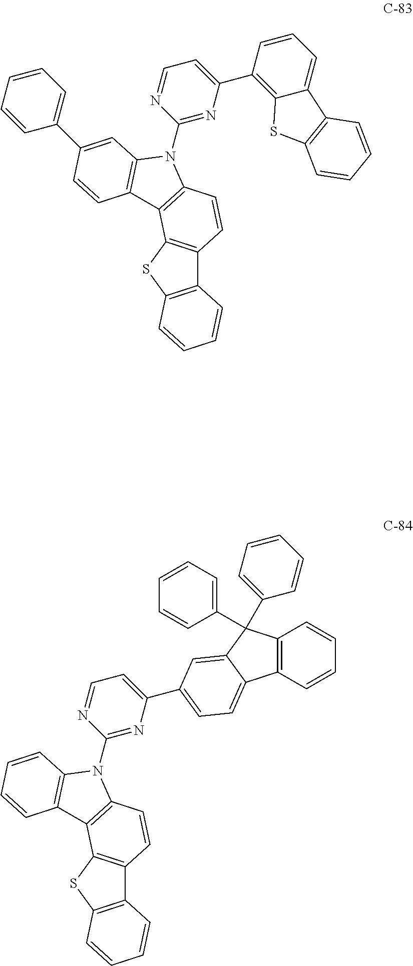 [SMILES: c1ccc(-c2ccc3c4c5sc6ccccc6c5ccc4n(-c4nccc(-c5cccc6c5sc5ccccc56)n4)c3c2)cc1 ; c1ccc(C2(c3ccccc3)c3ccccc3-c3ccc(-c4ccnc(-n5c6ccccc6c6c7sc8ccccc8c7ccc65)n4)cc32)cc1]

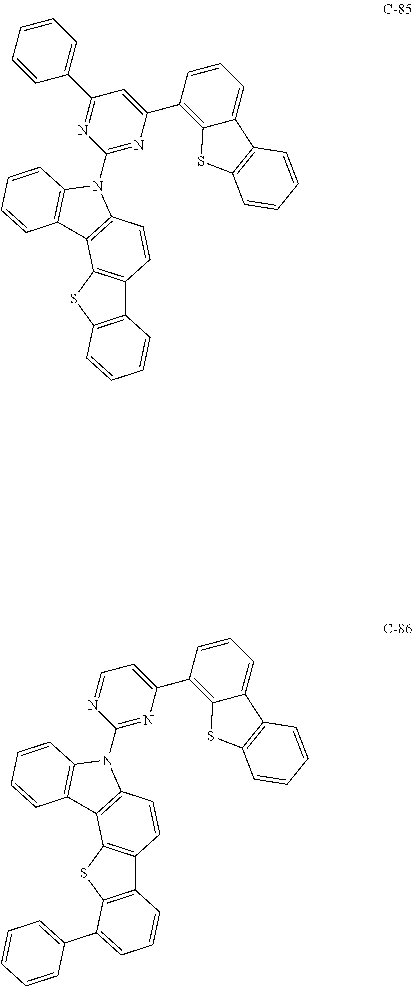 [SMILES: c1ccc(-c2cc(-c3cccc4c3sc3ccccc34)nc(-n3c4ccccc4c4c5sc6ccccc6c5ccc43)n2)cc1 ; c1ccc(-c2cccc3c2sc2c3ccc3c2c2ccccc2n3-c2nccc(-c3cccc4c3sc3ccccc34)n2)cc1]

The organic electroluminescent compounds of the present invention can be prepared by a synthetic method known to a person skilled in the art such as a Suzuki reaction. For example, they can be prepared according to the following reaction scheme 1.

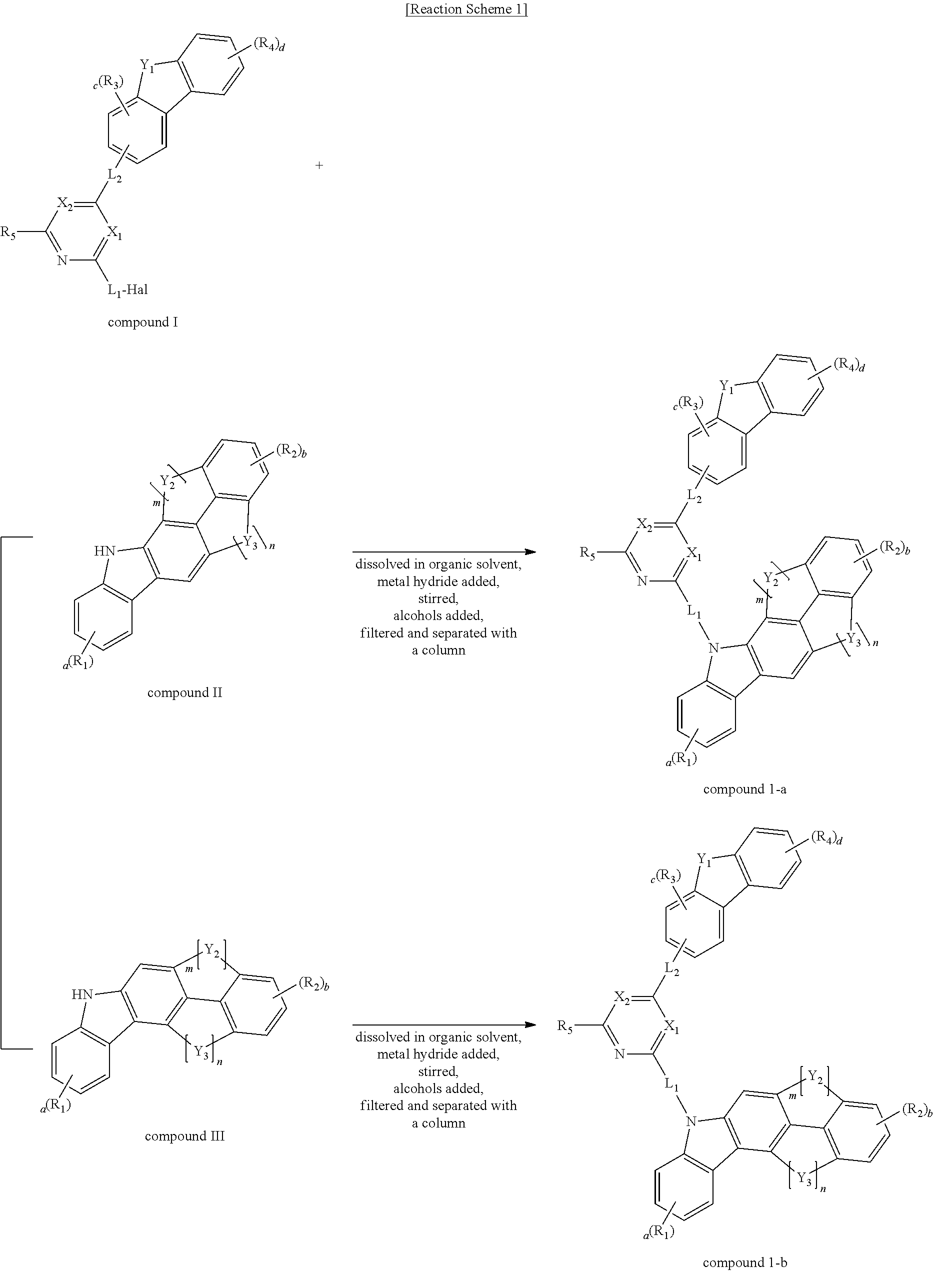

wherein L₁, L₂, R₁ to R₅, Y₁ to Y₃, X₁, X₂, a, b, c, d, m, and n are as defined in formula (1) above, and Hal represents a halogen.

In another embodiment of the present invention provides an organic electroluminescent material comprising the organic electroluminescent compound of formula (1), and an organic electroluminescent device comprising the material.

The above material can be comprised of the organic electroluminescent compound according to the present invention alone, or can further include conventional materials generally used in organic electroluminescent materials.

Said organic electroluminescent device comprises a first electrode, a second electrode, and at least one organic layer between said first and second electrodes. Said organic layer may comprise at least one organic electroluminescent compound of formula 1 according to the present invention.

One of the first and second electrodes is an anode, and the other is a cathode. The organic layer comprises a light-emitting layer, and at least one layer selected from the group consisting of a hole injection layer, a hole transport layer, an electron transport layer, an electron injection layer, an interlayer, and a hole blocking layer.

The organic electroluminescent compound according to the present invention can be comprised in the light-emitting layer. Where used in the light-emitting layer, the compound can be comprised as a host material. Preferably, the light-emitting layer can further comprise at least one dopant.

If needed, a compound other than the organic electroluminescent compound according to the present invention can be comprised additionally as a second host material.

The second host material can be from any of the known phosphorescent hosts. Specifically, the phosphorescent host selected from the group consisting of the compounds of formulas (2) to (6) below is preferable in view of luminous efficiency.

H-(C_{z}-L₄)ₕ-M (2)

H-(Cz)ᵢ-L₄-M (3)

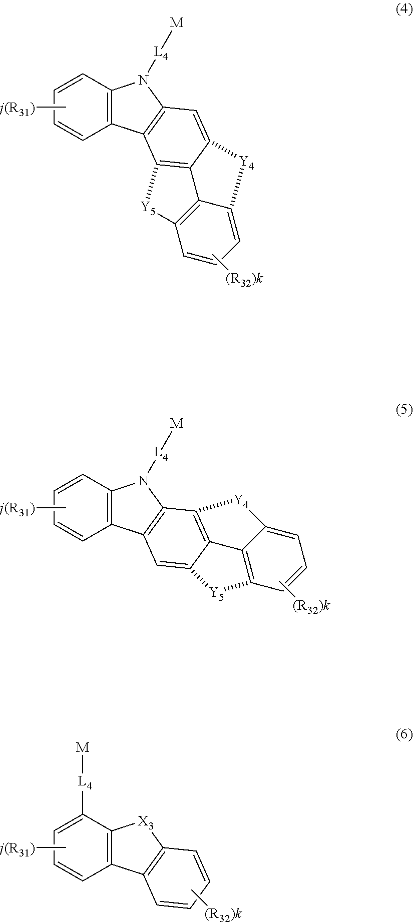

wherein Cz represents the following structure;

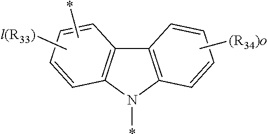

X₃ represents —O— or —S—;

R₃₁ to R₃₄ each independently represent hydrogen, deuterium, a halogen, a substituted or unsubstituted (C1-C30)alkyl group, a substituted of unsubstituted (C6-C30)aryl group, a substituted or unsubstituted 5- to 30-membered heteroaryl group, or R₃₅R₃₆R₃₇Si—;

R₃₅ to R₃₇ each independently represent a substituted or unsubstituted (C1-C30)alkyl group, or a substituted or unsubstituted (C6-C30)aryl group;

L₄ represents a single bond, a substituted or unsubstituted (C6-C30)arylene group, or a substituted or unsubstituted 5- to 30-membered heteroarylene group;

M represents a substituted or unsubstituted (C6-C30)aryl group, or a substituted or unsubstituted 5- to 30-membered heteroaryl group;

Y₄ and Y₅ each independently represent —O—, —S—, —N(R₃₁)— or —C(R₃₂)(R₃₃)—, provided that Y₄ and Y₅ do not simultaneously exist;

R₄₁ to R₄₃ each independently represent a substituted or unsubstituted (C1-C30)alkyl group, a substituted or unsubstituted (C6-C30)aryl group, or a substituted or unsubstituted 5- to 30-membered heteroaryl group, and R₄₂ and R₄₃ may be the same or different;

h and i each independently represent an integer of 1 to 3;

j, k, l and o each independently represent an integer of 0 to 4; and

where h, i, j, k, l or o is an integer of 2 or more, each of (Cz-L₄), each of (Cz), each of R₃₁, each of R₃₂, each of R₃₃ or each of R₃₄ may be the same or different.

Specifically, preferable examples of the second host material are as follows:

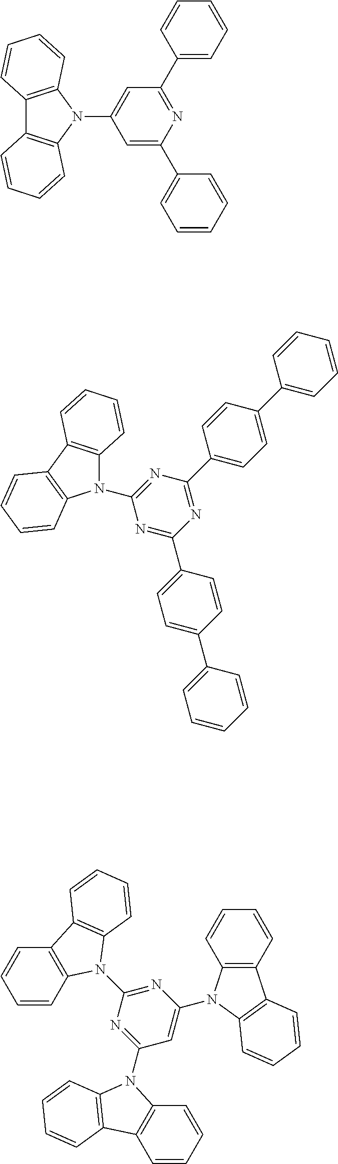 [SMILES: c1ccc(-c2cc(-n3c4ccccc4c4ccccc43)cc(-c3ccccc3)n2)cc1 ; c1ccc(-c2ccc(-c3nc(-c4ccc(-c5ccccc5)cc4)nc(-n4c5ccccc5c5ccccc54)n3)cc2)cc1 ; c1ccc2c(c1)c1ccccc1n2-c1cc(-n2c3ccccc3c3ccccc32)nc(-n2c3ccccc3c3ccccc32)n1]

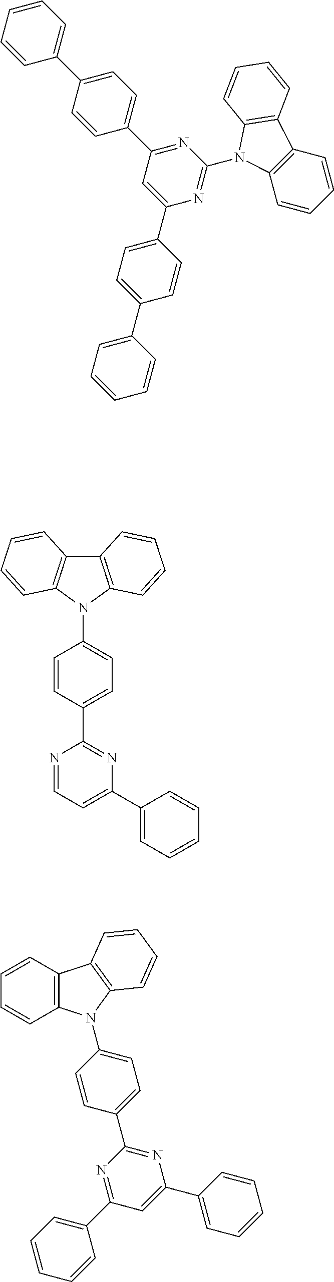 [SMILES: c1ccc(-c2ccc(-c3cc(-c4ccc(-c5ccccc5)cc4)nc(-n4c5ccccc5c5ccccc54)n3)cc2)cc1 ; c1ccc(-c2ccnc(-c3ccc(-n4c5ccccc5c5ccccc54)cc3)n2)cc1 ; c1ccc(-c2cc(-c3ccccc3)nc(-c3ccc(-n4c5ccccc5c5ccccc54)cc3)n2)cc1]

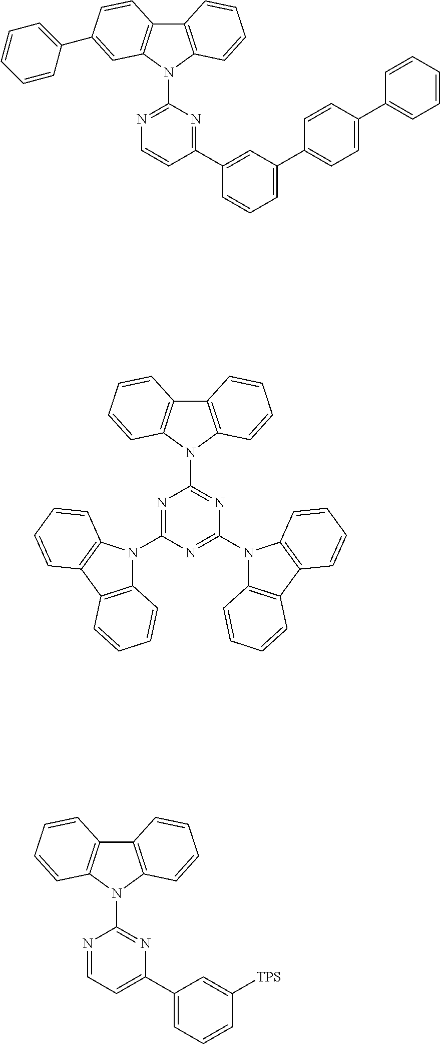

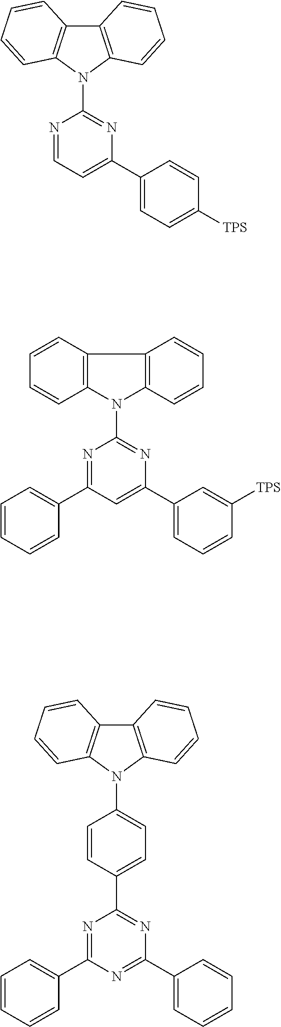

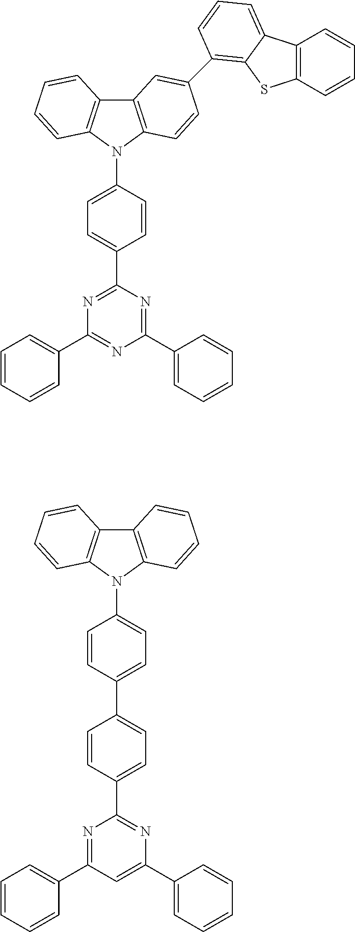 [SMILES: c1ccc(-c2nc(-c3ccccc3)nc(-c3ccc(-n4c5ccccc5c5cc(-c6cccc7c6sc6ccccc67)ccc54)cc3)n2)cc1 ; c1ccc(-c2cc(-c3ccccc3)nc(-c3ccc(-c4ccc(-n5c6ccccc6c6ccccc65)cc4)cc3)n2)cc1]

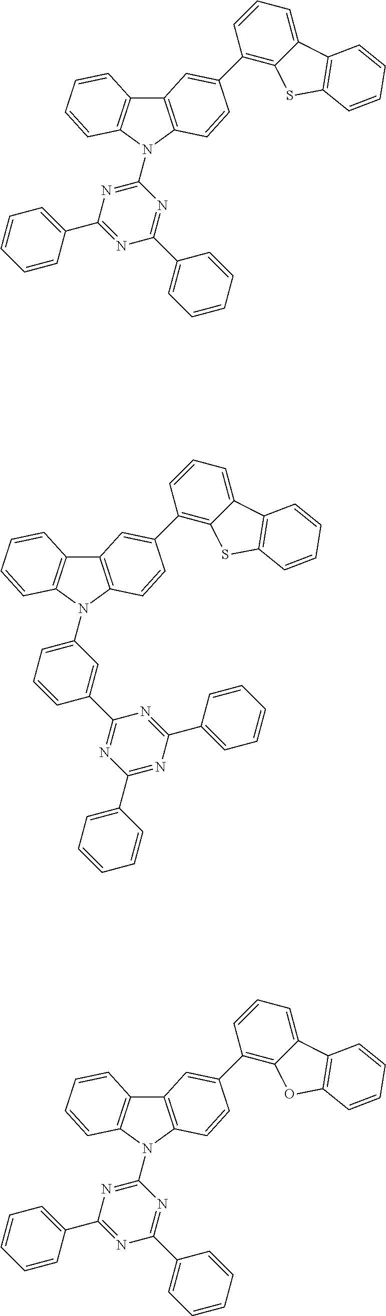 [SMILES: c1ccc(-c2nc(-c3ccccc3)nc(-n3c4ccccc4c4cc(-c5cccc6c5sc5ccccc56)ccc43)n2)cc1 ; c1ccc(-c2nc(-c3ccccc3)nc(-c3cccc(-n4c5ccccc5c5cc(-c6cccc7c6sc6ccccc67)ccc54)c3)n2)cc1 ; c1ccc(-c2nc(-c3ccccc3)nc(-n3c4ccccc4c4cc(-c5cccc6c5oc5ccccc56)ccc43)n2)cc1]

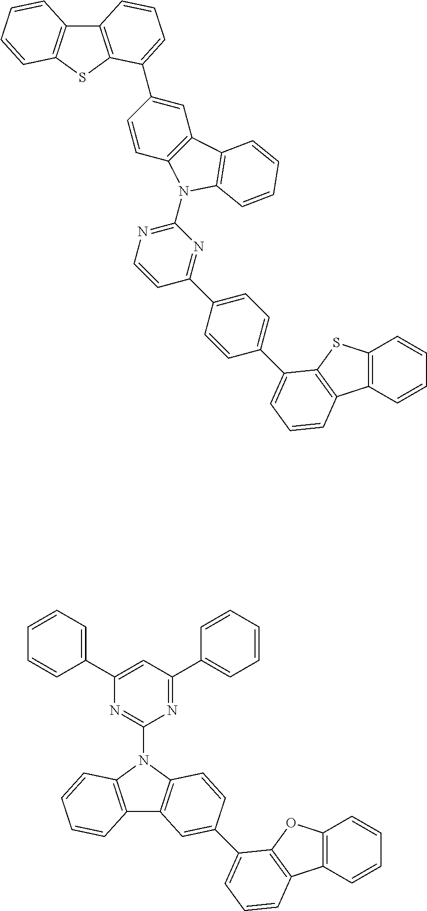 [SMILES: c1ccc2c(c1)sc1c(-c3ccc(-c4ccnc(-n5c6ccccc6c6cc(-c7cccc8c7sc7ccccc78)ccc65)n4)cc3)cccc12 ; c1ccc(-c2cc(-c3ccccc3)nc(-n3c4ccccc4c4cc(-c5cccc6c5oc5ccccc56)ccc43)n2)cc1]

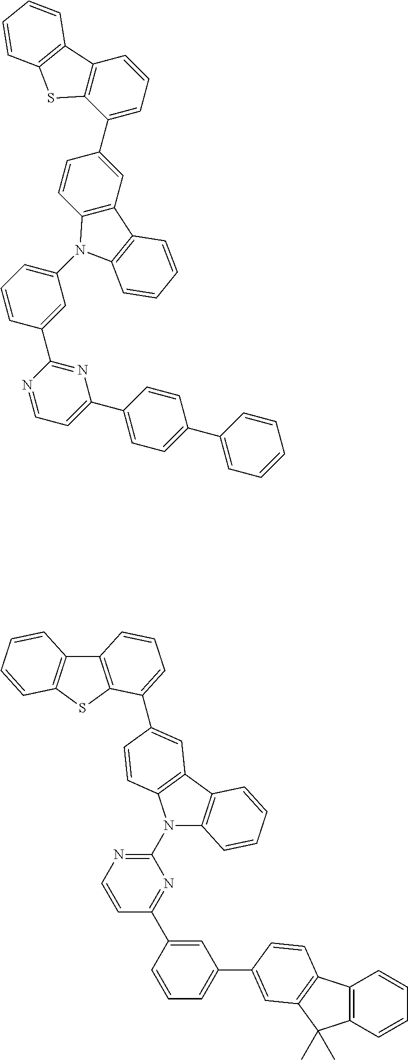 [SMILES: c1ccc(-c2ccc(-c3ccnc(-c4cccc(-n5c6ccccc6c6cc(-c7cccc8c7sc7ccccc78)ccc65)c4)n3)cc2)cc1 ; CC1(C)c2ccccc2-c2ccc(-c3cccc(-c4ccnc(-n5c6ccccc6c6cc(-c7cccc8c7sc7ccccc78)ccc65)n4)c3)cc21]

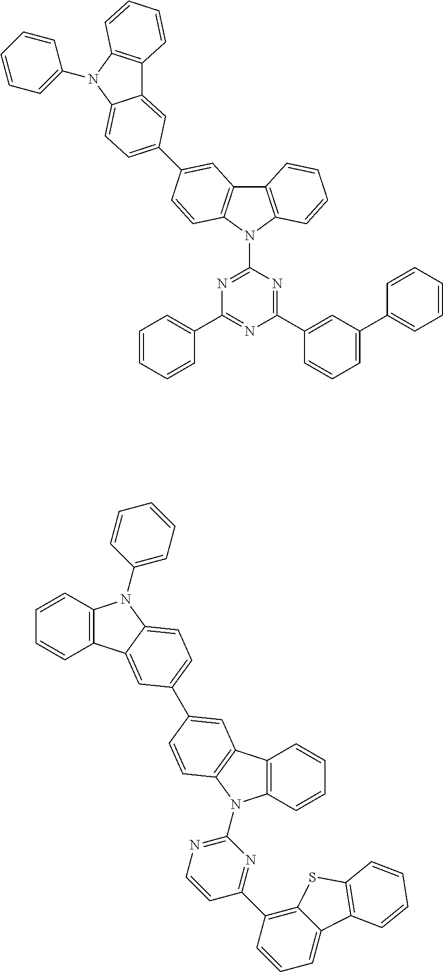 [SMILES: c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-n2c3ccccc3c3cc(-c4ccc5c(c4)c4ccccc4n5-c4nccc(-c5cccc6c5sc5ccccc56)n4)ccc32)cc1]

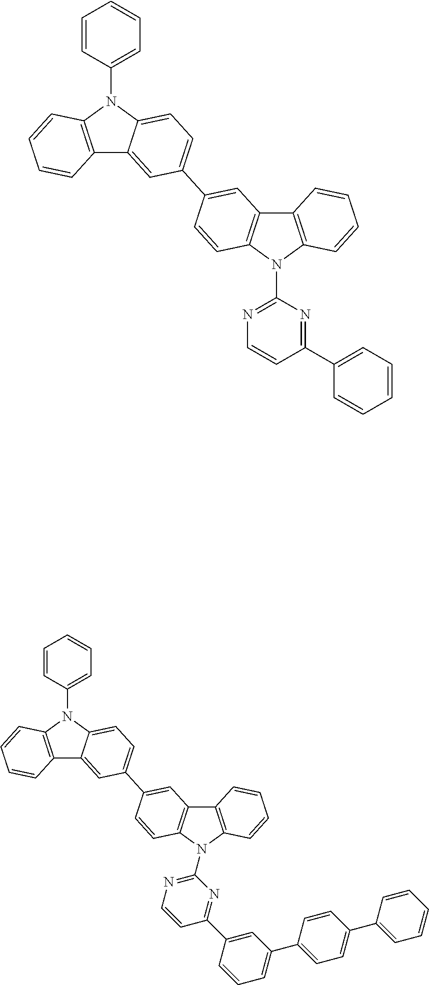 [SMILES: c1ccc(-c2ccnc(-n3c4ccccc4c4cc(-c5ccc6c(c5)c5ccccc5n6-c5ccccc5)ccc43)n2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

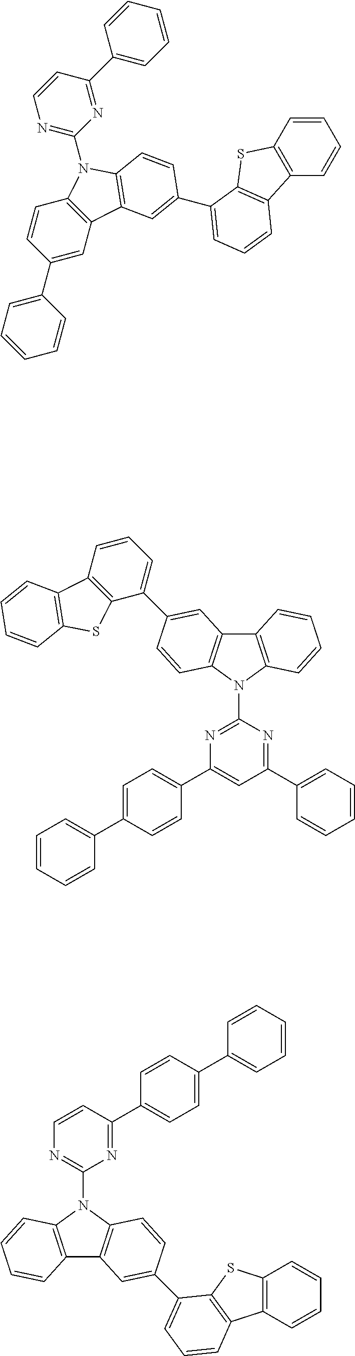 [SMILES: c1ccc(-c2ccc3c(c2)c2cc(-c4cccc5c4sc4ccccc45)ccc2n3-c2nccc(-c3ccccc3)n2)cc1 ; c1ccc(-c2ccc(-c3cc(-c4ccccc4)nc(-n4c5ccccc5c5cc(-c6cccc7c6sc6ccccc67)ccc54)n3)cc2)cc1 ; c1ccc(-c2ccc(-c3ccnc(-n4c5ccccc5c5cc(-c6cccc7c6sc6ccccc67)ccc54)n3)cc2)cc1]

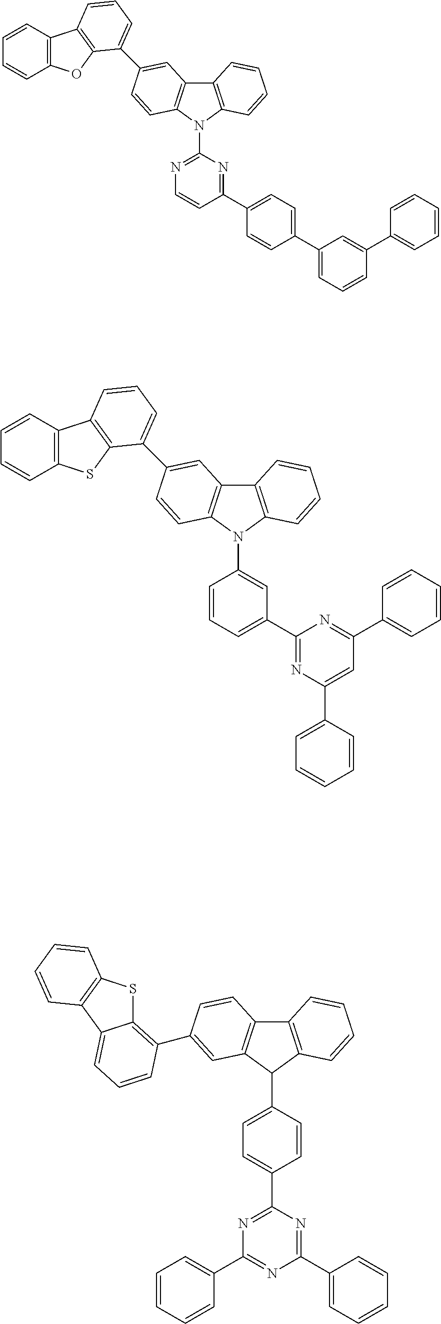 [SMILES: c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2cc(-c3ccccc3)nc(-c3cccc(-n4c5ccccc5c5cc(-c6cccc7c6sc6ccccc67)ccc54)c3)n2)cc1 ; c1ccc(-c2nc(-c3ccccc3)nc(-c3ccc(C4c5ccccc5-c5ccc(-c6cccc7c6sc6ccccc67)cc54)cc3)n2)cc1]

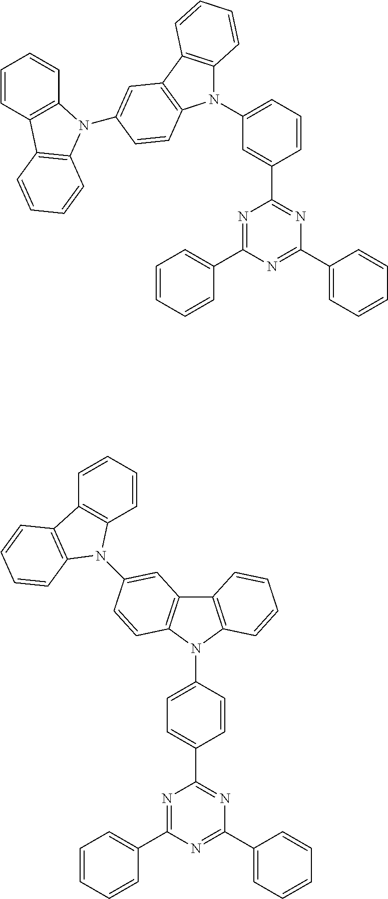 [SMILES: c1ccc(-c2nc(-c3ccccc3)nc(-c3cccc(-n4c5ccccc5c5cc(-n6c7ccccc7c7ccccc76)ccc54)c3)n2)cc1 ; c1ccc(-c2nc(-c3ccccc3)nc(-c3ccc(-n4c5ccccc5c5cc(-n6c7ccccc7c7ccccc76)ccc54)cc3)n2)cc1]

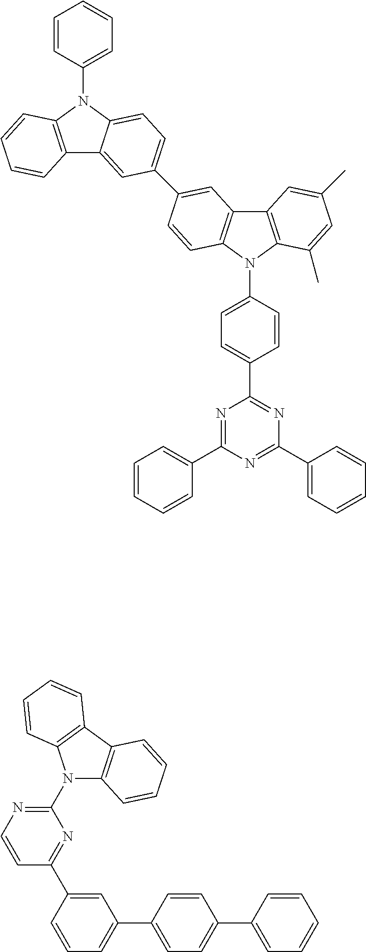 [SMILES: Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1 ; c1ccc(-c2ccc(-c3cccc(-c4ccnc(-n5c6ccccc6c6ccccc65)n4)c3)cc2)cc1]

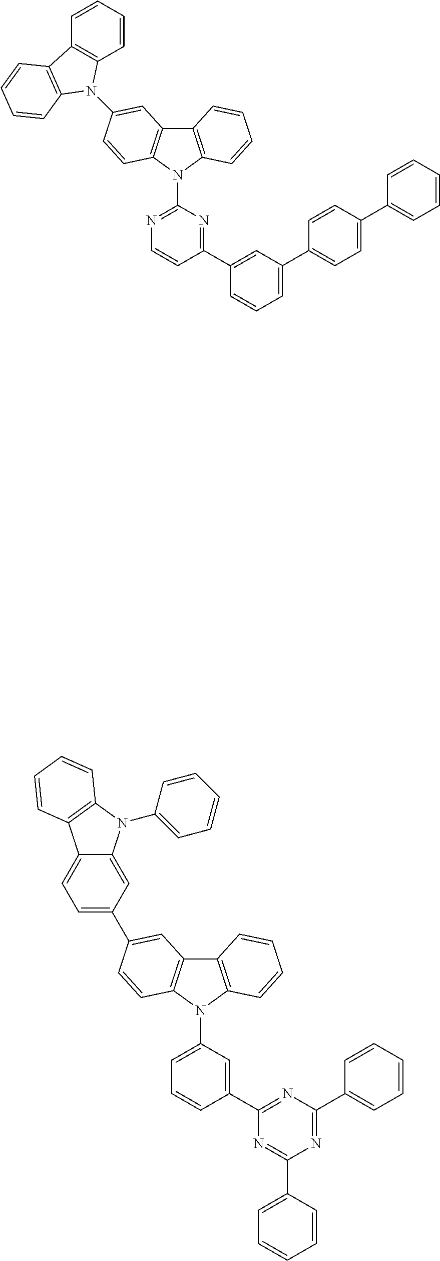 [SMILES: c1ccc(-c2ccc(-c3cccc(-c4ccnc(-n5c6ccccc6c6cc(-n7c8ccccc8c8ccccc87)ccc65)n4)c3)cc2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1]

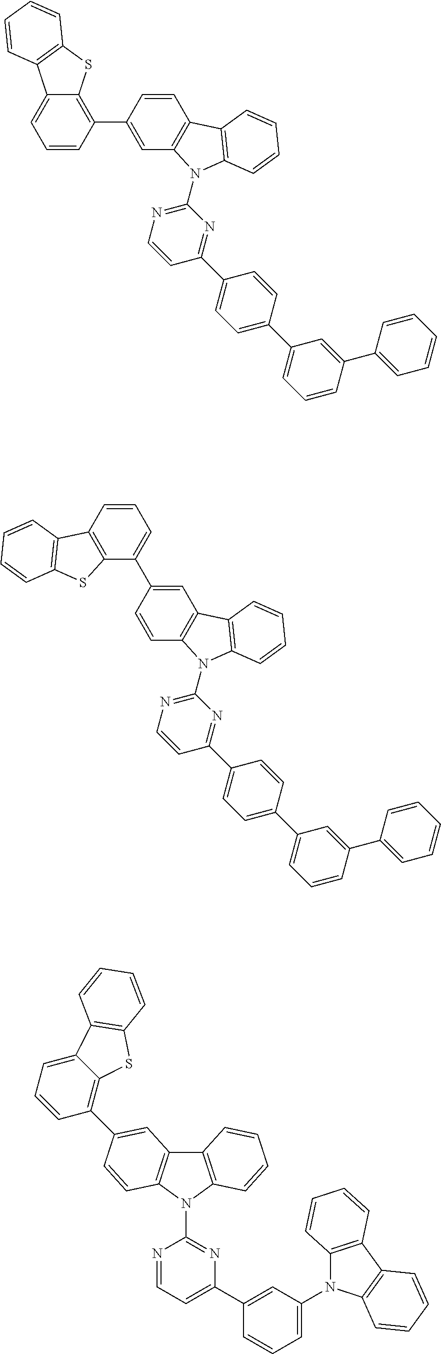 [SMILES: c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccc(-c4ccnc(-n5c6ccccc6c6cc(-c7cccc8c7sc7ccccc78)ccc65)n4)cc3)c2)cc1 ; c1cc(-c2ccnc(-n3c4ccccc4c4cc(-c5cccc6c5sc5ccccc56)ccc43)n2)cc(-n2c3ccccc3c3ccccc32)c1]

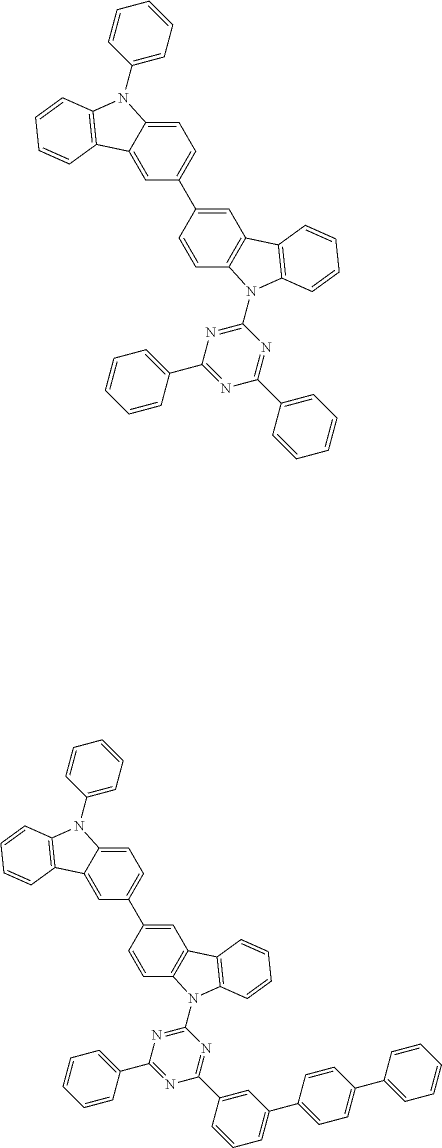 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1]

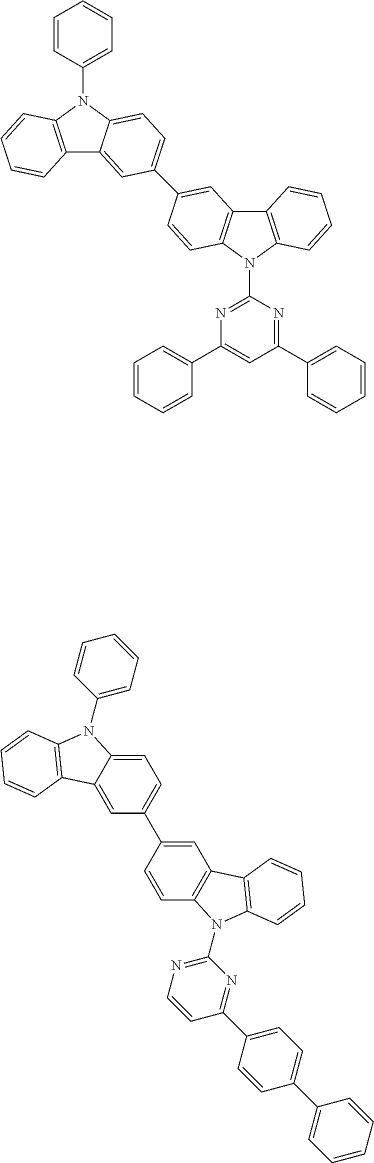 [SMILES: c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2ccc(-c3ccnc(-n4c5ccccc5c5cc(-c6ccc7c(c6)c6ccccc6n7-c6ccccc6)ccc54)n3)cc2)cc1]

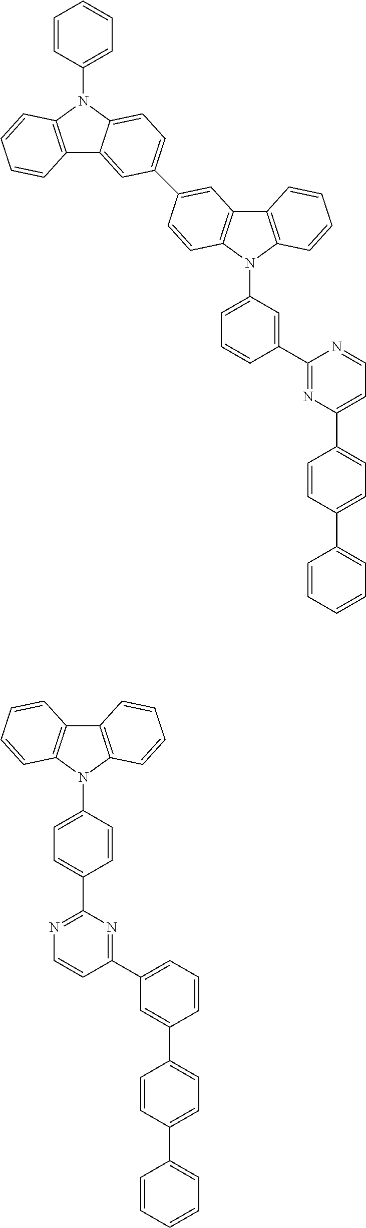 [SMILES: c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2ccc(-c3cccc(-c4ccnc(-c5ccc(-n6c7ccccc7c7ccccc76)cc5)n4)c3)cc2)cc1]

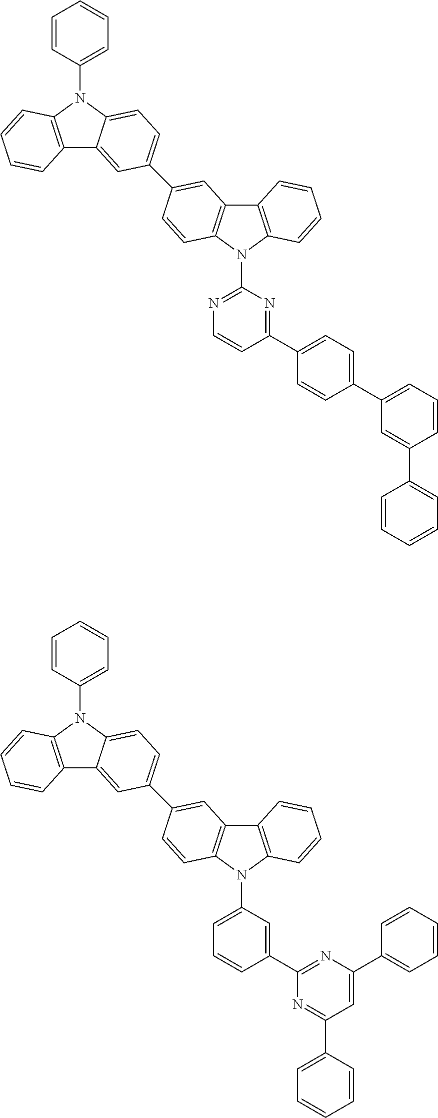 [SMILES: c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1]

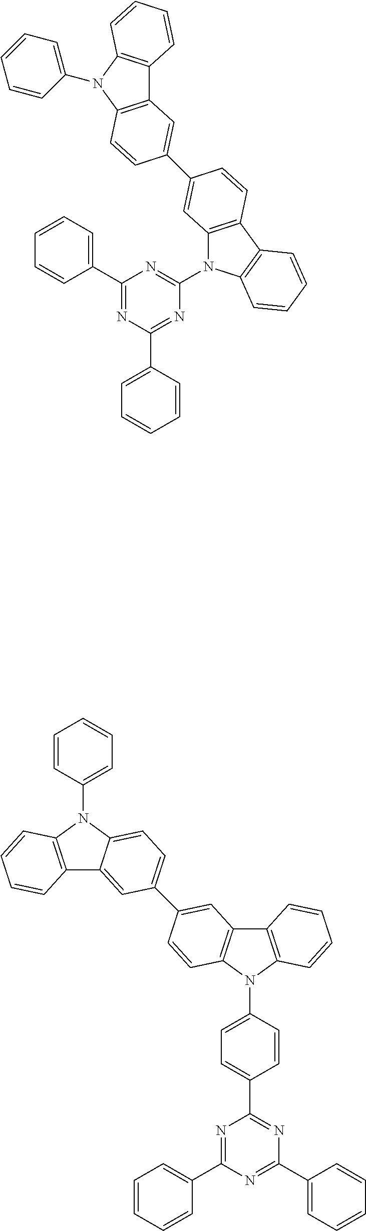 [SMILES: c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

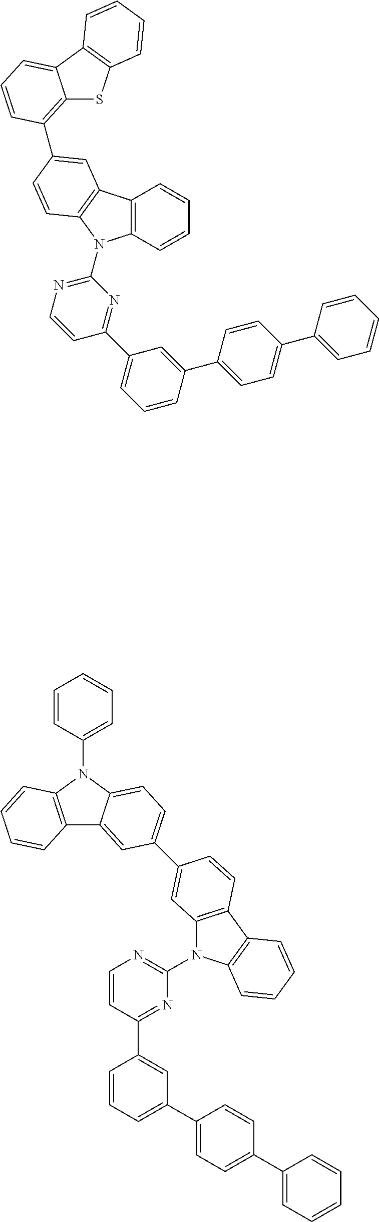 [SMILES: c1ccc(-c2ccc(-c3cccc(-c4ccnc(-n5c6ccccc6c6cc(-c7cccc8c7sc7ccccc78)ccc65)n4)c3)cc2)cc1 ; c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1]

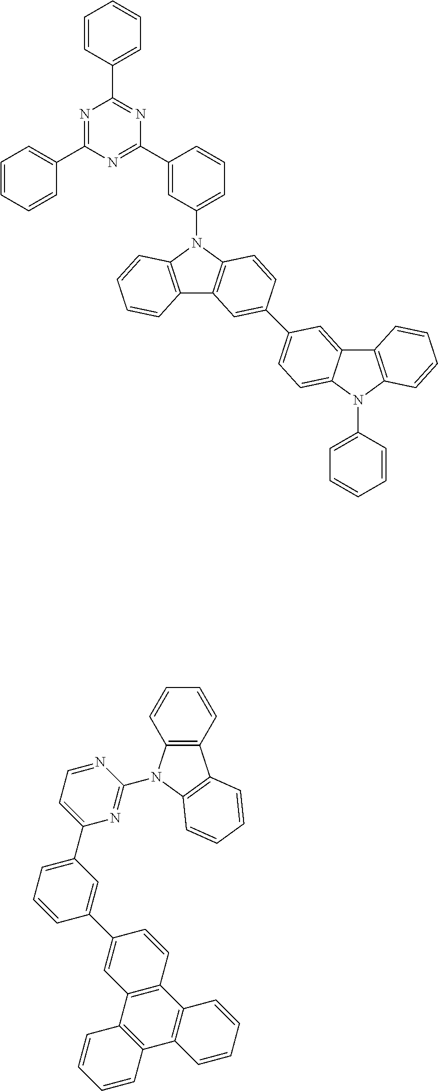 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1cc(-c2ccc3c4ccccc4c4ccccc4c3c2)cc(-c2ccnc(-n3c4ccccc4c4ccccc43)n2)c1]

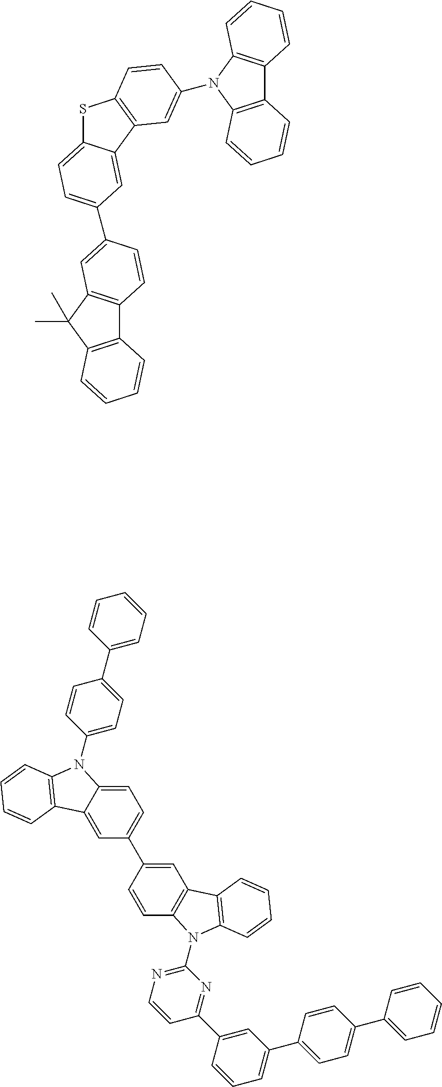 [SMILES: CC1(C)c2ccccc2-c2ccc(-c3ccc4sc5ccc(-n6c7ccccc7c7ccccc76)cc5c4c3)cc21 ; c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1]

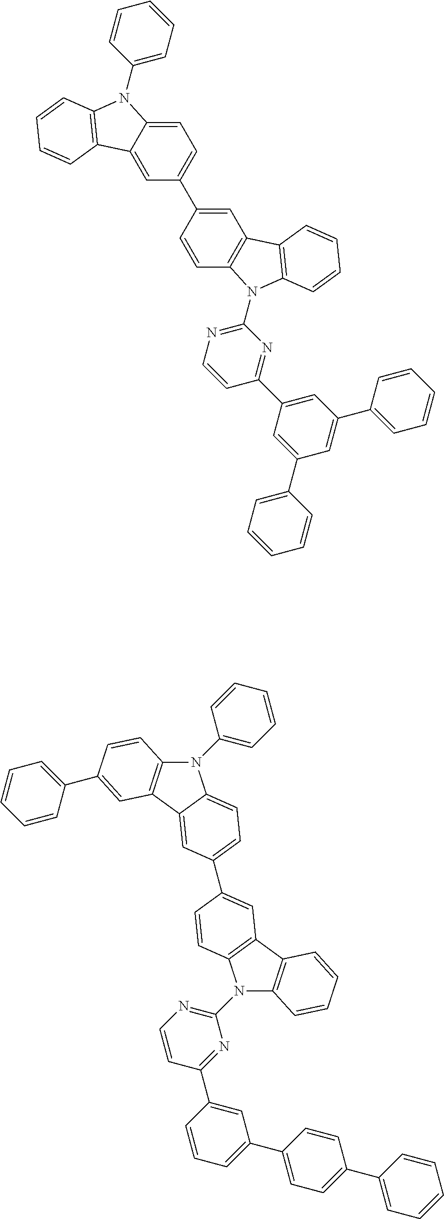 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1]

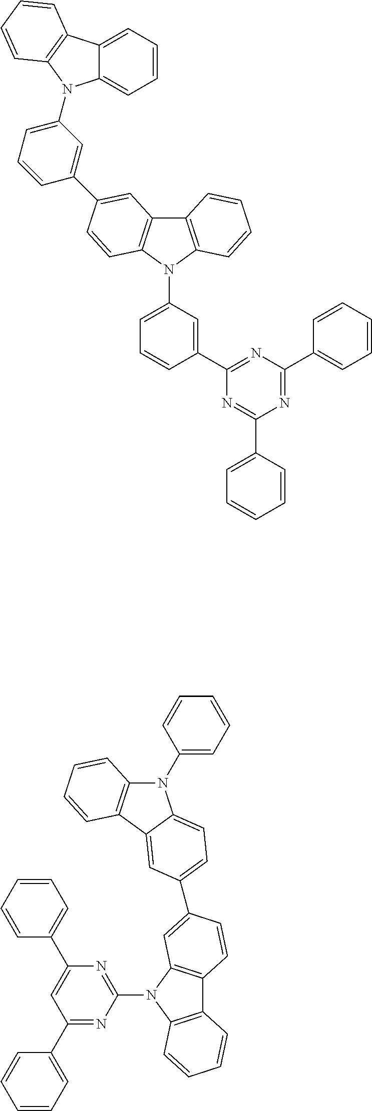 [SMILES: c1ccc(-c2nc(-c3ccccc3)nc(-c3cccc(-n4c5ccccc5c5cc(-c6cccc(-n7c8ccccc8c8ccccc87)c6)ccc54)c3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1]

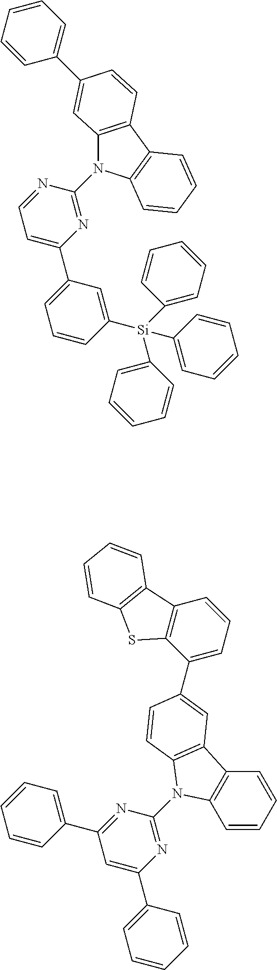 [SMILES: c1ccc(-c2ccc3c4ccccc4n(-c4nccc(-c5cccc([Si](c6ccccc6)(c6ccccc6)c6ccccc6)c5)n4)c3c2)cc1 ; c1ccc(-c2cc(-c3ccccc3)nc(-n3c4ccccc4c4cc(-c5cccc6c5sc5ccccc56)ccc43)n2)cc1]

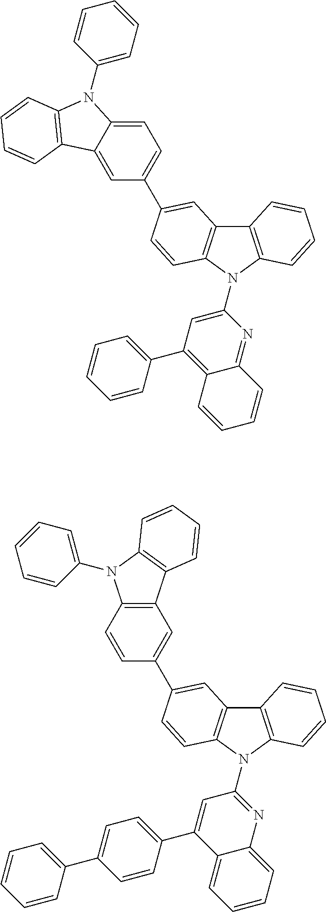 [SMILES: c1ccc(-c2cc(-n3c4ccccc4c4cc(-c5ccc6c(c5)c5ccccc5n6-c5ccccc5)ccc43)nc3ccccc23)cc1 ; c1ccc(-c2ccc(-c3cc(-n4c5ccccc5c5cc(-c6ccc7c(c6)c6ccccc6n7-c6ccccc6)ccc54)nc4ccccc34)cc2)cc1]

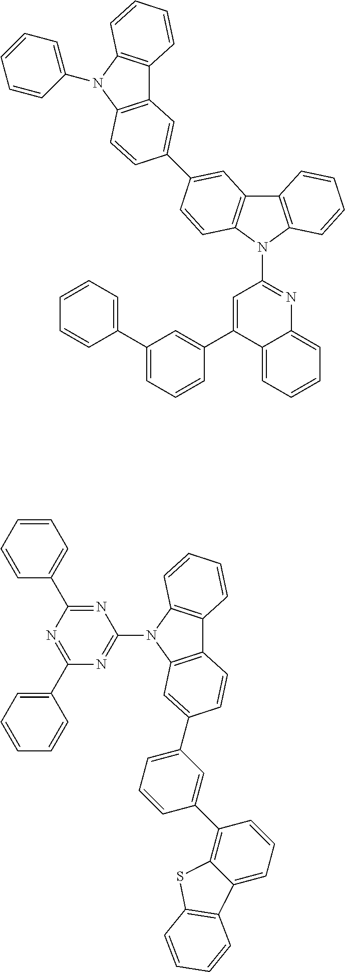 [SMILES: c1ccc(-c2cccc(-c3cc(-n4c5ccccc5c5cc(-c6ccc7c(c6)c6ccccc6n7-c6ccccc6)ccc54)nc4ccccc34)c2)cc1 ; c1ccc(-c2nc(-c3ccccc3)nc(-n3c4ccccc4c4ccc(-c5cccc(-c6cccc7c6sc6ccccc67)c5)cc43)n2)cc1]

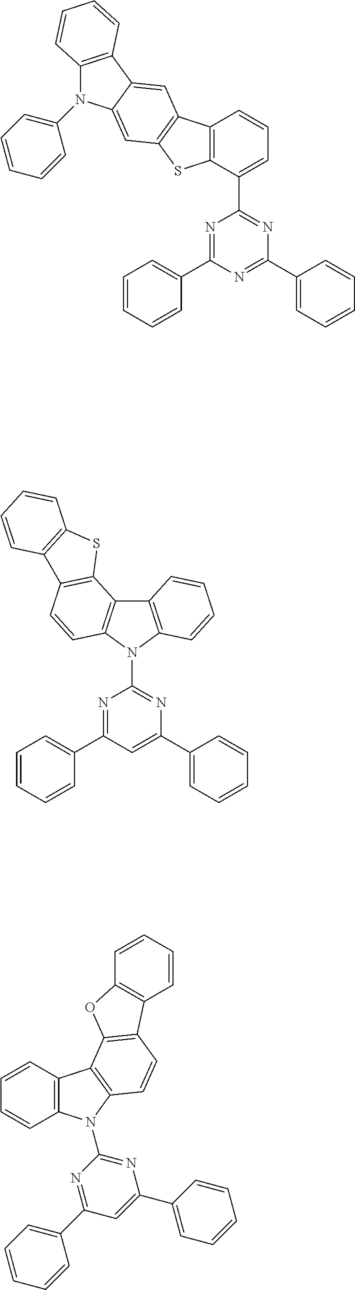 [SMILES: c1ccc(-c2nc(-c3ccccc3)nc(-c3cccc4c3sc3cc5c(cc34)c3ccccc3n5-c3ccccc3)n2)cc1 ; c1ccc(-c2cc(-c3ccccc3)nc(-n3c4ccccc4c4c5sc6ccccc6c5ccc43)n2)cc1 ; c1ccc(-c2cc(-c3ccccc3)nc(-n3c4ccccc4c4c5oc6ccccc6c5ccc43)n2)cc1]

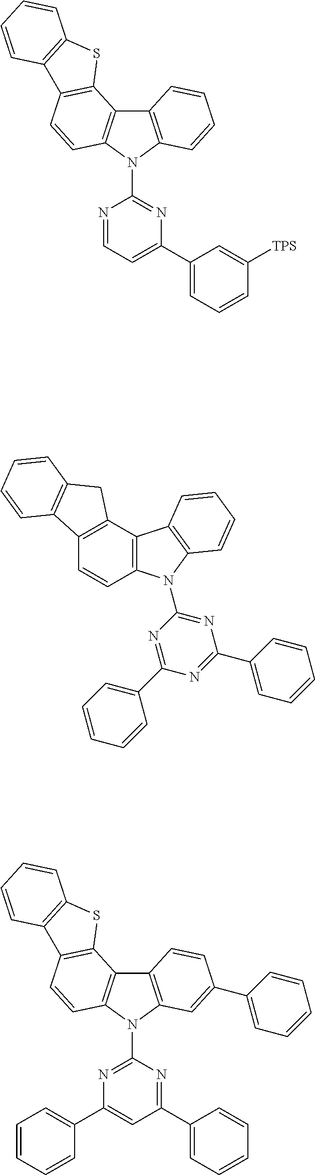

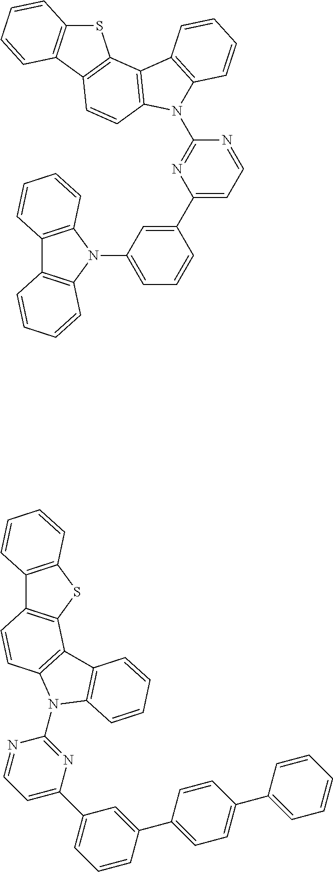 [SMILES: c1cc(-c2ccnc(-n3c4ccccc4c4c5sc6ccccc6c5ccc43)n2)cc(-n2c3ccccc3c3ccccc32)c1 ; c1ccc(-c2ccc(-c3cccc(-c4ccnc(-n5c6ccccc6c6c7sc8ccccc8c7ccc65)n4)c3)cc2)cc1]

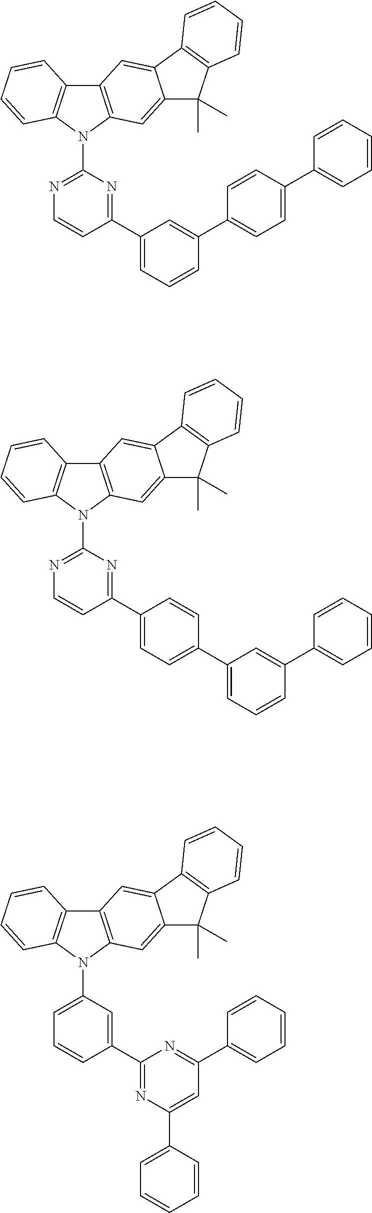 [SMILES: CC1(C)c2ccccc2-c2cc3c4ccccc4n(-c4nccc(-c5cccc(-c6ccc(-c7ccccc7)cc6)c5)n4)c3cc21 ; CC1(C)c2ccccc2-c2cc3c4ccccc4n(-c4nccc(-c5ccc(-c6cccc(-c7ccccc7)c6)cc5)n4)c3cc21 ; CC1(C)c2ccccc2-c2cc3c4ccccc4n(-c4cccc(-c5nc(-c6ccccc6)cc(-c6ccccc6)n5)c4)c3cc21]

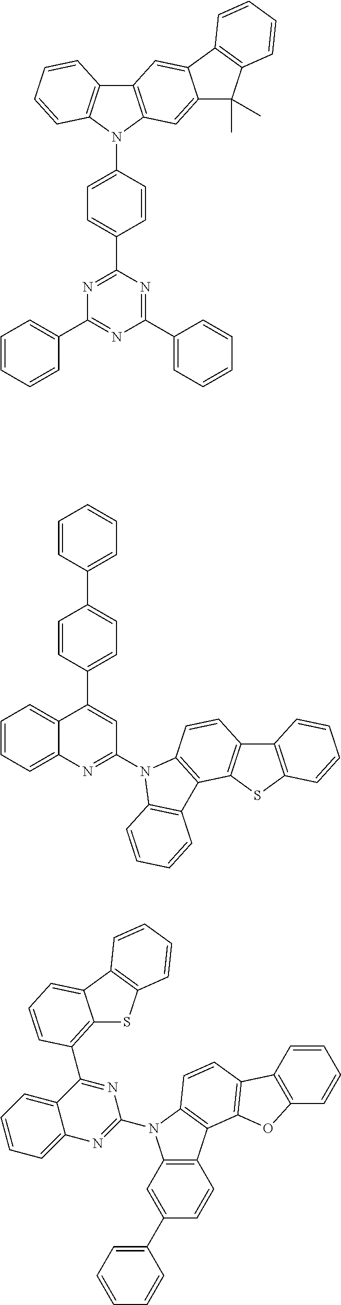 [SMILES: CC1(C)c2ccccc2-c2cc3c4ccccc4n(-c4ccc(-c5nc(-c6ccccc6)nc(-c6ccccc6)n5)cc4)c3cc21 ; c1ccc(-c2ccc(-c3cc(-n4c5ccccc5c5c6sc7ccccc7c6ccc54)nc4ccccc34)cc2)cc1 ; c1ccc(-c2ccc3c4c5oc6ccccc6c5ccc4n(-c4nc(-c5cccc6c5sc5ccccc56)c5ccccc5n4)c3c2)cc1]

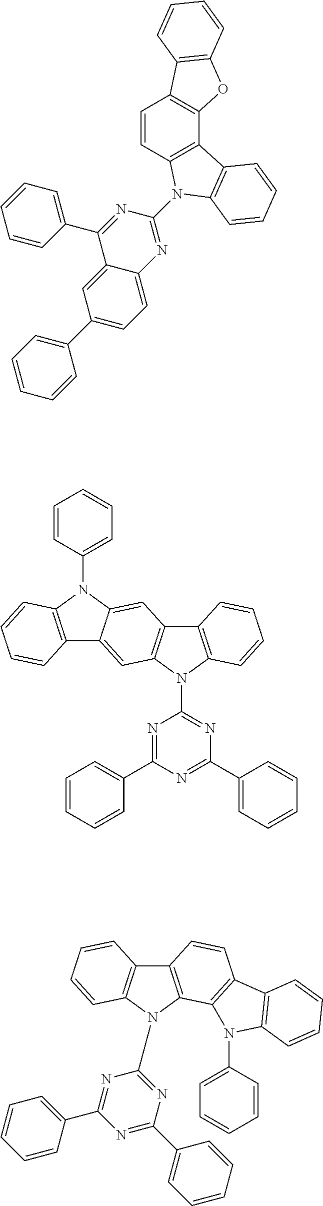 [SMILES: c1ccc(-c2ccc3nc(-n4c5ccccc5c5c6oc7ccccc7c6ccc54)nc(-c4ccccc4)c3c2)cc1 ; c1ccc(-c2nc(-c3ccccc3)nc(-n3c4ccccc4c4cc5c(cc43)c3ccccc3n5-c3ccccc3)n2)cc1 ; c1ccc(-c2nc(-c3ccccc3)nc(-n3c4ccccc4c4ccc5c6ccccc6n(-c6ccccc6)c5c43)n2)cc1]

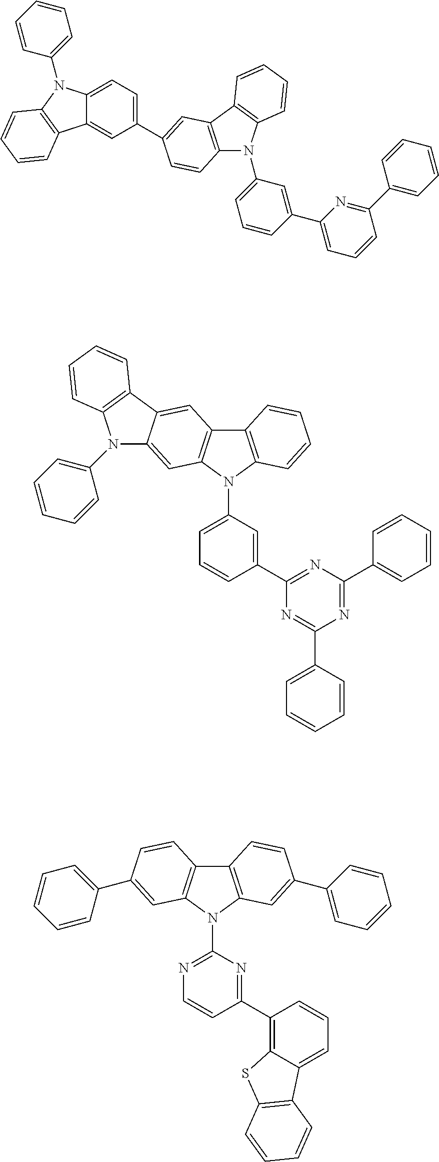 [SMILES: c1ccc(-c2cccc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-c3cccc(-n4c5ccccc5c5cc6c7ccccc7n(-c7ccccc7)c6cc54)c3)n2)cc1 ; c1ccc(-c2ccc3c4ccc(-c5ccccc5)cc4n(-c4nccc(-c5cccc6c5sc5ccccc56)n4)c3c2)cc1]

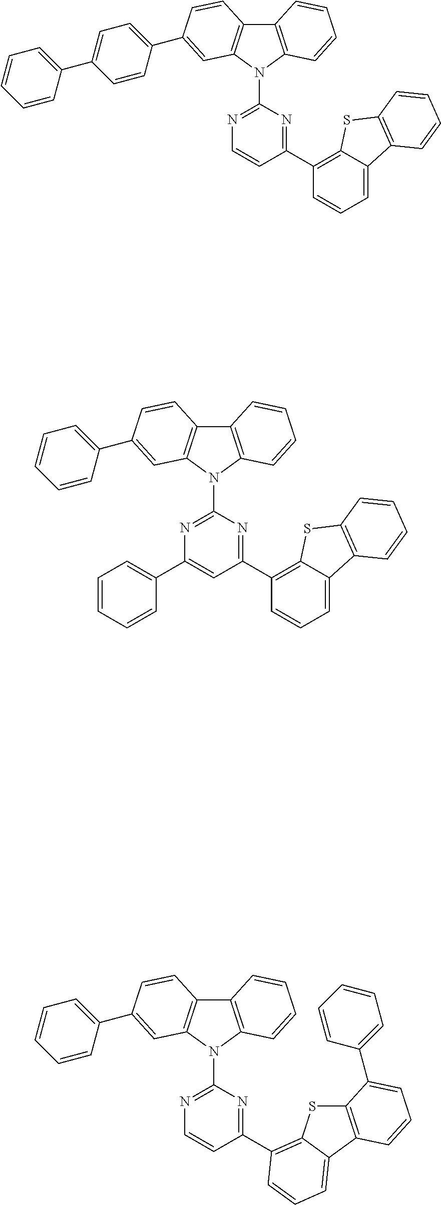 [SMILES: c1ccc(-c2ccc(-c3ccc4c5ccccc5n(-c5nccc(-c6cccc7c6sc6ccccc67)n5)c4c3)cc2)cc1 ; c1ccc(-c2ccc3c4ccccc4n(-c4nc(-c5ccccc5)cc(-c5cccc6c5sc5ccccc56)n4)c3c2)cc1 ; c1ccc(-c2ccc3c4ccccc4n(-c4nccc(-c5cccc6c5sc5c(-c7ccccc7)cccc56)n4)c3c2)cc1]

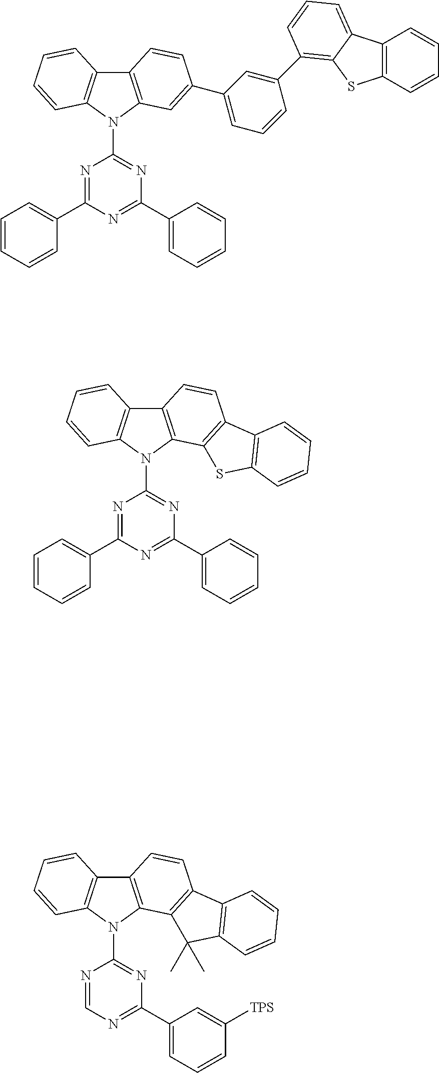

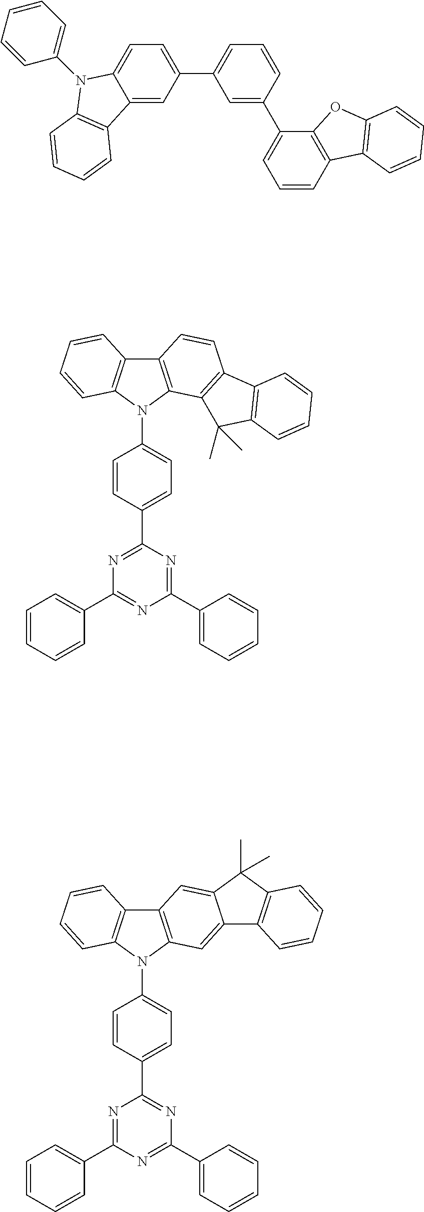 [SMILES: c1ccc(-n2c3ccccc3c3cc(-c4cccc(-c5cccc6c5oc5ccccc56)c4)ccc32)cc1 ; CC1(C)c2ccccc2-c2ccc3c4ccccc4n(-c4ccc(-c5nc(-c6ccccc6)nc(-c6ccccc6)n5)cc4)c3c21 ; CC1(C)c2ccccc2-c2cc3c(cc21)c1ccccc1n3-c1ccc(-c2nc(-c3ccccc3)nc(-c3ccccc3)n2)cc1]

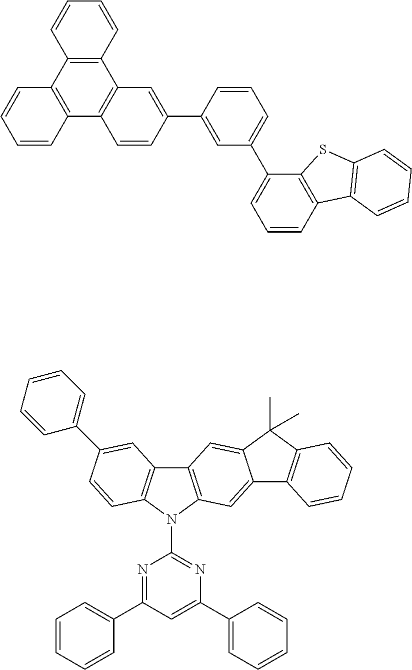 [SMILES: c1cc(-c2ccc3c4ccccc4c4ccccc4c3c2)cc(-c2cccc3c2sc2ccccc23)c1 ; CC1(C)c2ccccc2-c2cc3c(cc21)c1cc(-c2ccccc2)ccc1n3-c1nc(-c2ccccc2)cc(-c2ccccc2)n1]

The dopant comprised in the organic electroluminescent device according to the present invention may be selected from compounds represented by the following formulas 7 to 9.

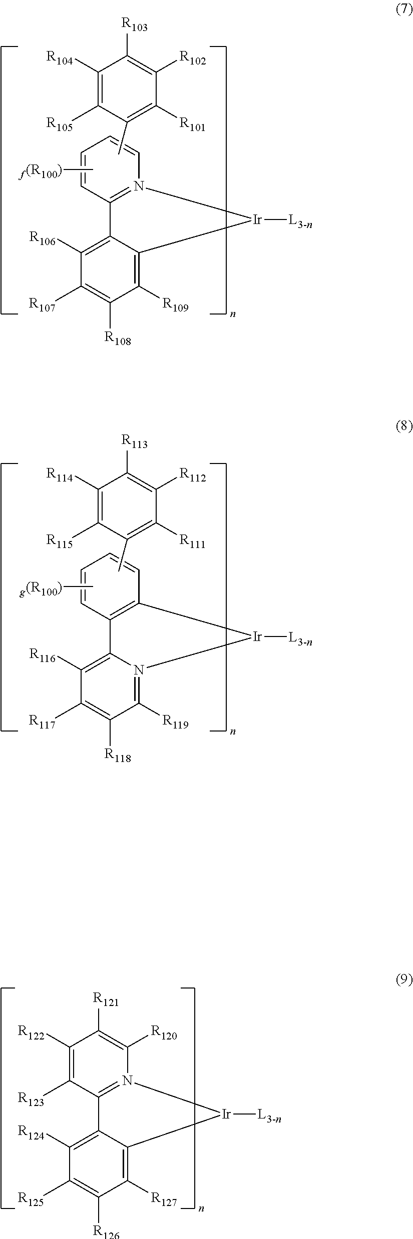

wherein L is selected from the following structures:

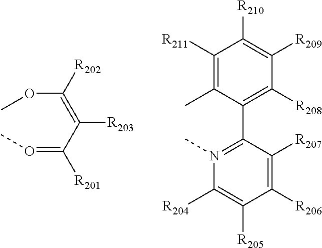

R₁₀₀ represents hydrogen, a substituted or unsubstituted (C1-C30)alkyl group, or a substituted or unsubstituted (C3-C30)cycloalkyl group;

R₁₀₁ to R₁₀₉, and R₁₁₁ to R₁₂₃ each independently represent hydrogen, deuterium, a halogen, a (C1-C30)alkyl group unsubstituted or substituted with halogen(s), a substituted or unsubstituted (C3-C30)cycloalkyl group, a cyano group, or a substituted or unsubstituted (C1-C30)alkoxy group; adjacent substituents of R₁₂₀ to R₁₂₃ may be linked to each other to form a fused ring, e.g. quinoline;

R₁₂₄ to R₁₂₇ each independently represent hydrogen, deuterium, a halogen, a substituted or unsubstituted (C1-C30)alkyl group, or a substituted or unsubstituted (C6-C30)aryl group; where R₁₂₄ to R₁₂₇ are aryl groups, adjacent substituents may be linked to each other to form a fused ring, e.g. fluorene;

R₂₀₁ to R₂₁₁ each independently represent hydrogen, deuterium, a halogen, a (C1-C30)alkyl group unsubstituted or substituted with halogen(s), or a substituted or unsubstituted (C3-C30)cycloalkyl group;

f and g each independently represent an integer of 1 to 3; where f or g is an integer of 2 or more, each of R₁₀₀ may be the same or different; and

n is an integer of 1 to 3.

The dopant materials include the following:

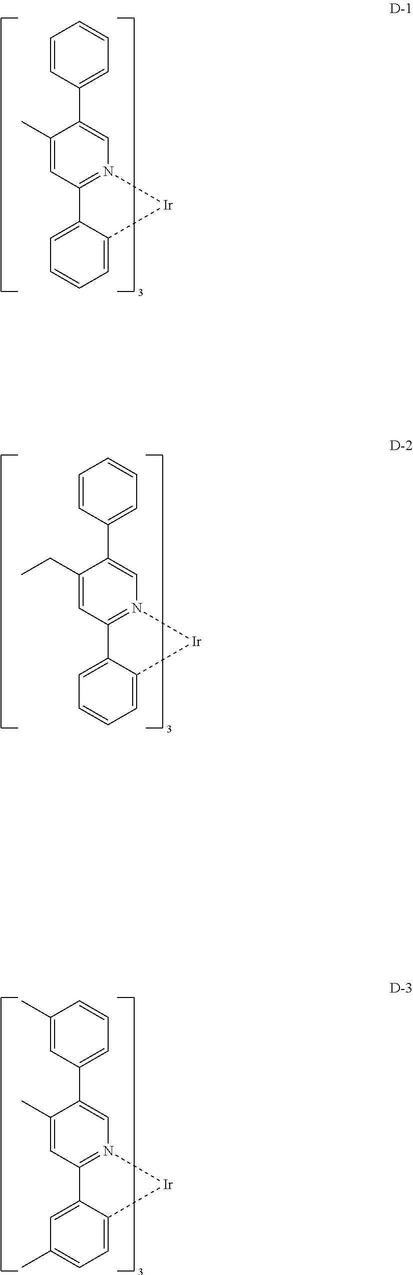

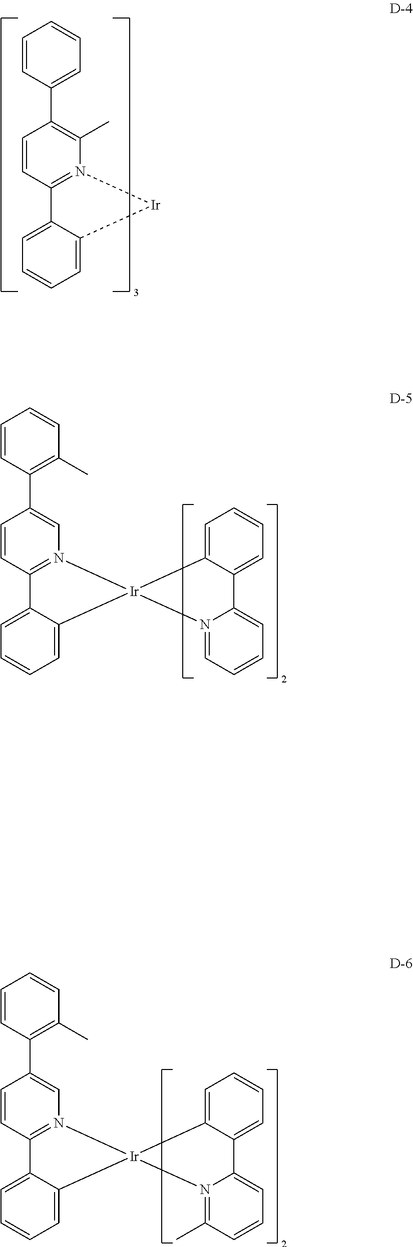

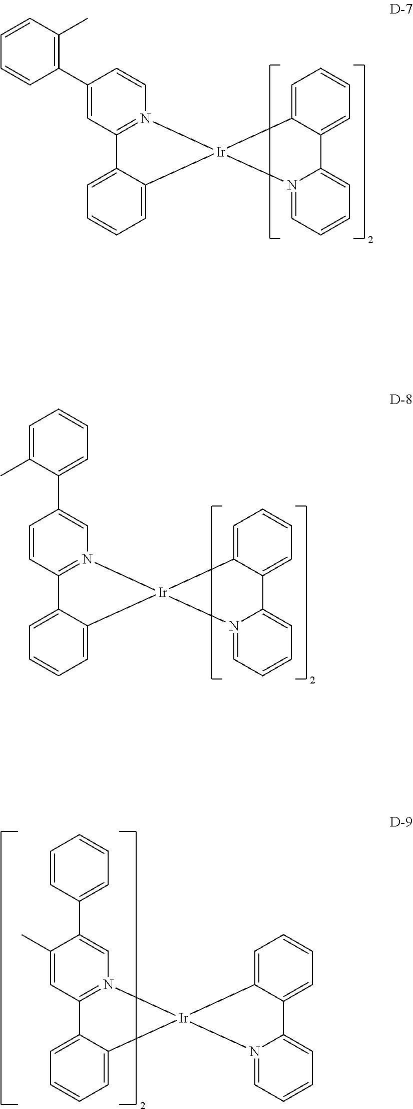

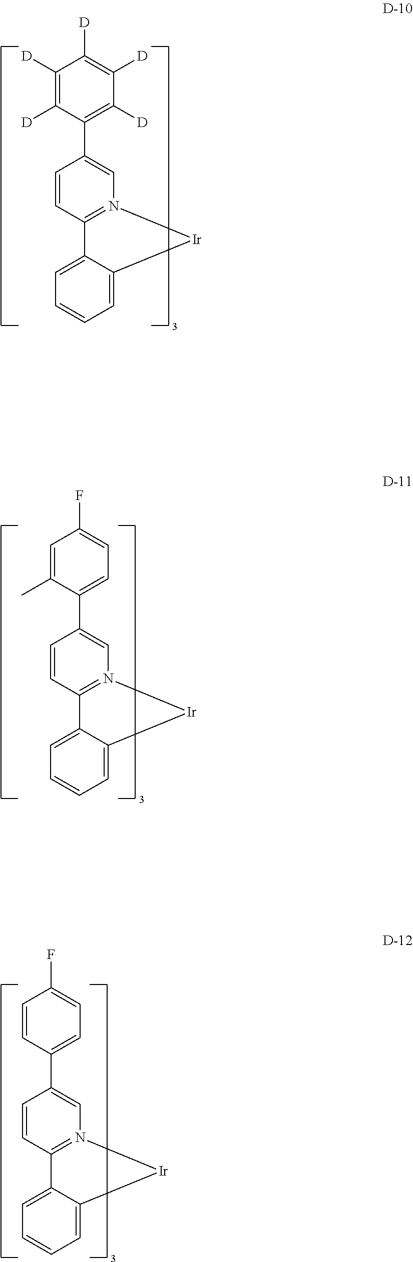

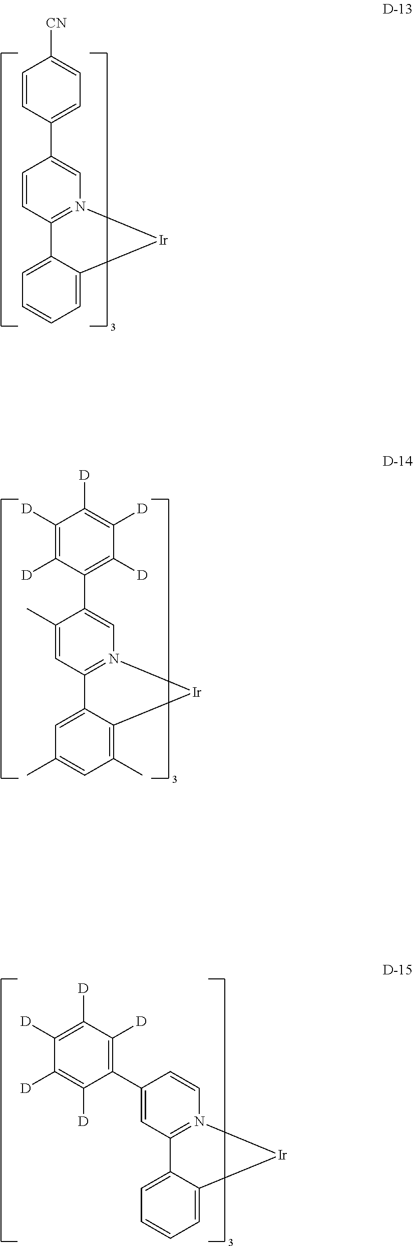

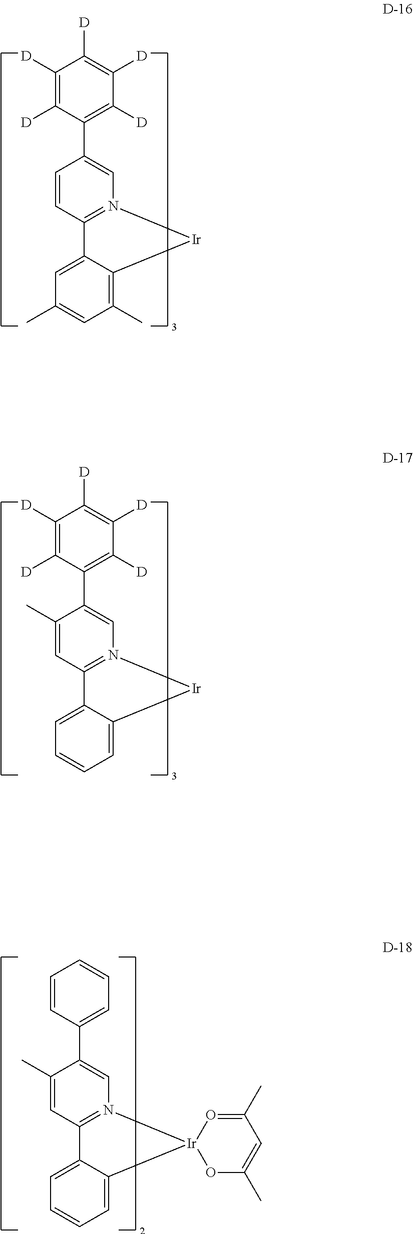

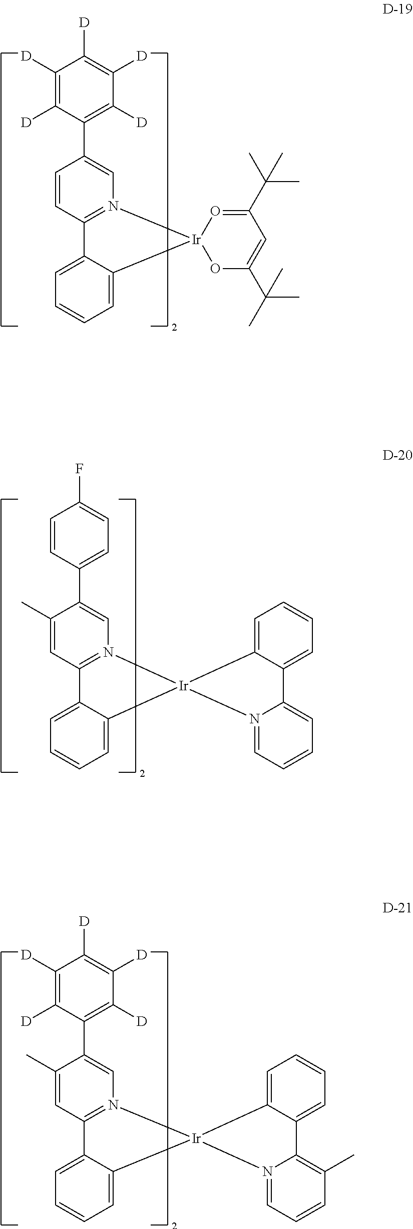

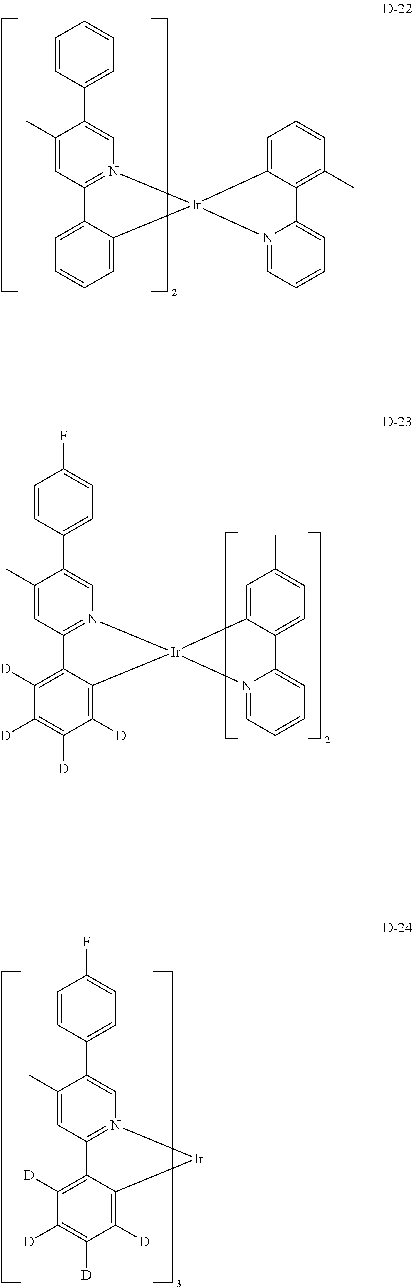

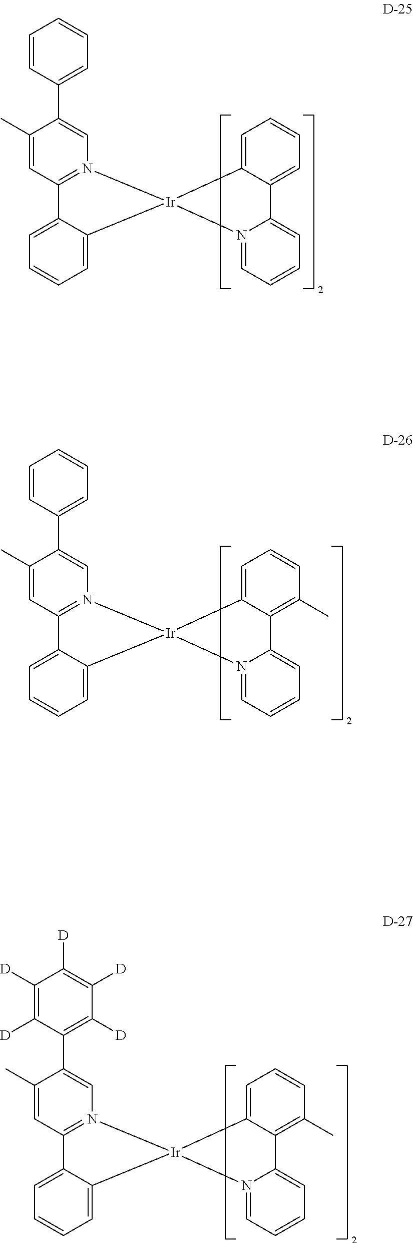

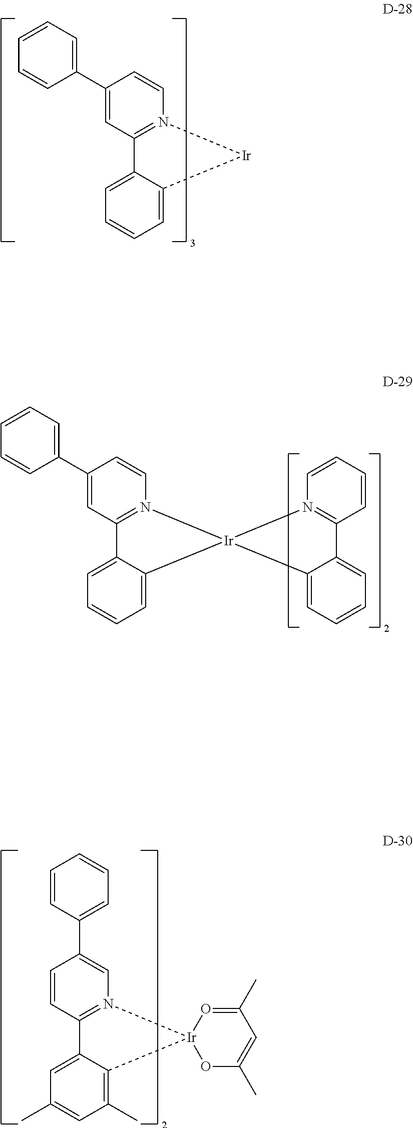

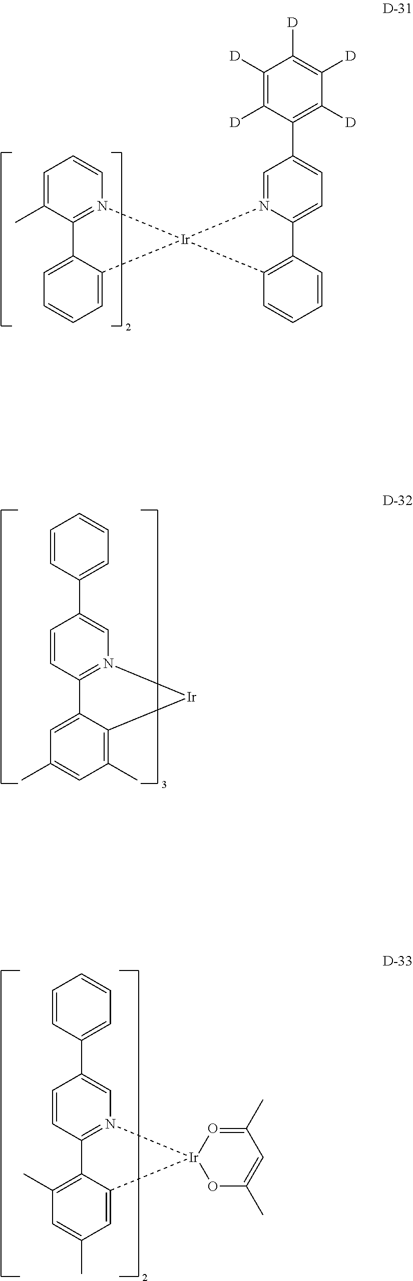

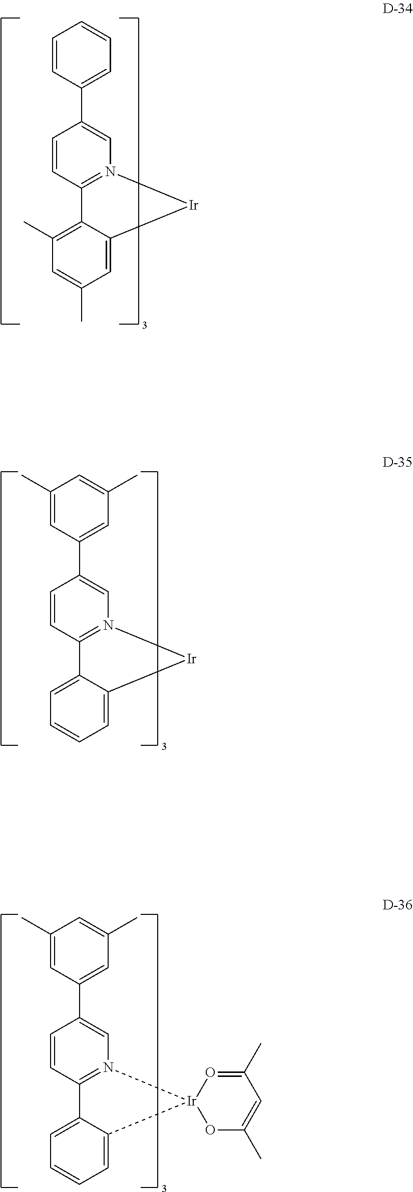

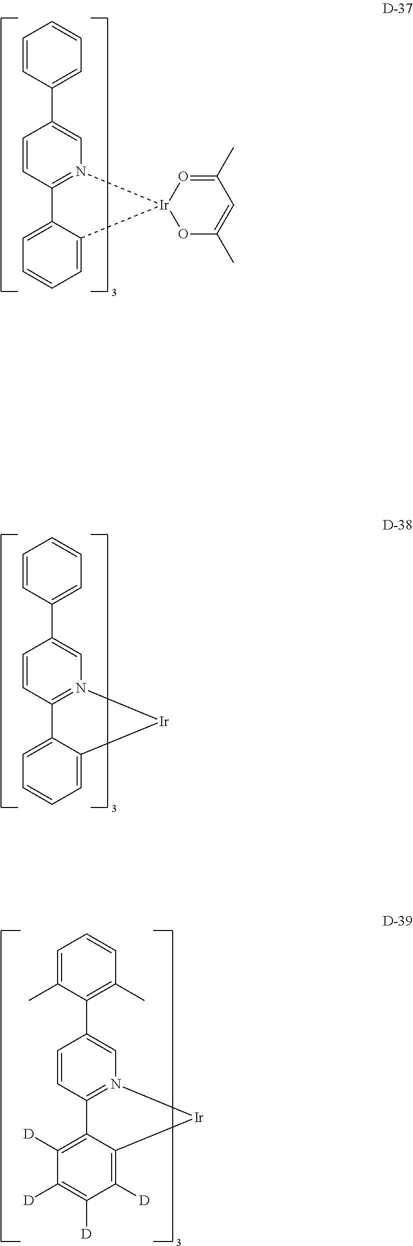

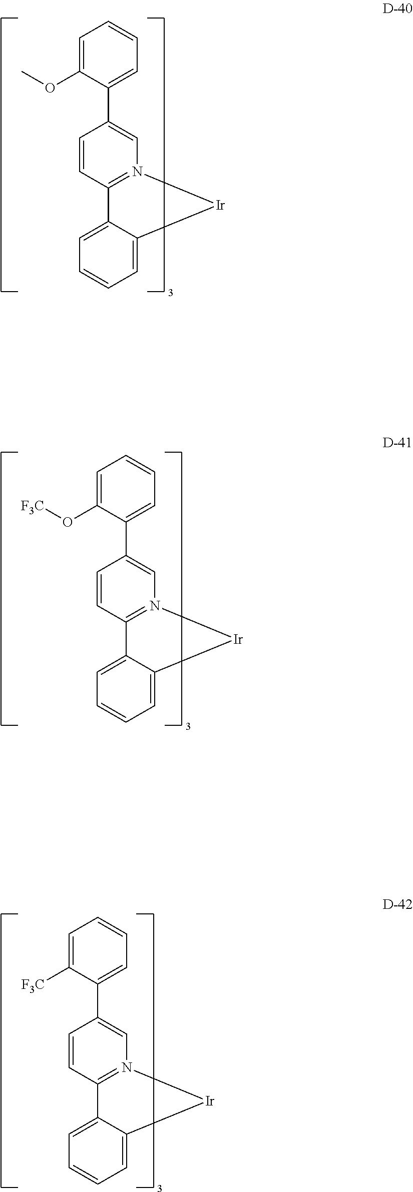

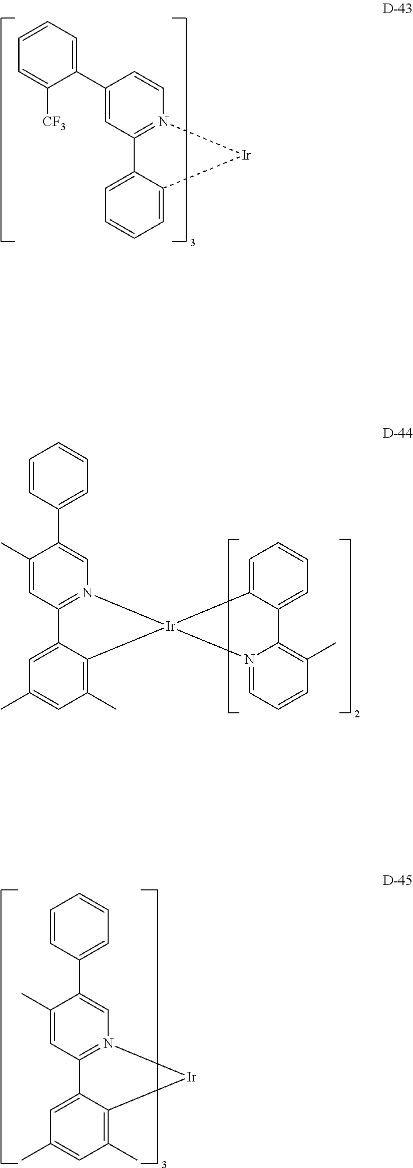

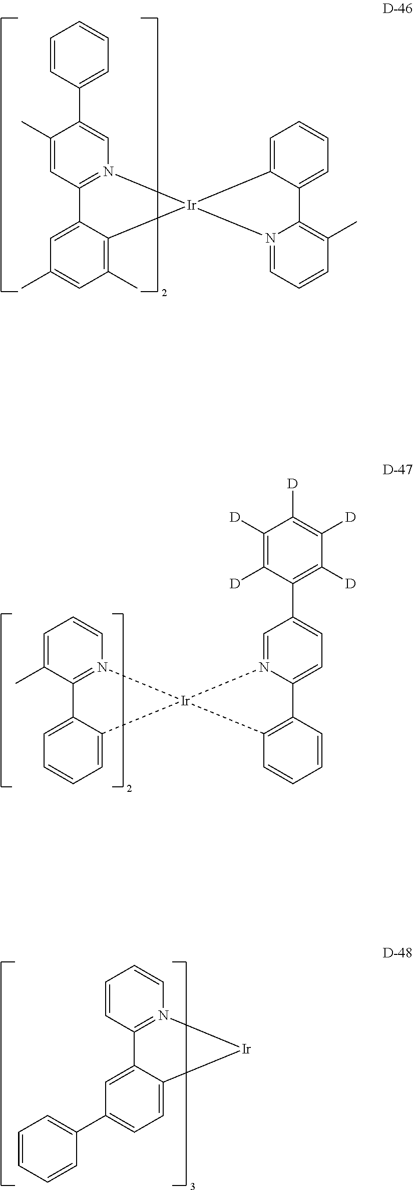

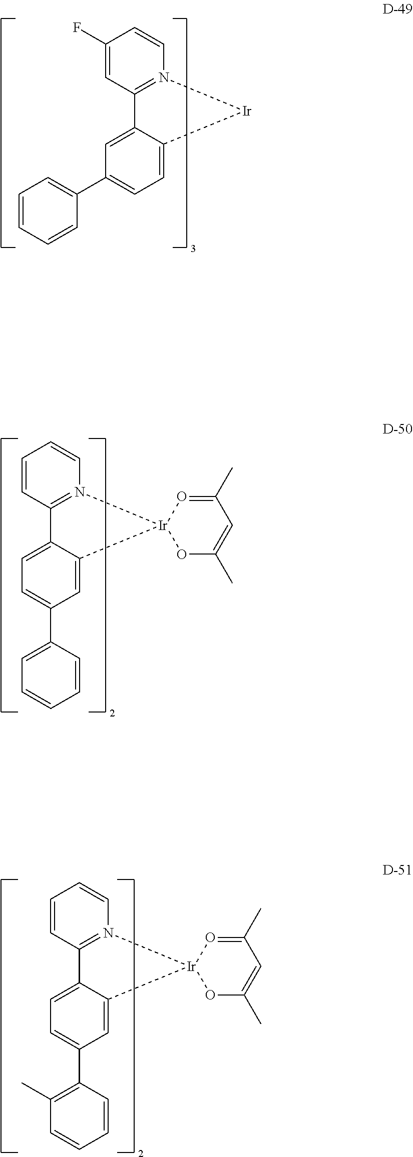

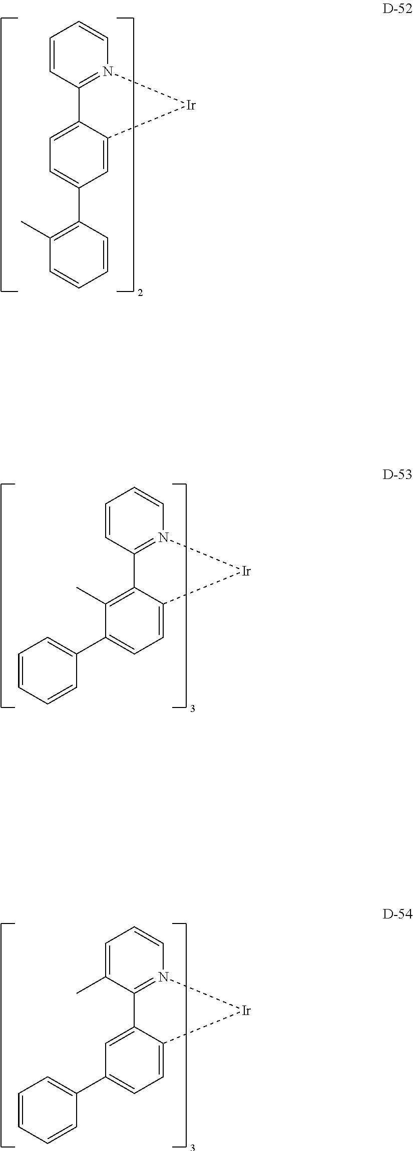

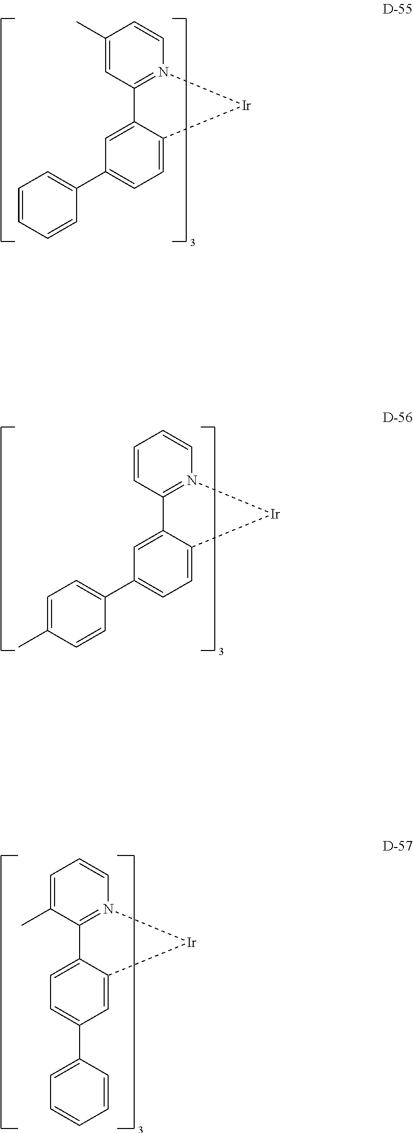

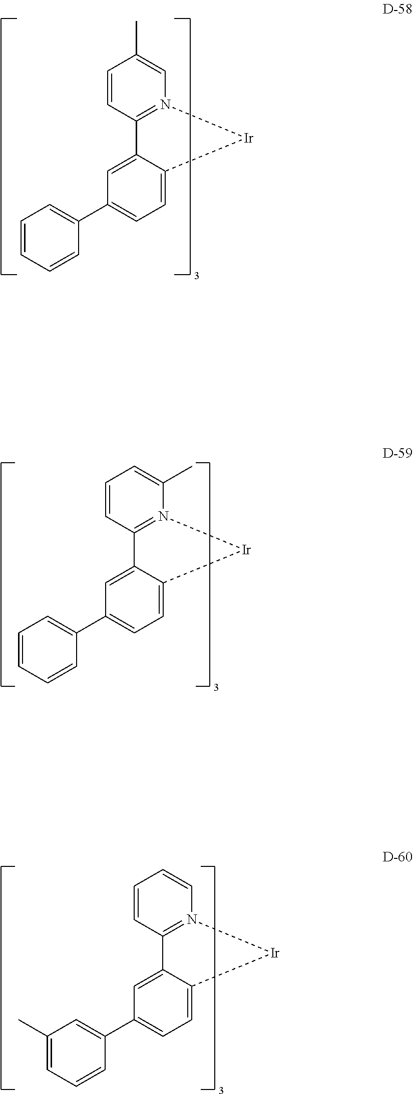

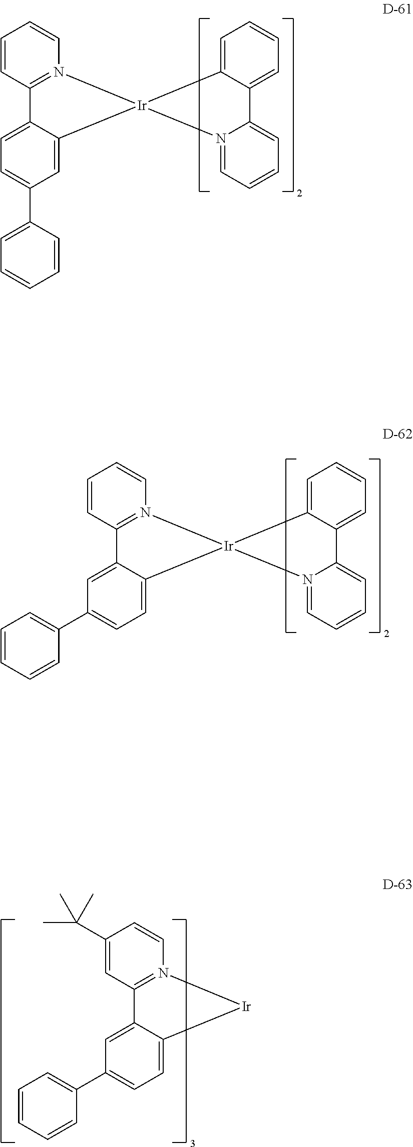

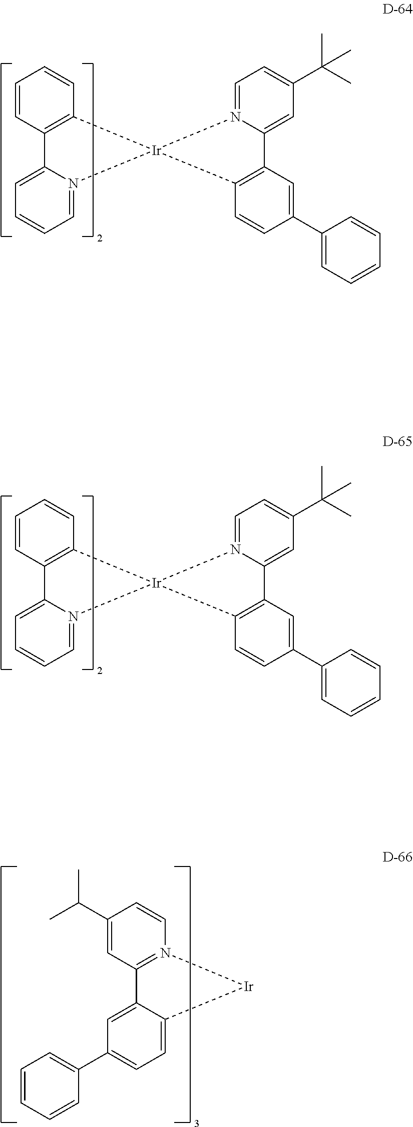

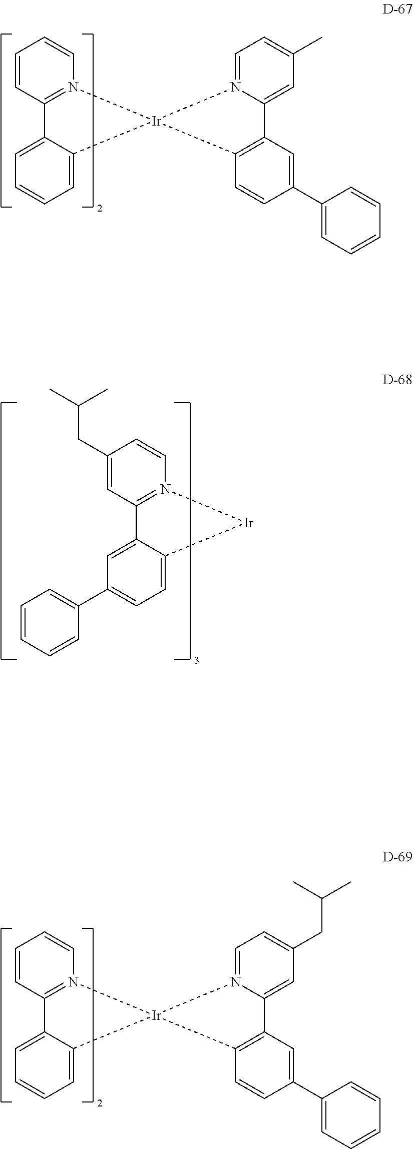

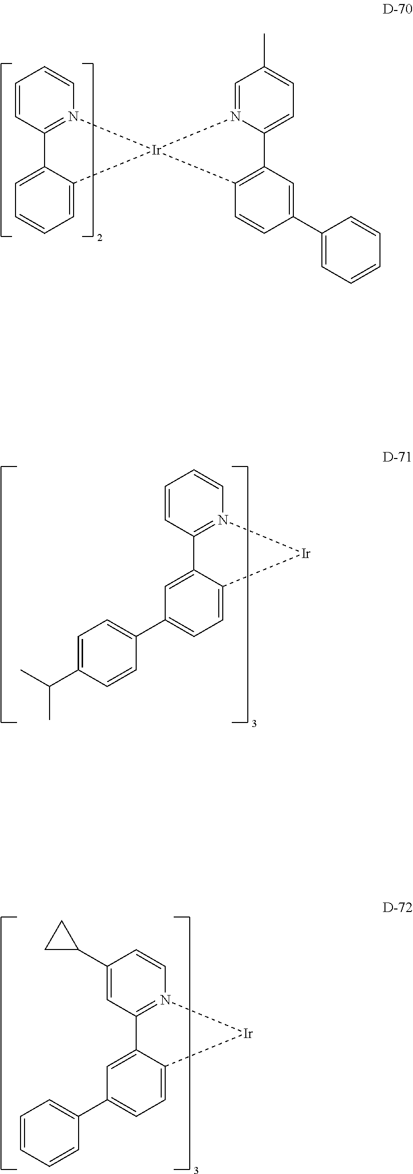

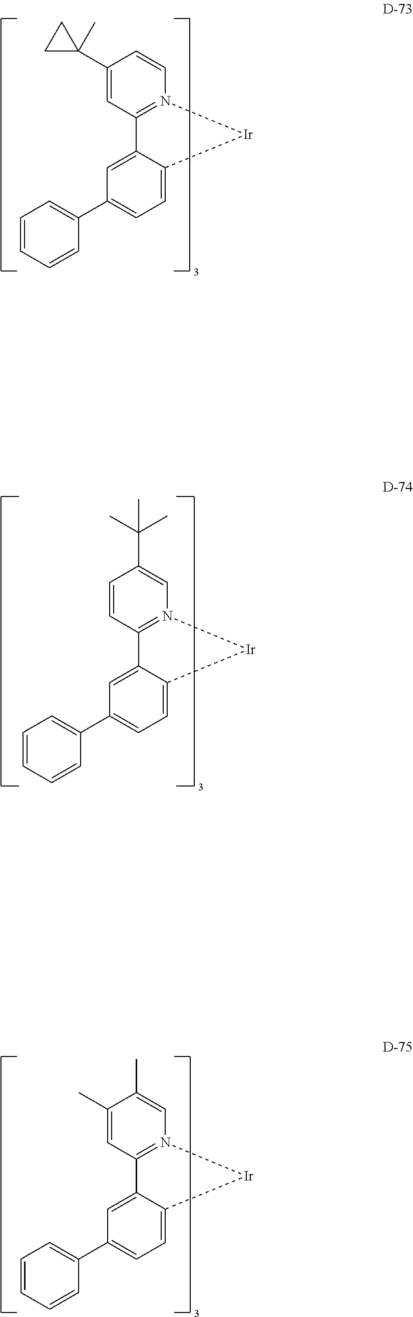

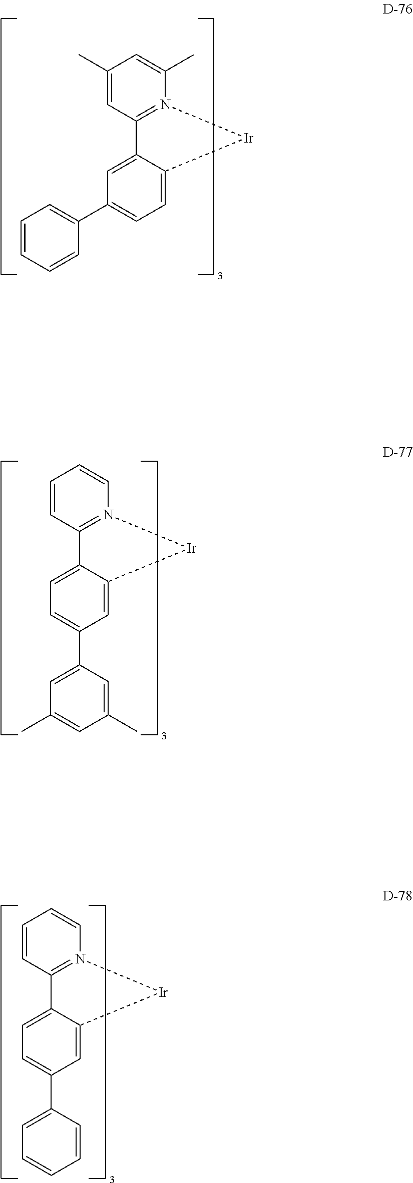

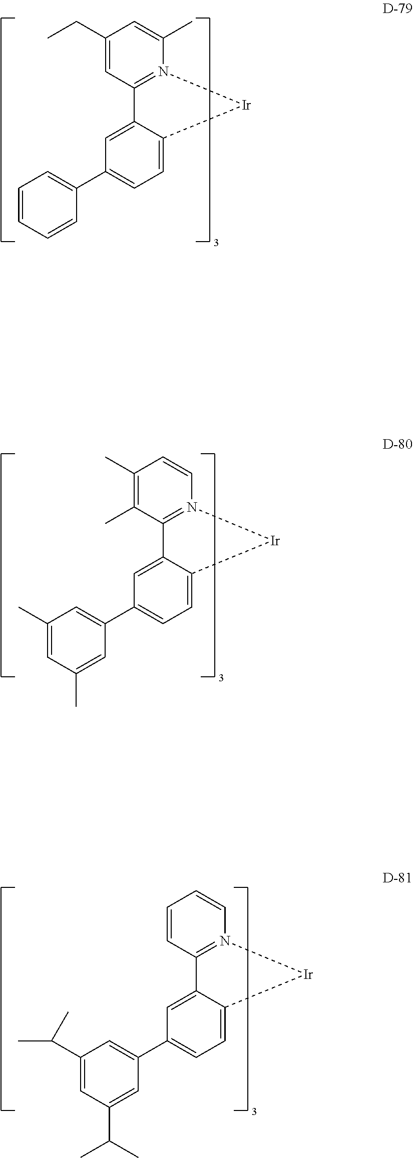

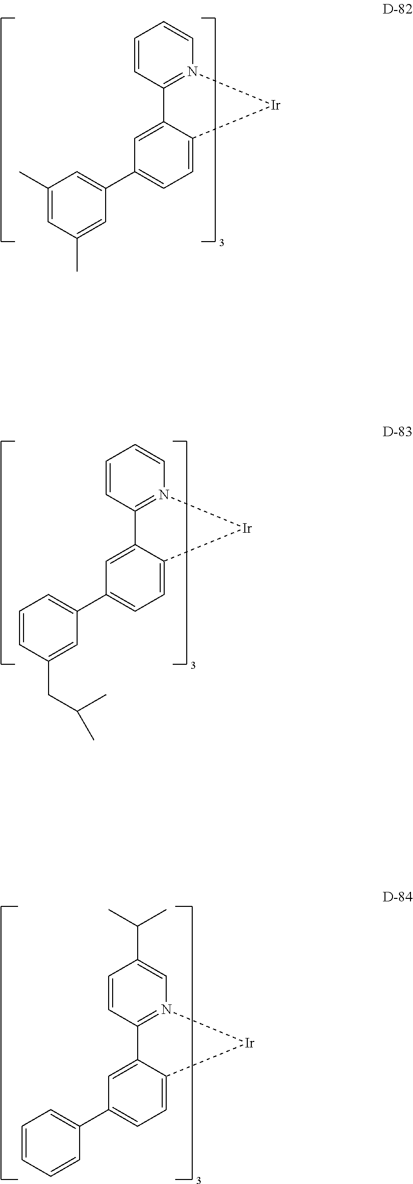

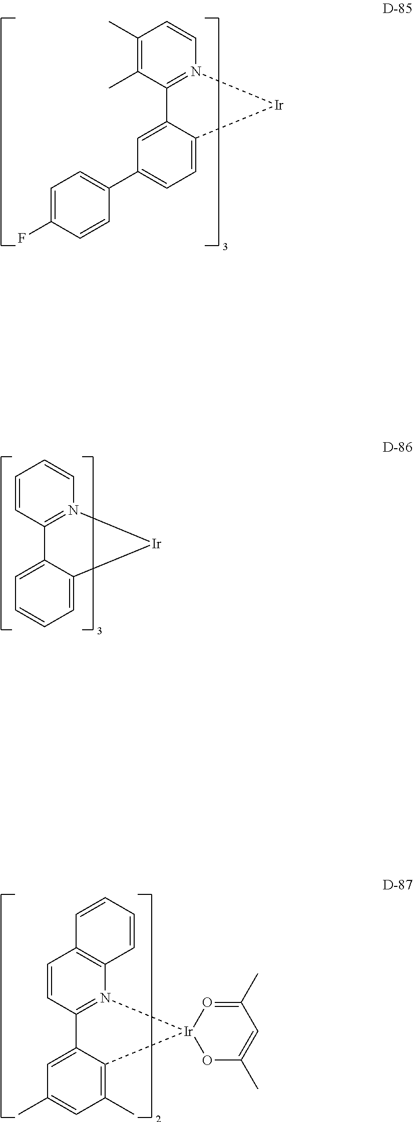

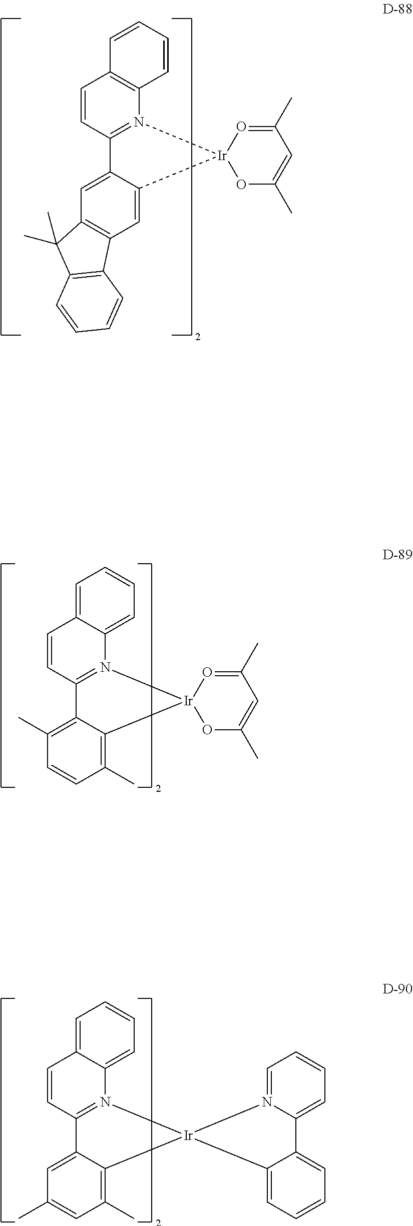

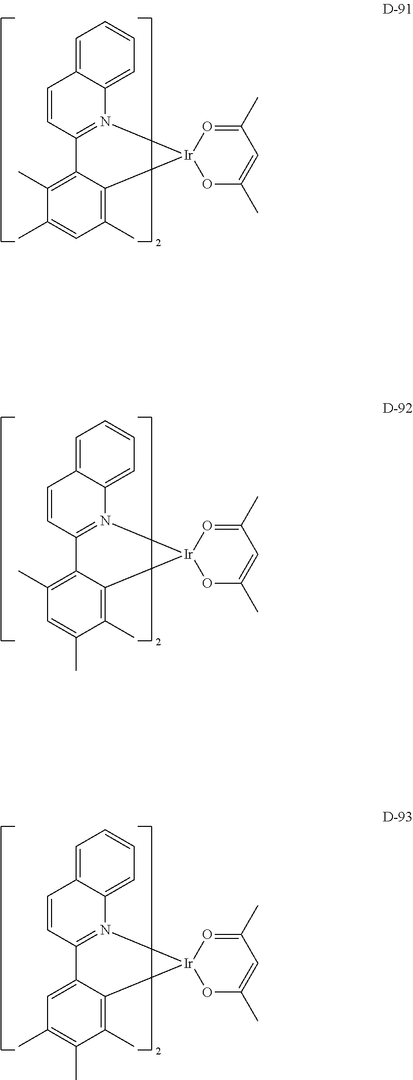

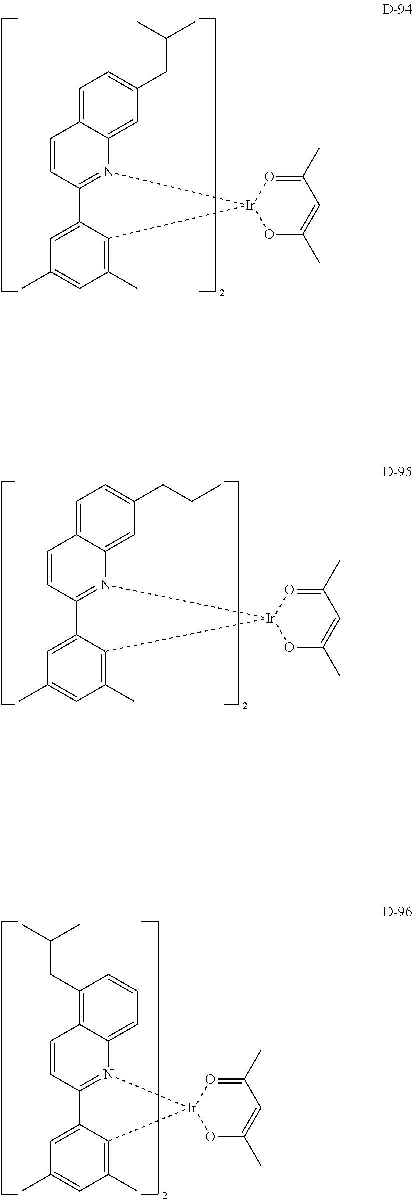

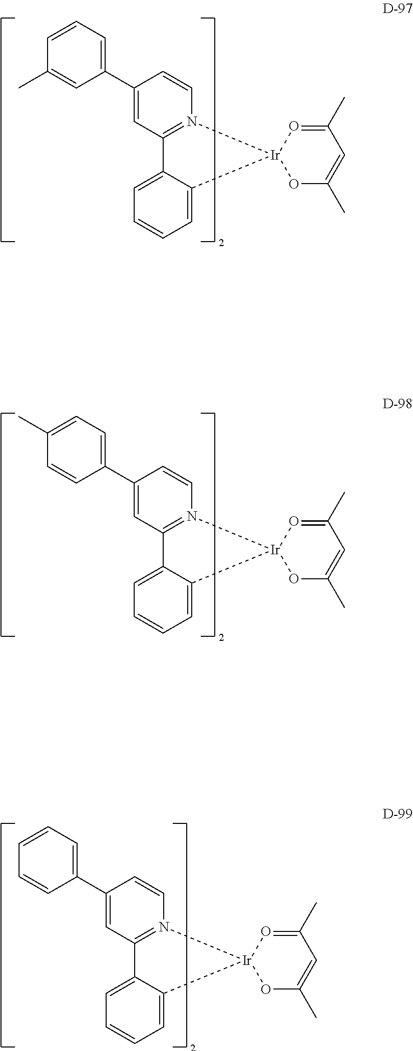

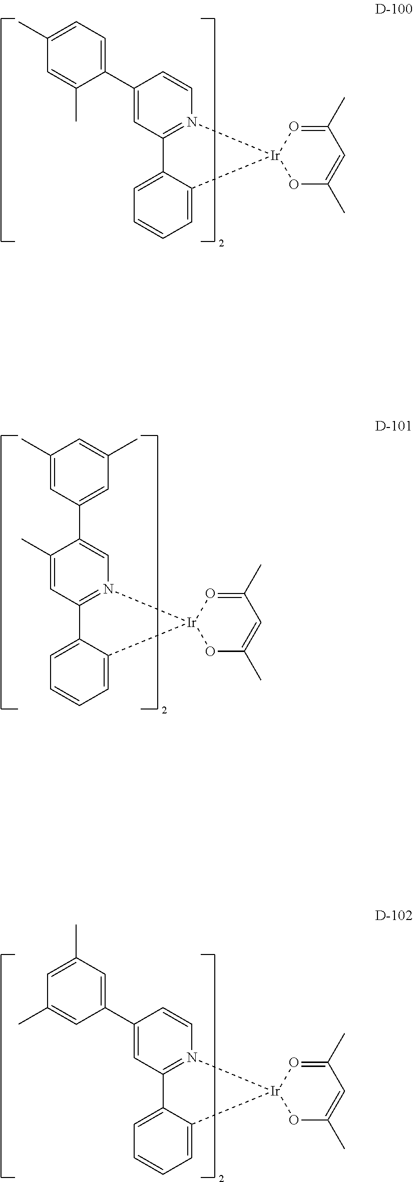

In another embodiment of the present invention, a material used for an organic electroluminescent device is provided. The material comprises the compound according to the present invention as a host material. When the compound according to the present invention is comprised as a host material (first host material), another compound can be comprised in the material used for an organic electroluminescent device, as a second host material, wherein the ratio of the first host material to the second host material can be in the range of 1:99 to 99:1.

In addition, the organic electroluminescent device according to the present invention comprises a first electrode, a second electrode, and at least one organic layer between said first and second electrodes. Said organic layer may comprise a material used for an organic electroluminescent device according to the present invention.

The organic electroluminescent device according to the present invention may further comprise, in addition to the organic electroluminescent compounds represented by formula 1, at least one compound selected from the group consisting of arylamine-based compounds and styrylarylamine-based compounds.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may further comprise at least one additional light-emitting layer, and a charge generating layer.

In addition, the organic electroluminescent device according to the present invention may emit white light by further comprising at least one light-emitting layer which comprises a blue electroluminescent compound, a red electroluminescent compound or a green electroluminescent compound known in the field, besides the organic electroluminescent compound according to the present invention. Also, if needed, a yellow or orange light-emitting layer can be comprised in the device.

According to the present invention, at least one layer (hereinafter, “a surface layer”) may be preferably placed on an inner surface(s) of one or both electrode(s); selected from a chalcogenide layer, a metal halide layer and a metal oxide layer. Specifically, a chalcogenide (includes oxides) layer of silicon or aluminum is preferably placed on an anode surface of an electroluminescent medium layer, and a metal halide layer or a metal oxide layer is preferably placed on a cathode surface of an electroluminescent medium layer. Such a surface layer provides operation stability for the organic electroluminescent device. Preferably, said chalcogenide includes SiOₓ(1≦X≦2), AlOₓ(1≦X≦1.5), SiON, SiAlON, etc.; said metal halide includes LiF, MgF₂, CaF₂, a rare earth metal fluoride, etc.; and said metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

In order to form each layer of the organic electroluminescent device according to the present invention, dry film-forming methods such as vacuum evaporation, sputtering, plasma and ion plating methods, or wet film-forming methods such as spin coating, dip coating, flow coating methods can be used.

When using a wet film-forming method, a thin film can be formed by dissolving or diffusing materials forming each layer into any suitable solvent such as ethanol, chloroform, tetrahydrofuran, dioxane, etc. The solvent can be any solvent where the materials forming each layer can be dissolved or diffused, and where there are no problems in film-formation capability.

Hereinafter, the organic electroluminescent compound, the preparation method of the compound, and the luminescent properties of the device comprising the compound of the present invention will be explained in detail with reference to the following examples.

Hereinafter, the acronyms used in the examples are as follows:
Ph: phenyl, EtOH: ethanol, EA: ethylacetate, OEt: ethoxy, OAc: acetate n-butyl: normal-butyl, t-Bu: tertiary-butyl, i-Pr: isopropyl, MC: methylene chloride THF: tetrahydrofuran, DMF: dimethylformamide

### Example 1

### Preparation of compound C-15

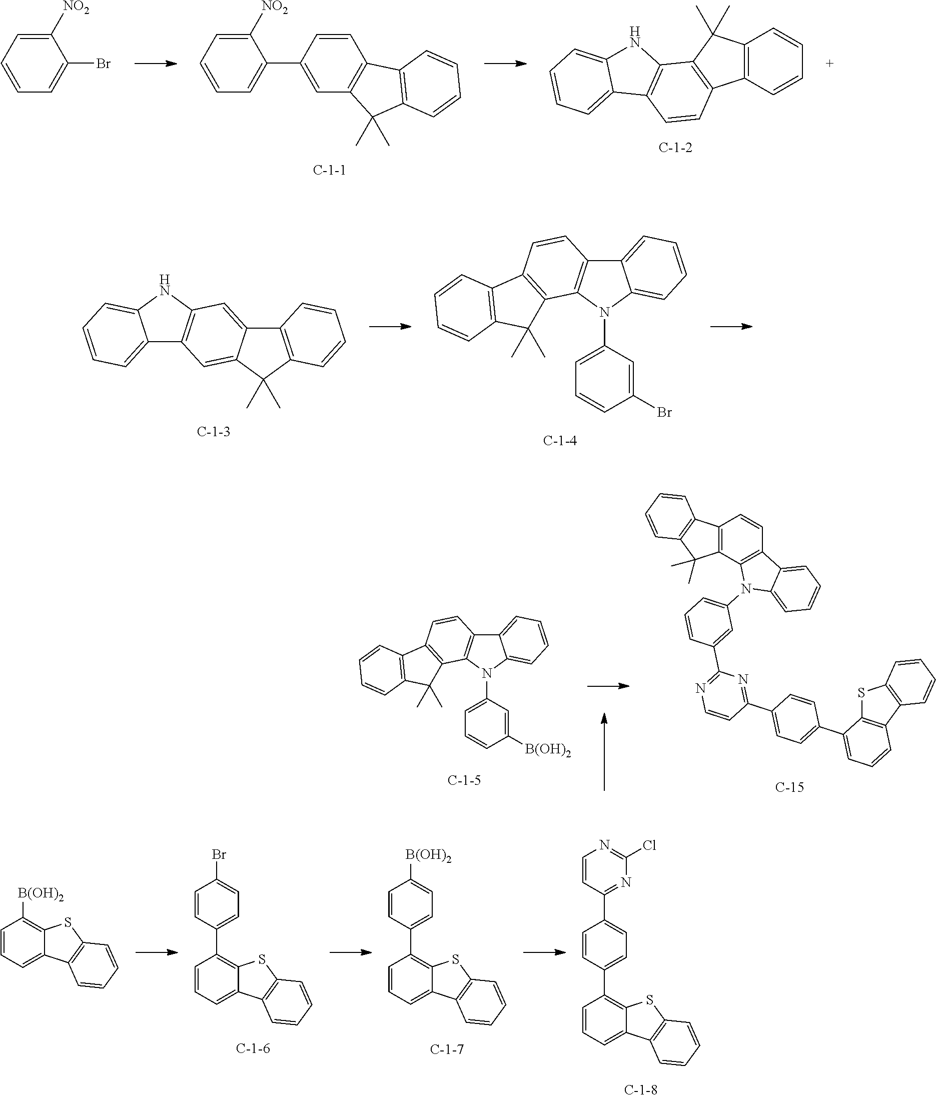

Preparation of Compound C-1-1

After dissolving 9,9-dimethyl-2-fluorene boronic acid (20 g, 84 mmol), 1-bromo-2-nitrobenzene (14.1 g, 70 mmol), Pd(PPh₃)₄ (4 g, 34.6 mmol), and Na₂CO₃ (22.3 g, 210 mmol) in a mixture solvent of toluene (400 mL), EtOH (100 mL), and distilled water (100 mL), the mixture was stirred for 6 hours at 120° C. Then, the mixture was extracted with EA and distilled water, and then separated with a column to obtain compound C-1-1 (21.7 g, 98.3%).

Preparation of Compound C-1-2 and C-1-3

After dissolving compound C-1-1 (21.7 g, 68.8 mmol) in a mixture solvent of P(OEt)₃ (200 mL), and 1,2-dichlorobenzene (150 mL), the mixture was stirred for 20 hours at 160° C. Then, P(OEt)₃ and 1,2-dichlorobenzene were removed by distillation under reduced pressure, and then the remaining product was separated with a column to obtain compound C-1-2 (8 g, 41%), and compound C-1-3 (8.8 g, 45%).

Preparation of Compound C-1-4

After dissolving compound C-1-2 (10 g, 35.3 mmol), 1-bromo-3-iodobenzene (29.9 g, 105.9 mmol), Pd(OAc)₂ (2.4 g, 10.6 mmol), and NaOt-Bu (16.9 g, 176.5 mmol) in toluene (180 mL), P(t-Bu)₃ (4.2 mL, 17.6 mmol) was added to the mixture. Then, the mixture was stirred for 3 days at 90° C. Then, the mixture was cooled to room temperature, and then extracted with EA and distilled water. The obtained product was separated with a column to obtain compound C-1-4 (9.4 g, 60.6%).

Preparation of Compound C-1-5

After dissolving compound C-1-4 (8.4 g, 19.2 mmol) in THF (500 mL), n-BuLi (2.5 M, 11.5 mL, 28.7 mmol) was added to the mixture at −78° C. under nitrogen condition. Then, the mixture was stirred for 1 hour, then B(Oi-Pr)₃ was added to the mixture, and then the mixture was stirred for 5 hours. Then, the mixture was quenched with 1 N HCl, and then extracted with EA and distilled water. Then, the obtained product was recrystallized with MC and hexane to obtain compound C-1-5 (5 g, 57.8%).

Preparation of Compound C-1-6

After dissolving 4-dibenzothiophene boronic acid (30 g, 131.5 mmol), 1-bromo-4-iodobenzene (55.81 g, 197.3 mmol), Pd(PPh₃)₄ (7.6 g, 6.57 mmol), and 2 M Na₂CO₃ (200 mL) in a mixture solvent of toluene (800 mL) and EtOH (100 mL), the mixture was stirred under reflux. After 5 hours, the mixture was cooled to room temperature, and then was extracted with EA. The organic layer was washed with distilled water, Then, the obtained product was distilled under reduced pressure, and then separated with a column to obtain compound C-1-6 (20 g, 45.6%).

Preparation of Compound C-1-7

After dissolving compound C-1-6 (20 g, 60 mmol) in THF (392 mL), n-BuLi (31.4 mL, 78.5 mmol, 2.5 M in hexane) was added to the mixture at −78° C. Then, the mixture was stirred for 1 hour, then B(Oi-Pr)₃ (20.8 mL, 90.6 mmol) was added slowly to the mixture, and then the mixture was stirred for 2 hours. Then, the mixture was quenched by adding 2 M HCl, and then extracted with distilled water and EA. Then, the obtained product was recrystallized with MC and hexane to obtain compound C-1-7 (12.8 g, 70%).

Preparation of Compound C-1-8

After dissolving compound C-1-7 (12 g, 39.4 mmol), 2,4-dichloropyrimidine (8.8 g, 59.2 mmol), K₂CO₃ (16.8 g, 118 mmol), and Pd(PPh₃)₄ (2.3 g, 1.97 mmol) in a mixture solvent of toluene (236 mL), EtOH (59 mL), and purified water (59 mL), the mixture was stirred under reflux for 4 hours. After completing the reaction, the mixture was cooled to room temperature, and then the aqueous layer was removed. Then, the organic layer was concentrated, and then the obtained solid was separated with a column to obtain compound C-1-8 (13 g, 88.4%).

Preparation of Compound C-15

After dissolving compound C-1-8 (5 g, 13.40 mmol), compound C-1-5 (5.9 g, 14.75 mmol), K₂CO₃ (5.5 g, 40.22 mmol), and Pd(PPh₃)₄ (0.77 g, 0.67 mmol) in a mixture solvent of toluene (150 mL), EtOH (20 mL), and purified water (20 mL), the mixture was stirred under reflux for 4 hours. After completing the reaction, the mixture was cooled to room temperature, and then the aqueous layer was removed. Then, the organic layer was concentrated, and then the obtained solid was separated with a column to obtain compound C-15 (5.6 g, 60.05%).

### Example 2

### Preparation of Compound C-60

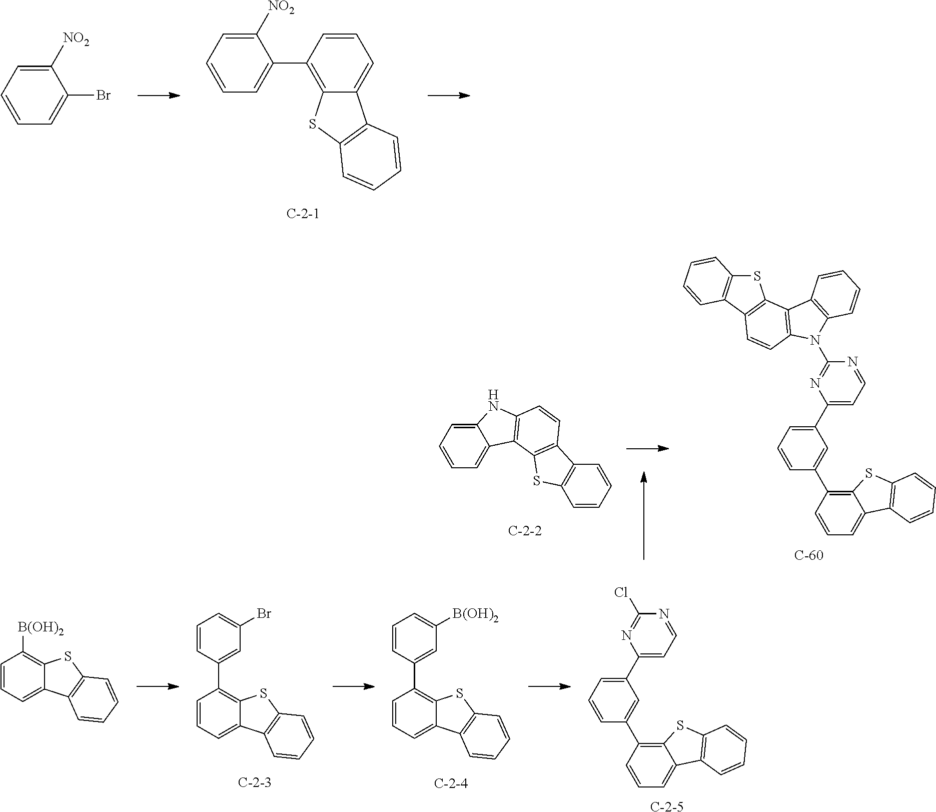

Preparation of Compound C-2-1

After dissolving 1-bromo-2-nitrobenzene (85 g, 0.42 mol), dibenzo[b,d]-thiophen-4-yl boronic acid (80 g, 0.35 mmol), Pd(PPh₃)₄ (20 g, 0.018 mol), and K₂CO₃ (116 g, 1.0 mol) in a mixture solvent of toluene (1700 mL), EtOH (440 mL), and H₂O (440 mL), the mixture was stirred for 12 hours at 120° C. After completing the reaction, the mixture was extracted with EA, and then the organic layer was dried with MgSO₄. After filtering the obtained product, the solvent was removed under reduced pressure, and then the remaining product was separated with a column to obtain, white solid, compound C-2-1 (93 g, 87%).

Preparation of Compound C-2-2

After adding compound C-2-1 (88 g, 0.29 mol) to P(OEt)₃ (960 mL, 0.4 M), the mixture was stirred for 6 hours at 150° C. After completing the reaction, P(OEt)₃ was removed by distillation, and then the remaining product was separated with a column to obtain, white solid, compound C-2-2 (40 g, 70%).

Preparation of Compound C-2-3

After dissolving 1,3-dibromobenzene (16.5 g, 0.2 mol), dibenzo[b,d]-thiophen-4-yl boronic acid (15 g, 0.06 mol), Pd(PPh₃)₄ (3.8 g, 0.003 mol), and Na₂CO₃ (14 g, 0.13 mol) in a mixture solvent of toluene (330 mL), and H₂O (70 mL), the mixture was stirred for 12 hours at 80° C. After completing the reaction, the mixture was extracted with EA, and then the organic layer was dried with MgSO₄. After filtering the obtained product, the solvent was removed under reduced pressure, and then the remaining product was separated with a column to obtain, white solid, compound C-2-3 (8.4 g, 40%).

Preparation of Compound C-2-4

After adding compound C-2-3 (8.4 g, 0.025 mol) in THF (200 mL), n-BuLi (15 mL, 2.25 M in hexane) was added slowly to the mixture at −78° C. under nitrogen condition. Then, the mixture was stirred for 1 hour at −78° C., then B(Oi-Pr)₃ (11.4 mL, 0.05 mol) was added slowly to the mixture at −78° C., and then the mixture was heated to room temperature and reaction took place for 12 hours. After completing the reaction, the mixture was extracted with EA, and then the organic layer was dried with MgSO₄. After filtering the obtained product, the solvent was removed under reduced pressure, and then the remaining product was separated with a column to obtain, white solid, compound C-2-4 (6 g, 80%).

Preparation of Compound C-2-5

After dissolving 2,4-dichloropyrimidine (5.9 g, 0.04 mol), compound C-2-4 (8.3 g, 0.03 mol), Pd(PPh₃)₄ (1.7 g, 0.001 mol), and Na₂CO₃ (8.1 g, 0.07 mol) in a mixture solvent of toluene (150 mL), EtOH (40 mL), and H₂O (40 mL), the mixture was stirred for 12 hours at 80° C. After completing the reaction, the mixture was extracted with EA, and then the organic layer was dried with MgSO₄. After filtering the obtained product, the solvent was removed under reduced pressure, and then the remaining product was separated with a column to obtain compound C-2-5 (10 g, 98%).

Preparation of Compound C-60

After dissolving compound C-2-2 (5 g, 18.29 mmol), and compound C-2-5 (7.5 g, 20.12 mmol) in DMF (200 mL), NaH (60%, 1.09 g, 27.43 mmol) was added to the mixture. Then, the mixture was stirred for 12 hours, and then methanol was added to the mixture. Then, solid was filtered, and then the remaining product was separated with a column to obtain compound C-60 (7 g, 62.7%).

### Example 3

### Preparation of Compound C-61

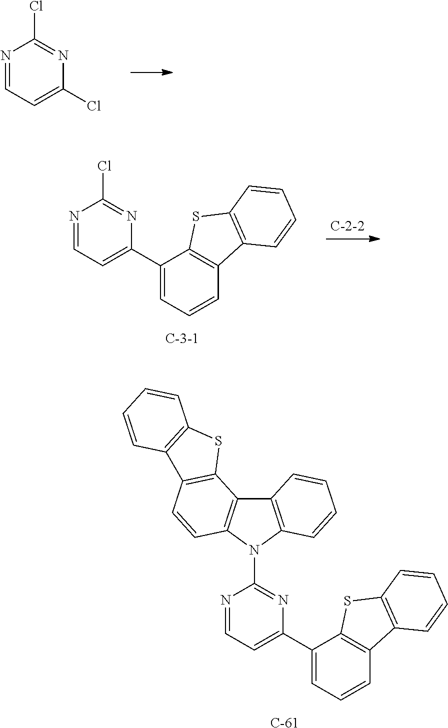

Compound C-3-1 was prepared by the same method as compound C-2-5 in Example 2, and compound C-61 was prepared by the same method as compound C-60 in Example 2.

### Example 4

### Preparation of Compound C-62

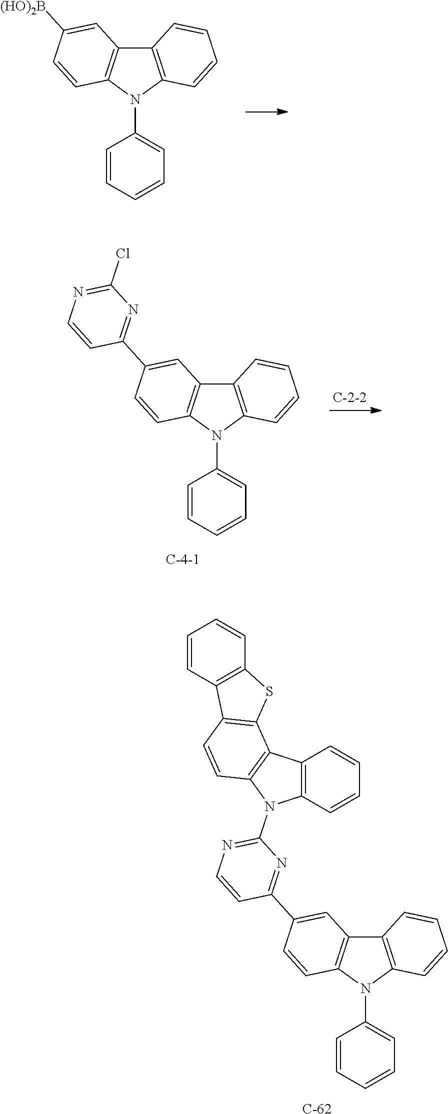

Compound C-4-1, and compound C-62 were prepared by the same methods as compound C-2-5, and compound C-62, respectively, as in Example 2.

### Example 5

### Preparation of Compound C-63

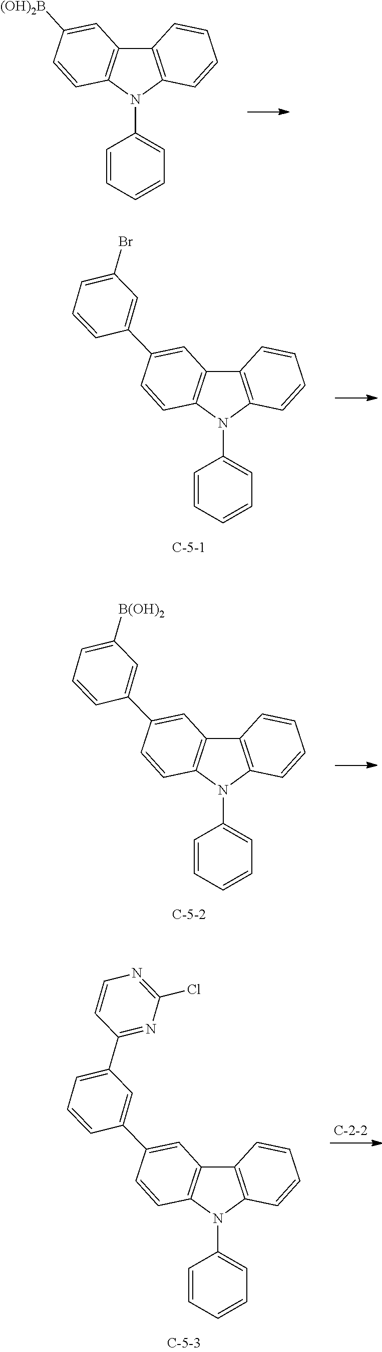

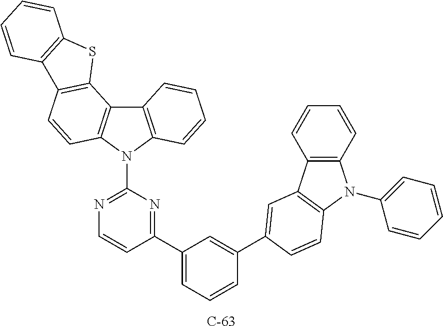

Compound C-5-1 to compound C-5-3 were prepared by the same methods as compounds C-2-3, C-2-4, and C-2-5, respectively, as in Example 2, and compound C-63 was prepared by the same method as compound C-60 in Example 2.

### Example 6

### Preparation of Compound C-22

Compound C-22 was prepared by the same method as compound C-60 in Example 2, using compound C-2-5 in Example 2, and compound C-1-3 in Example 1.

### Example 7

### Preparation of Compound C-64

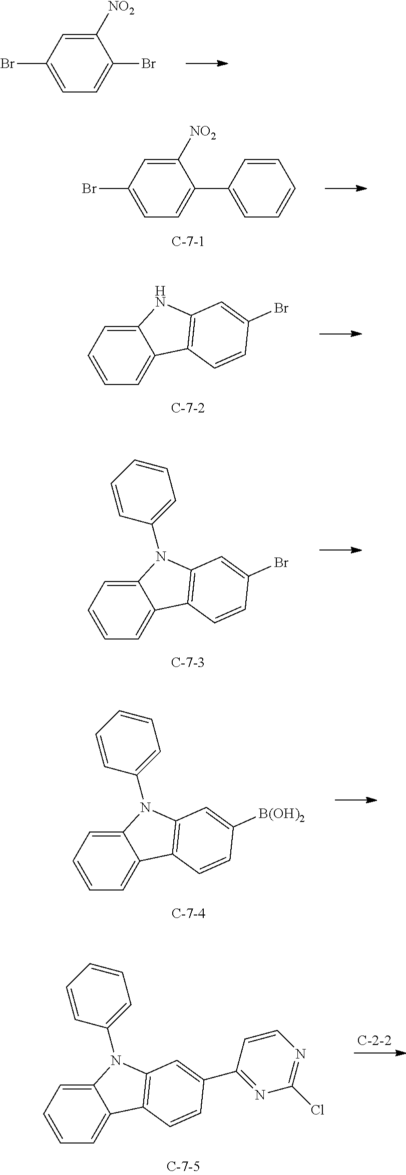 [SMILES: O=[N+]([O-])c1cc(Br)ccc1Br ; O=[N+]([O-])c1cc(Br)ccc1-c1ccccc1 ; Brc1ccc2c(c1)[nH]c1ccccc12 ; Brc1ccc2c3ccccc3n(-c3ccccc3)c2c1 ; OB(O)c1ccc2c3ccccc3n(-c3ccccc3)c2c1 ; Clc1nccc(-c2ccc3c4ccccc4n(-c4ccccc4)c3c2)n1]

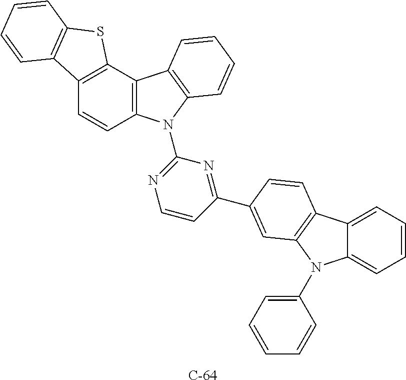

Preparation of Compound C-7-1

After adding 1,4-dibromo-2-nitrobenzene (50 g, 177.99 mmol), phenyl boronic acid (19.7 g, 161.81 mmol), Na₂CO₃ (51 g, 485.43 mmol), and Pd(PPh₃)₄ (9.4 g, 8.1 mmol) to a mixture solvent of toluene (900 mL), EtOH (240 mL), and purified water (240 mL), the mixture was stirred under reflux for 1 day. After completing the reaction, the mixture was cooled to room temperature, and then extracted with distilled water and EA. Then, the organic layer was distilled under reduced pressure, and then separated with a column with MC/hexane to obtain compound C-7-1 (42 g, 92%).

Preparation of Compound C-7-2

After adding compound C-7-1 (42 g, 150 mmol) in a mixture solvent of P(OEt)₃ (450 mL), and 1,2-dichlorobenzene (300 mL), the mixture was stirred for 1 day at 150° C. After completing the reaction, the mixture was concentrated under reduced pressure, and then extracted with EA, and then the organic layer was concentrated. The obtained product was separated with a column with MC/hexane to obtain compound C-7-2 (18 g, 48%).

Preparation of Compound C-7-3

After mixing compound C-7-2 (23 g, 0.093 mmol), iodobenzene (20.9 mL, 0.186 mol), CuI (14.2 g, 0.074 mol), Cs₂CO₃ (91.2 g, 0.28 mol), toluene (300 mL), and ethylenediamine (9.46 mL, 0.140 mol), the mixture was stirred under reflux. After 12 hours, the mixture was cooled to room temperature, and CuI and Cs₂CO₃ were removed. Then, the remaining liquid was distilled under reduced pressure, and then separated with a column to obtain compound C-7-3 (28 g, 92.4%).

Preparation of Compound C-7-4

After dissolving compound C-7-3 (28 g, 86.90 mmol) in THF (500 mL), n-BuLi (41.7 mL, 2.5 M) was added slowly to the mixture. After 1 hour, triisopropyl borate (30 mL, 130.3 mmol) was added to the mixture. After stirring the mixture for 12 hours at room temperature, distilled water was added to the mixture. Then, the mixture was extracted with EA, and then dried with MgSO₄. The obtained product was distilled under reduced pressure, and then recrystallized with EA/hexane to obtain compound C-7-4 (21 g, 78.4%).

Preparation of Compound C-7-5 and Compound C-64

Compound C-7-5 was prepared by the same method as compound C-2-5 in Example 2, and compound C-64 was prepared by the same method as compound C-60 in Example 2.

### Example 8

### Preparation of Compound C-39

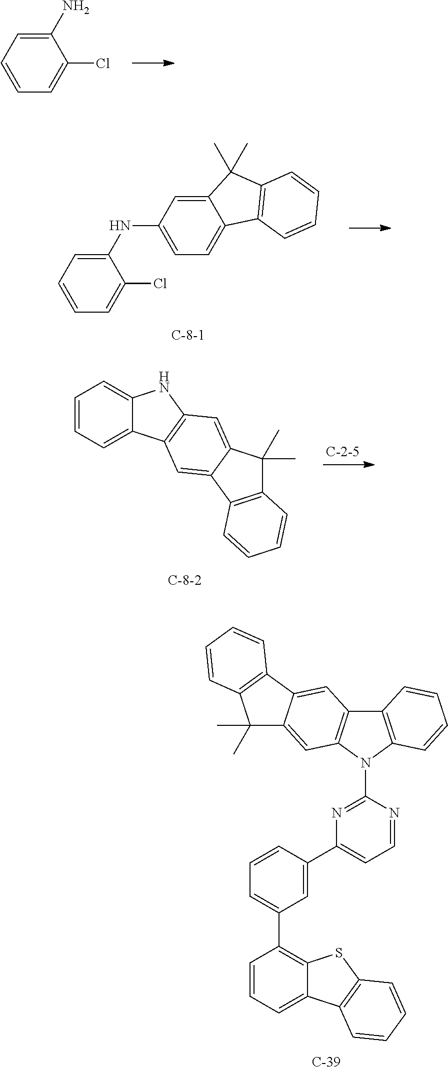

Preparation of Compound C-8-1

After mixing 2-bromo-9,9-dimethyl-9H-fluorene (50 g, 0.183 mol), 2-chloroaniline (57 mL, 0.549 mol), Pd(OAc)₂ (1.6 g, 0.007 mol), NaO-t-Bu (44 g, 0.458 mol), toluene (500 mL), and P(t-Bu)₃ (7.2 mL, 0.0146 mol), the mixture was stirred for 12 hours at 120° C. After completing the reaction, the mixture was extracted with EA, and then the organic layer was dried with MgSO₄. After filtering the obtained product, the solvent was removed under reduced pressure, and then the remaining product was separated with a column to obtain, white solid, compound C-8-1 (32 g, 55%).

Preparation of Compound C-8-2

After mixing compound C-8-1 (32 g, 0.1 mol), Pd(OAc)₂ (1.1 g, 0.005 mol), di-t-butylmethylphosphine.HBF₄ (2.48 g, 0.01 mol), K₂CO₃ (42 g, 0.30 mol), and dimethyl amide (DMA) (550 mL), the mixture was stirred for 12 hours at 200° C. After completing the reaction, the mixture was extracted with EA, and then the organic layer was dried with MgSO₄. After filtering the obtained product, the solvent was removed under reduced pressure, and then the remaining product was separated with a column to obtain, white solid, compound C-8-2 (14 g, 47%).

Preparation of Compound C-39

Compound C-39 was prepared by the same method as compound C-60 in Example 2.

### Example 9

### Preparation of Compound C-40

Compound C-40 was prepared by the same method as compound C-60 in Example 2, using compound C-8-2 in Example 8, and compound C-7-5 in Example 7.

### Example 10

### Preparation of Compound C-41

Compound C-41 was prepared by the same method as compound C-60 in Example 2, using compound C-8-2 in Example 8, and compound C-1-8 in Example 1.

The Physical properties of the final compounds prepared according to above examples 1 to 10 are as follow:

| | Yield | MS/EIMS | | UV | PL | Mp |
|---|---|---|---|---|---|---|
| Example | (%) | Found | Calculated | (nm) | (nm) | (° C.) |
| 1 | 60.05 | 696.24 | 695.87 | 320 | 400 | 245 |
| 2 | 62.7 | 610.14 | 609.76 | 334 | 459 | 267 |
| 3 | 64.6 | 534.11 | 533.66 | 336 | 466 | 292 |
| 4 | 58.2 | 593.18 | 592.71 | 362 | 428 | 238 |
| 5 | 55.3 | 669.21 | 668.81 | 356 | 387 | 250 |
| 6 | 60.7 | 620.21 | 619.78 | 334 | 452 | 263 |
| 7 | 50.0 | 593.18 | 592.71 | 344 | 431 | 261 |
| 8 | 62.3 | 620.21 | 619.78 | 352 | 482 | 200 |
| 9 | 52.5 | 603.25 | 602.73 | 356 | 469 | 203 |
| 10 | 48.4 | 620.21 | 619.78 | 344 | 481 | 288 |

### Device Example 1

### Production of an OLED Device Using the Compound According to the Present Invention

An OLED device was produced using the compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N¹-(naphthalen-1-yl)-N⁴,N⁴-diphenylbenzen-1,4-diamine) was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 60 nm on the ITO substrate. Then, N,N′-di(4-biphenyl)-N,N′-di(4-biphenyl)-4,4′-diaminobiphenyl was introduced into another cell of said vacuum vapor depositing apparatus, and was evaporated by applying an electric current to the cell, thereby forming a hole transport layer having a thickness of 20 nm on the hole injection layer. Thereafter, compound C-22 according to the present invention was introduced into one cell of the vacuum vapor depositing apparatus, as a host material, and tris(4-methyl-2,5-diphenylpyridine)iridium was introduced into another cell as a dopant. The two materials were evaporated at different rates and were deposited in a doping amount of 15 wt % based on the total amount of the host and dopant to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate was introduced into another cell. The two materials were evaporated at the same rate and were deposited in a doping amount of 50 wt % each to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a green emission having a luminance of 1320 cd/m² and a current density of 2.7 mA/cm² at a driving voltage of 4.2 V.

### Device Example 2

### Production of an OLED Device Using the Compound According to the Present Invention

An OLED device was produced in the same manner as in Device Example 1, except for using compound C-60 as a host of the light emitting material.

The produced OLED device showed a green emission having a luminance of 3430 cd/m² and a current density of 7.3 mA/cm² at a driving voltage of 4.1 V.

### Device Example 3

### Production of an OLED Device Using the Compound According to the Present Invention

An OLED device was produced in the same manner as in Device Example 1, except for using compound C-61 as a host of the light emitting material.

The produced OLED device showed a green emission having a luminance of 2640 cd/m² and a current density of 5.66 mA/cm² at a driving voltage of 3.5 V.

### Device Example 4

### Production of an OLED Device Using the Compound According to the Present Invention

An OLED device was produced in the same manner as in Device Example 1, except for using compound C-62 as a host of the light emitting material.

The produced OLED device showed a green emission having a luminance of 1890 cd/m² and a current density of 4.84 mA/cm² at a driving voltage of 3.8 V.

### Comparative Example 1

### Production of an OLED Device Using Conventional Electroluminescent Compounds

An OLED device was produced in the same manner as in Device Example 1, except for depositing the light emitting layer using 4,4′-N,N′-dicarbazole-biphenyl as a host of the light emitting material, and compound Ir(ppy)₃ [tris(2-phenylpyridine)iridium] as a dopant in another cell; and depositing aluminum(III)bis(2-methyl-8-quinolinato)4-phenylphenolate to form a hole blocking layer having a thickness of 10 nm on the light emitting layer.

The produced OLED device showed a green emission having a luminance of 3000 cd/m² and a current density of 9.52 mA/cm² at a driving voltage of 7.2 V.

It is verified that the organic electroluminescent compounds of the present invention have superior luminous efficiency over conventional host compounds. Notably, the devices using the compounds according to the present invention as a luminescent host material have superior luminous characteristics. In addition, the compounds can improve the power efficiency of the device by decreasing the driving voltage, to reduce overall power consumption.

1. An organic electroluminescent compound represented by the following formula 1: 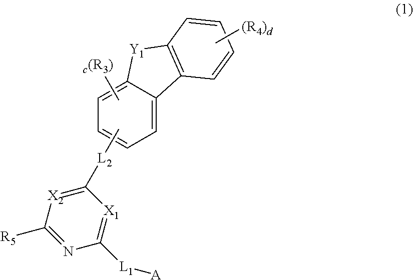
wherein
A represents 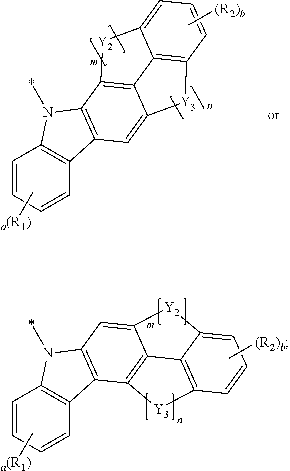
L₁ and L₂ each independently represent a single bond, a substituted or unsubstituted 5- to 30-membered heteroarylene group, or a substituted or unsubstituted (C6-C30)arylene group;
X₁ and X₂ each independently represent CH or N;
Y₁ to Y₃ each independently represent —O—, —S—, —C(R₁₁)(R₁₂)—, —Si(R₁₃)(R₁₄)— or —N(R₁₅)—;
m and n each independently represent 0 or 1; where m+n=1;
R₁ to R₄ each independently represent hydrogen, deuterium, a halogen, a cyano group, a carboxyl group, a nitro group, a hydroxyl group, a substituted or unsubstituted (C1-C30)alkyl group, a substituted or unsubstituted (C2-C30)alkenyl group, a substituted or unsubstituted (C2-C30)alkynyl group, a substituted or unsubstituted (C1-C30)alkoxy group, a substituted or unsubstituted (C3-C30)cycloalkyl group, a substituted or unsubstituted (C3-C30)cycloalkenyl group, a substituted or unsubstituted 3- to 7-membered heterocycloalkyl group, a substituted or unsubstituted (C6-C30)aryl group, a substituted or unsubstituted 5- to 30-membered heteroaryl group, —NR₁₆R₁₇, —SiR₁₈R₁₉R₂₀, —SR₂₁, —OR₂₂, —COR₂₃, or —B(OR₂₄)(OR₂₅);
R₅ represents hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₁₆R₁₇, or —SiR₁₈R₁₉R₂₀;
R₁₁ to R₂₅ each independently represent hydrogen, deuterium, a halogen, a cyano group, a carboxyl group, a nitro group, a hydroxyl group, a substituted or unsubstituted (C1-C30)alkyl group, a substituted or unsubstituted (C2-C30)alkenyl group, a substituted or unsubstituted (C2-C30)alkynyl group, a substituted or unsubstituted (C1-C30)alkoxy group, a substituted or unsubstituted (C3-C30)cycloalkyl group, a substituted or unsubstituted (C3-C30)cycloalkenyl group, a substituted or unsubstituted 3- to 7-membered heterocycloalkyl group, a substituted or unsubstituted (C6-C30)aryl group, or a substituted or unsubstituted 5- to 30-membered heteroaryl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;
a, b and d each independently represent an integer of 1 to 4; where a, b or d is an integer of 2 or more, each of R₁, each of R₂, or each of R₄ may be same or different;
c represents an integer of 1 to 3; where c is an integer of 2 or more, each of R₃ may be same or different;
the heteroarylene group and the heteroaryl group contain at least one hetero atom selected from B, N, O, S, P(═O), Si and P; and
the heterocycloalkyl group contains at least one hetero atom selected from 0, S and N.

2. The organic electroluminescent compound according to claim 1, wherein in L₁, L₂, R₁ to R₅, and R₁₁ to R₂₅, the substituents of the substituted (C1-C30)alkyl group, substituted (C2-C30)alkenyl group, substituted (C2-C30)alkynyl group, substituted (C1-C30)alkoxy group, substituted (C3-C30)cycloalkyl group, substituted (C3-C30)cycloalkenyl group, substituted 3- to 7-membered heterocycloalkyl group, substituted (C6-C30)aryl group, substituted (C6-C30)arylene group, substituted 5- to 30-membered heteroaryl group, and substituted 5- to 30-membered heteroarylene group each independently are at least one selected from the group consisting of deuterium; a halogen; a cyano group; a carboxyl group; a nitro group; a hydroxyl group; a (C1-C30)alkyl group; a halo(C1—C30)alkyl group; a (C2-C30)alkenyl group; a (C2-C30)alkynyl group; a (C1-C30)alkoxy group; a (C1-C30)alkylthio group; a (C3-C30)cycloalkyl group; a (C3-C30)cycloalkenyl group; a 3- to 7-membered heterocycloalkyl group; a (C6-C30)aryl group unsubstituted or substituted with a 5- to 30-membered heteroaryl group; a (C6-C30)aryloxy group; a (C6-C30)arylthio group; a 5- to 30-membered heteroaryl group unsubstituted or substituted with a (C6-C30)aryl group; a tri(C1-C30)alkylsilyl group; a tri(C6-C30)arylsilyl group; a di(C1-C30)alkyl(C6-C30)arylsilyl group; a (C1-C30)alkyl di(C6-C30)arylsilyl group; an amino group; a mono- or di-(C1-C30)alkylamino group; a mono- or di-(C6-C30)arylamino group; a (C1-C30)alkyl(C6-C30)arylamino group; a (C1-C30)alkylcarbonyl group; a (C1-C30)alkoxycarbonyl group; a (C6-C30)arylcarbonyl group; a di(C6-C30)arylboronyl group; a di(C1-C30)alkylboronyl group; a (C1-C30)alkyl(C6-C30)arylboronyl group; a (C6-C30)aryl(C1-C30)alkyl group; and a (C1-C30)alkyl(C6-C30)aryl group.

3. The organic electroluminescent compound according to claim 1, wherein
Y₁ to Y₃ each independently represent —O—, —S—, —C(R₁₁)(R₁₂)— or —N(R₁₅)—; and
R₁₁, R₁₂, and R₁₅ are as defined in claim 1.

4. The organic electroluminescent compound according to claim 1, wherein
L₁ and L₂ each independently represent a single bond, a phenyl group, a biphenyl group, a naphthyl group, a fluorenyl group, a phenanthrenyl group, a pyridyl group, a pyrazinyl group, a pyrimidinyl group, or a pyridazinyl group.

5. The organic electroluminescent compound according to claim 1, wherein the compound represented by formula 1 is selected from the group consisting of:

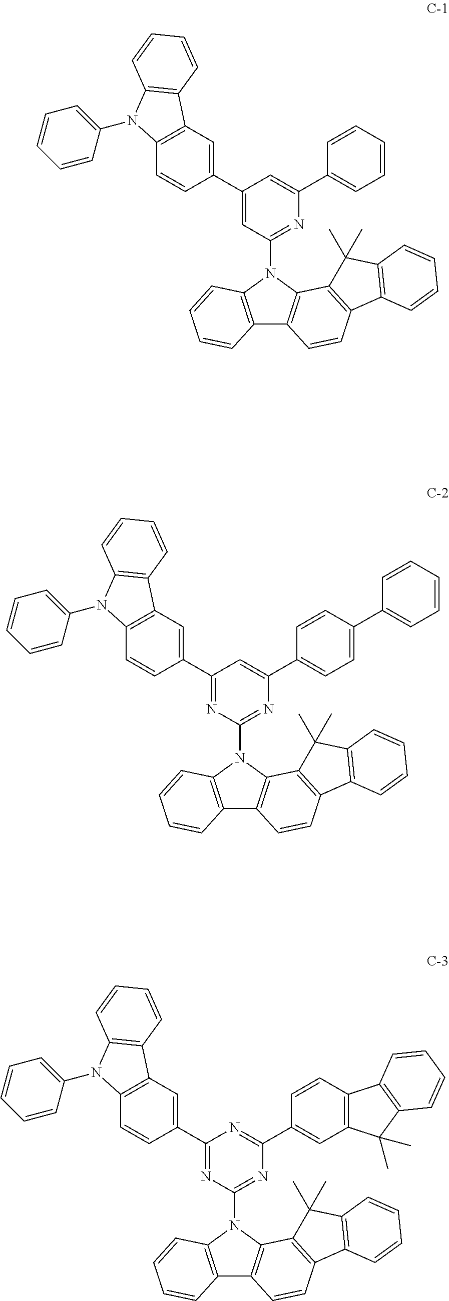 [SMILES: CC1(C)c2ccccc2-c2ccc3c4ccccc4n(-c4cc(-c5ccc6c(c5)c5ccccc5n6-c5ccccc5)cc(-c5ccccc5)n4)c3c21 ; CC1(C)c2ccccc2-c2ccc3c4ccccc4n(-c4nc(-c5ccc(-c6ccccc6)cc5)cc(-c5ccc6c(c5)c5ccccc5n6-c5ccccc5)n4)c3c21 ; CC1(C)c2ccccc2-c2ccc(-c3nc(-c4ccc5c(c4)c4ccccc4n5-c4ccccc4)nc(-n4c5ccccc5c5ccc6c(c54)C(C)(C)c4ccccc4-6)n3)cc21]

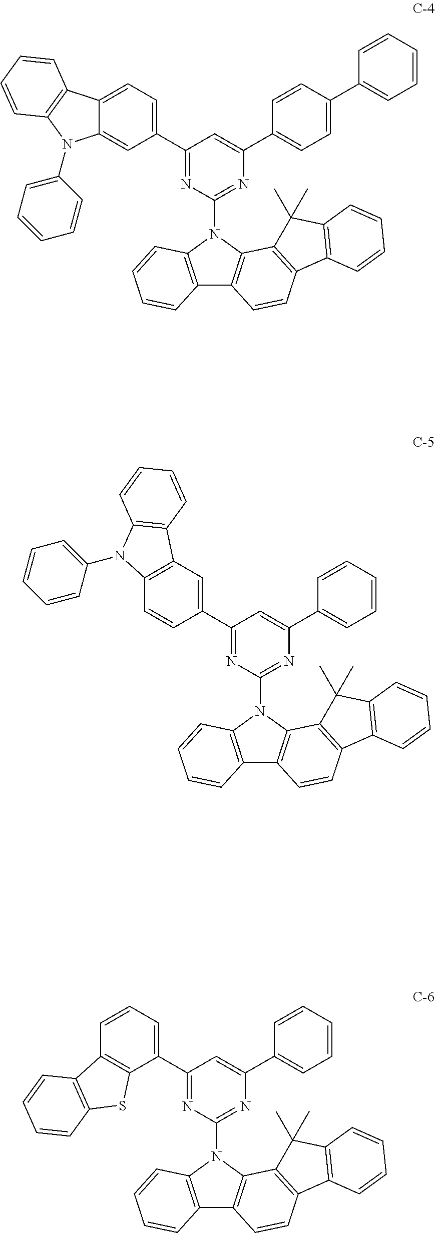 [SMILES: CC1(C)c2ccccc2-c2ccc3c4ccccc4n(-c4nc(-c5ccc(-c6ccccc6)cc5)cc(-c5ccc6c7ccccc7n(-c7ccccc7)c6c5)n4)c3c21 ; CC1(C)c2ccccc2-c2ccc3c4ccccc4n(-c4nc(-c5ccccc5)cc(-c5ccc6c(c5)c5ccccc5n6-c5ccccc5)n4)c3c21 ; CC1(C)c2ccccc2-c2ccc3c4ccccc4n(-c4nc(-c5ccccc5)cc(-c5cccc6c5sc5ccccc56)n4)c3c21]

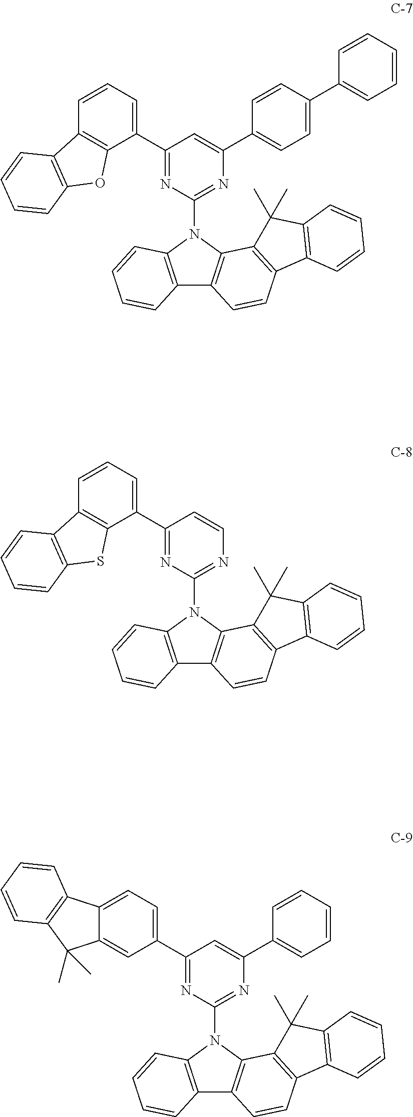 [SMILES: CC1(C)c2ccccc2-c2ccc3c4ccccc4n(-c4nc(-c5ccc(-c6ccccc6)cc5)cc(-c5cccc6c5oc5ccccc56)n4)c3c21 ; CC1(C)c2ccccc2-c2ccc3c4ccccc4n(-c4nccc(-c5cccc6c5sc5ccccc56)n4)c3c21 ; CC1(C)c2ccccc2-c2ccc(-c3cc(-c4ccccc4)nc(-n4c5ccccc5c5ccc6c(c54)C(C)(C)c4ccccc4-6)n3)cc21]

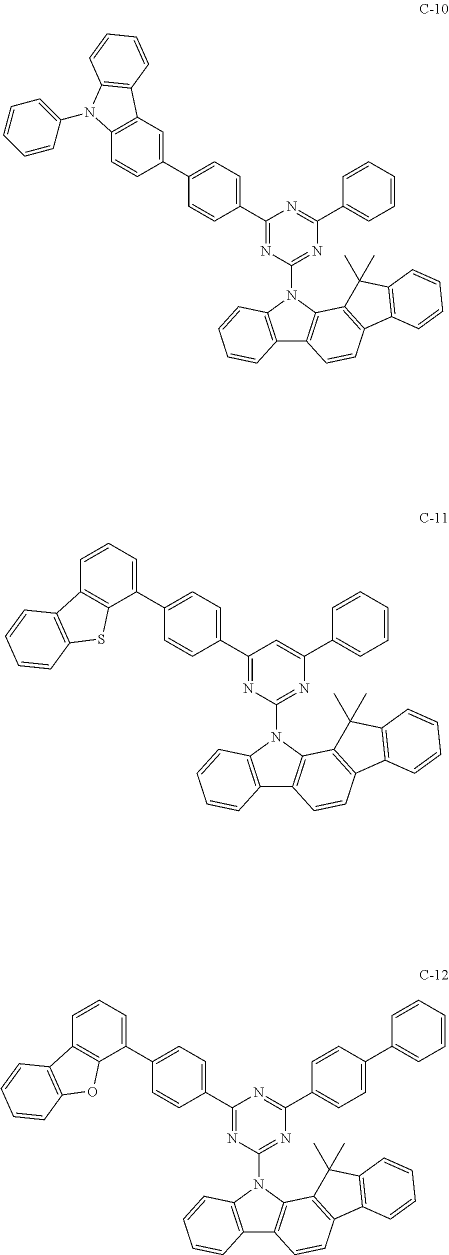 [SMILES: CC1(C)c2ccccc2-c2ccc3c4ccccc4n(-c4nc(-c5ccccc5)nc(-c5ccc(-c6ccc7c(c6)c6ccccc6n7-c6ccccc6)cc5)n4)c3c21 ; CC1(C)c2ccccc2-c2ccc3c4ccccc4n(-c4nc(-c5ccccc5)cc(-c5ccc(-c6cccc7c6sc6ccccc67)cc5)n4)c3c21 ; CC1(C)c2ccccc2-c2ccc3c4ccccc4n(-c4nc(-c5ccc(-c6ccccc6)cc5)nc(-c5ccc(-c6cccc7c6oc6ccccc67)cc5)n4)c3c21]

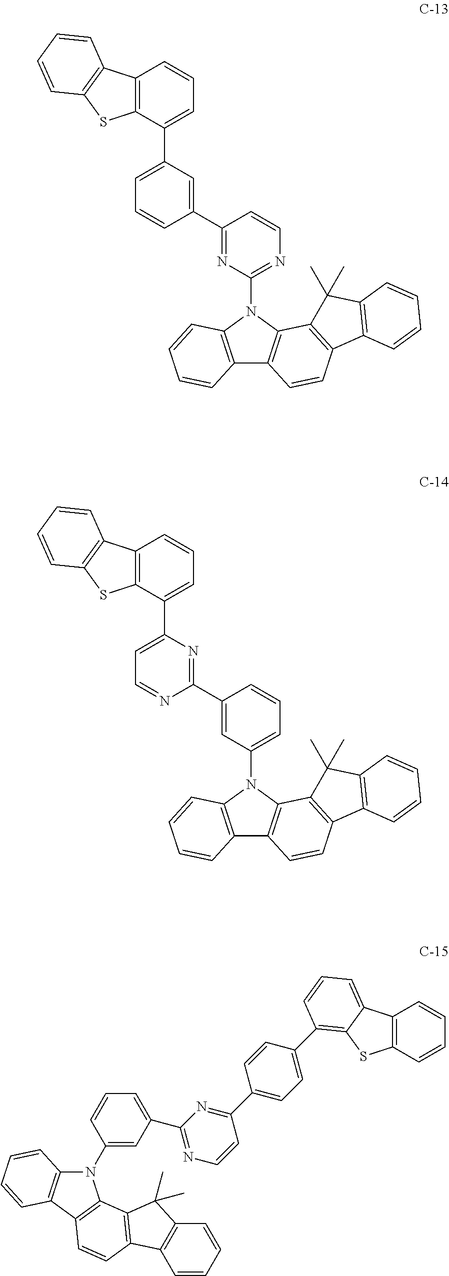 [SMILES: CC1(C)c2ccccc2-c2ccc3c4ccccc4n(-c4nccc(-c5cccc(-c6cccc7c6sc6ccccc67)c5)n4)c3c21 ; CC1(C)c2ccccc2-c2ccc3c4ccccc4n(-c4cccc(-c5nccc(-c6cccc7c6sc6ccccc67)n5)c4)c3c21 ; CC1(C)c2ccccc2-c2ccc3c4ccccc4n(-c4cccc(-c5nccc(-c6ccc(-c7cccc8c7sc7ccccc78)cc6)n5)c4)c3c21]

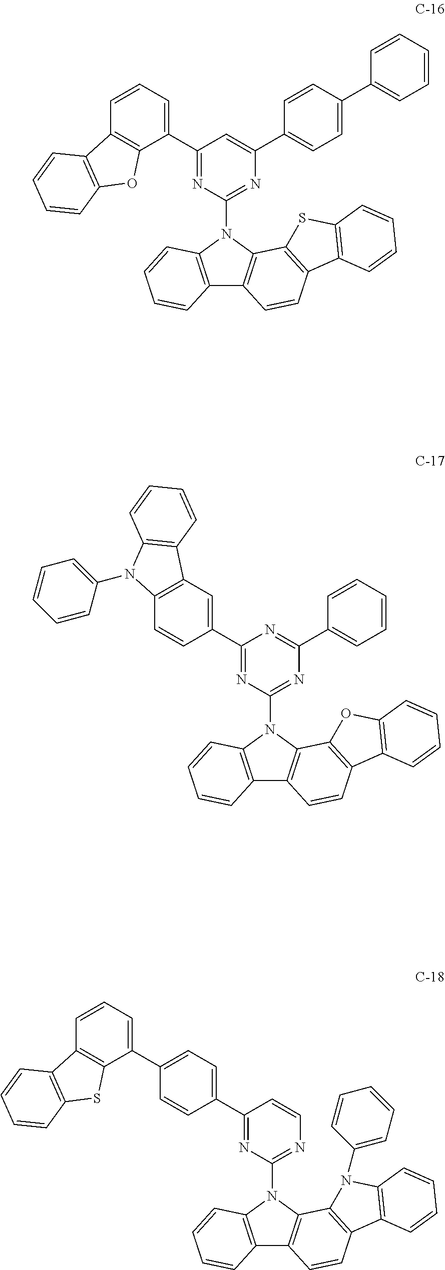 [SMILES: c1ccc(-c2ccc(-c3cc(-c4cccc5c4oc4ccccc45)nc(-n4c5ccccc5c5ccc6c7ccccc7sc6c54)n3)cc2)cc1 ; c1ccc(-c2nc(-c3ccc4c(c3)c3ccccc3n4-c3ccccc3)nc(-n3c4ccccc4c4ccc5c6ccccc6oc5c43)n2)cc1 ; c1ccc(-n2c3ccccc3c3ccc4c5ccccc5n(-c5nccc(-c6ccc(-c7cccc8c7sc7ccccc78)cc6)n5)c4c32)cc1]

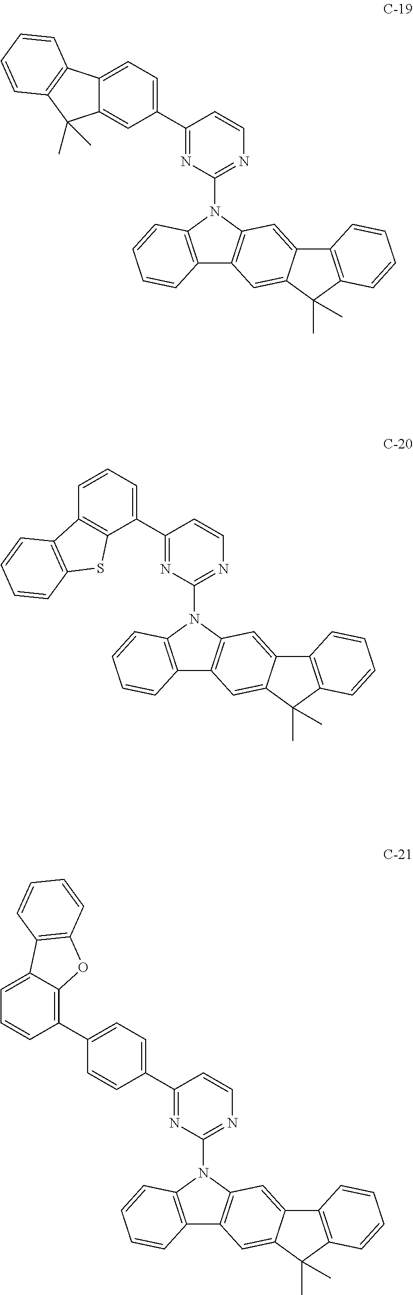 [SMILES: CC1(C)c2ccccc2-c2ccc(-c3ccnc(-n4c5ccccc5c5cc6c(cc54)-c4ccccc4C6(C)C)n3)cc21 ; CC1(C)c2ccccc2-c2cc3c(cc21)c1ccccc1n3-c1nccc(-c2cccc3c2sc2ccccc23)n1 ; CC1(C)c2ccccc2-c2cc3c(cc21)c1ccccc1n3-c1nccc(-c2ccc(-c3cccc4c3oc3ccccc34)cc2)n1]

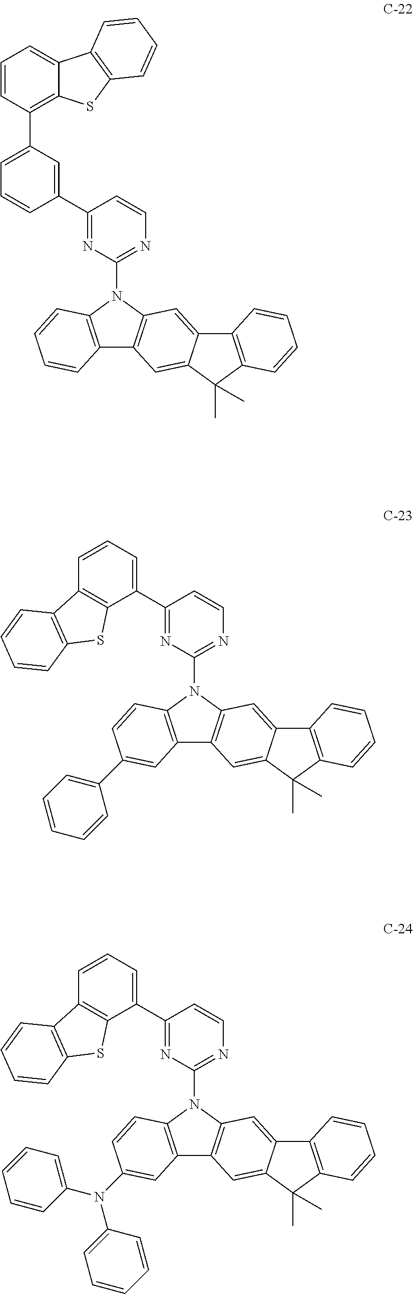 [SMILES: CC1(C)c2ccccc2-c2cc3c(cc21)c1ccccc1n3-c1nccc(-c2cccc(-c3cccc4c3sc3ccccc34)c2)n1 ; CC1(C)c2ccccc2-c2cc3c(cc21)c1cc(-c2ccccc2)ccc1n3-c1nccc(-c2cccc3c2sc2ccccc23)n1 ; CC1(C)c2ccccc2-c2cc3c(cc21)c1cc(N(c2ccccc2)c2ccccc2)ccc1n3-c1nccc(-c2cccc3c2sc2ccccc23)n1]

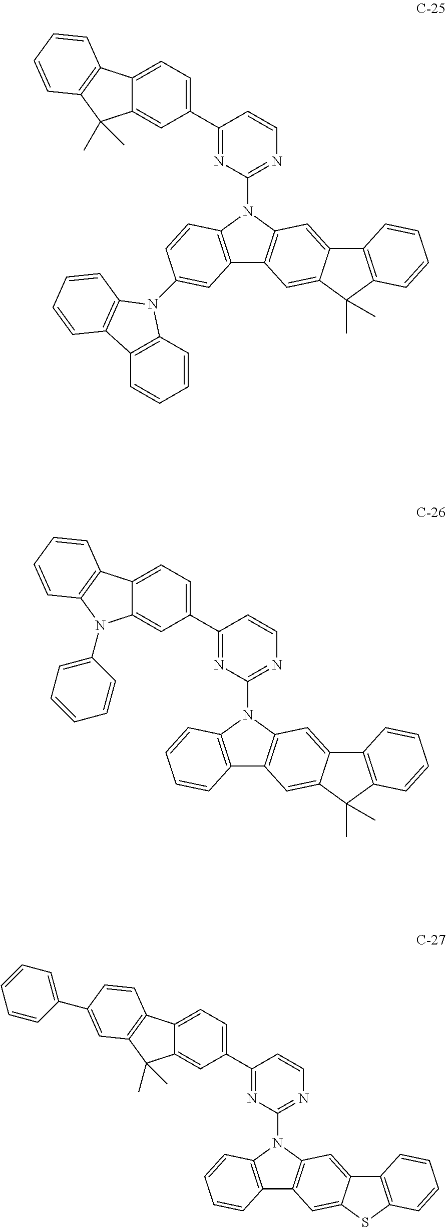 [SMILES: CC1(C)c2ccccc2-c2ccc(-c3ccnc(-n4c5ccc(-n6c7ccccc7c7ccccc76)cc5c5cc6c(cc54)-c4ccccc4C6(C)C)n3)cc21 ; CC1(C)c2ccccc2-c2cc3c(cc21)c1ccccc1n3-c1nccc(-c2ccc3c4ccccc4n(-c4ccccc4)c3c2)n1 ; CC1(C)c2cc(-c3ccccc3)ccc2-c2ccc(-c3ccnc(-n4c5ccccc5c5cc6sc7ccccc7c6cc54)n3)cc21]

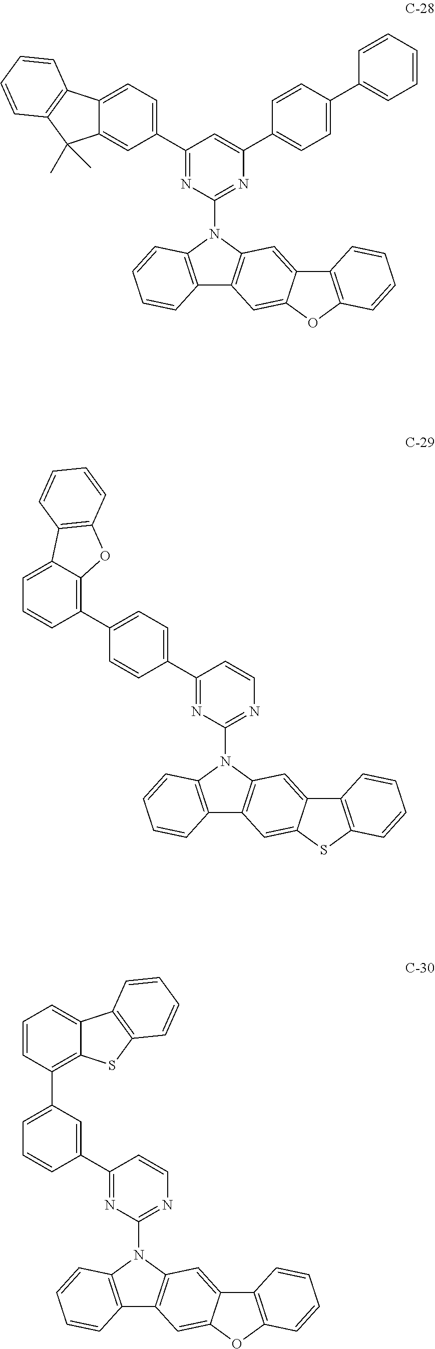 [SMILES: CC1(C)c2ccccc2-c2ccc(-c3cc(-c4ccc(-c5ccccc5)cc4)nc(-n4c5ccccc5c5cc6oc7ccccc7c6cc54)n3)cc21 ; c1ccc2c(c1)oc1c(-c3ccc(-c4ccnc(-n5c6ccccc6c6cc7sc8ccccc8c7cc65)n4)cc3)cccc12 ; c1cc(-c2ccnc(-n3c4ccccc4c4cc5oc6ccccc6c5cc43)n2)cc(-c2cccc3c2sc2ccccc23)c1]

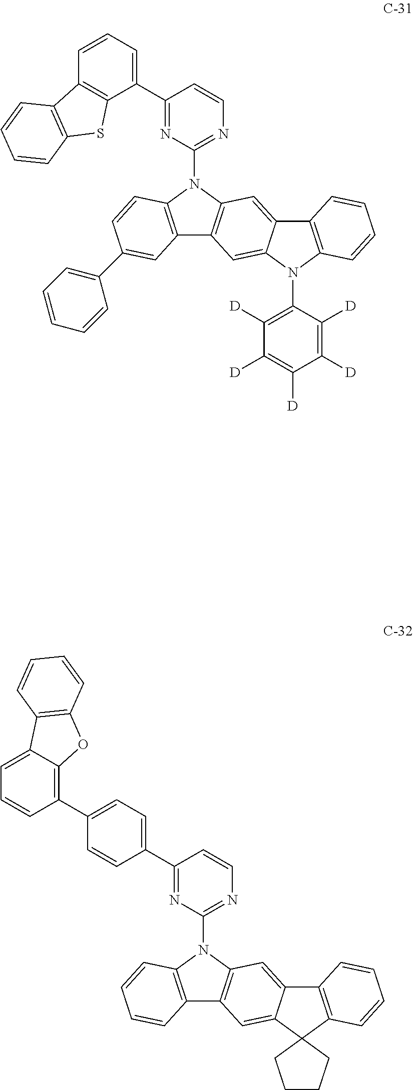 [SMILES: [2H]c1c([2H])c([2H])c(-n2c3ccccc3c3cc4c(cc32)c2cc(-c3ccccc3)ccc2n4-c2nccc(-c3cccc4c3sc3ccccc34)n2)c([2H])c1[2H] ; c1ccc2c(c1)-c1cc3c(cc1C21CCCC1)c1ccccc1n3-c1nccc(-c2ccc(-c3cccc4c3oc3ccccc34)cc2)n1]

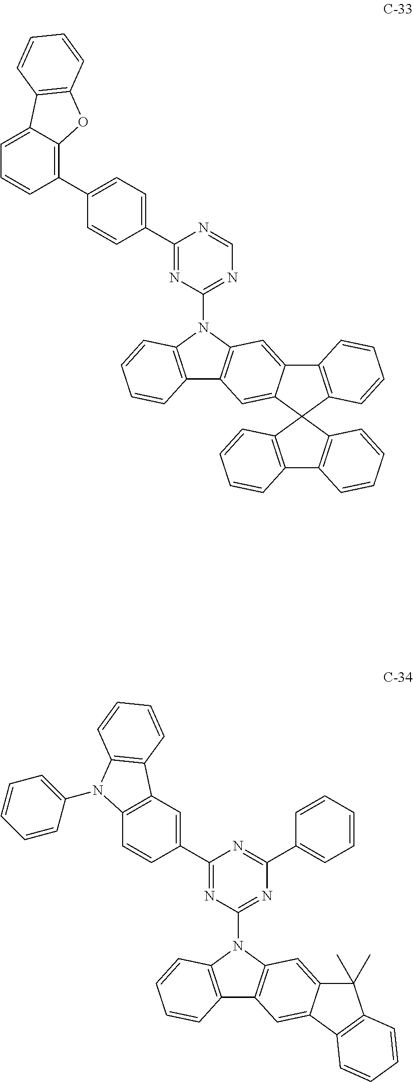 [SMILES: c1ccc2c(c1)-c1ccccc1C21c2ccccc2-c2cc3c(cc21)c1ccccc1n3-c1ncnc(-c2ccc(-c3cccc4c3oc3ccccc34)cc2)n1 ; CC1(C)c2ccccc2-c2cc3c4ccccc4n(-c4nc(-c5ccccc5)nc(-c5ccc6c(c5)c5ccccc5n6-c5ccccc5)n4)c3cc21]

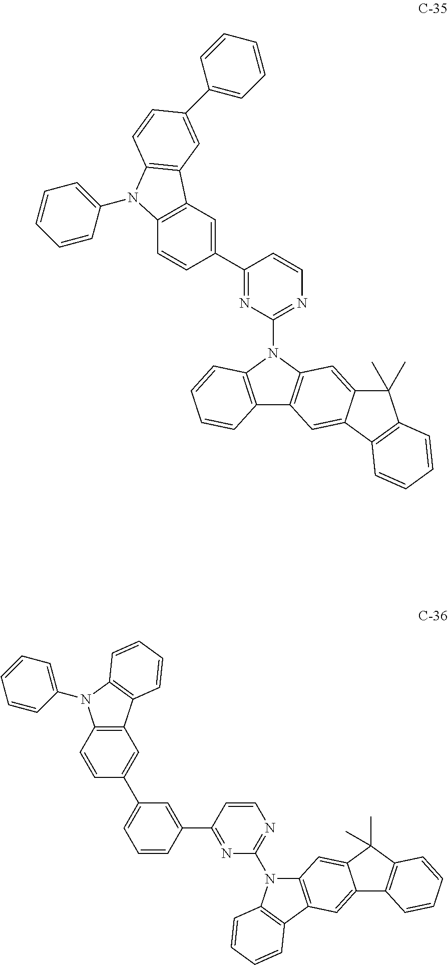 [SMILES: CC1(C)c2ccccc2-c2cc3c4ccccc4n(-c4nccc(-c5ccc6c(c5)c5cc(-c7ccccc7)ccc5n6-c5ccccc5)n4)c3cc21 ; CC1(C)c2ccccc2-c2cc3c4ccccc4n(-c4nccc(-c5cccc(-c6ccc7c(c6)c6ccccc6n7-c6ccccc6)c5)n4)c3cc21]

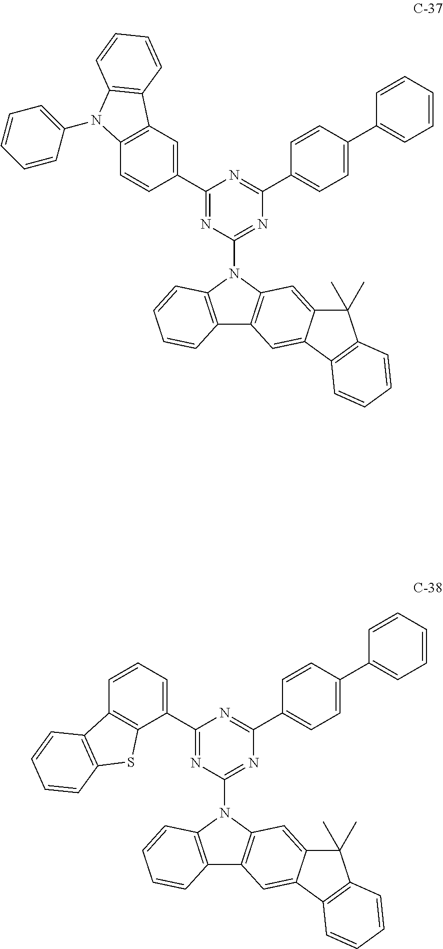 [SMILES: CC1(C)c2ccccc2-c2cc3c4ccccc4n(-c4nc(-c5ccc(-c6ccccc6)cc5)nc(-c5ccc6c(c5)c5ccccc5n6-c5ccccc5)n4)c3cc21 ; CC1(C)c2ccccc2-c2cc3c4ccccc4n(-c4nc(-c5ccc(-c6ccccc6)cc5)nc(-c5cccc6c5sc5ccccc56)n4)c3cc21]

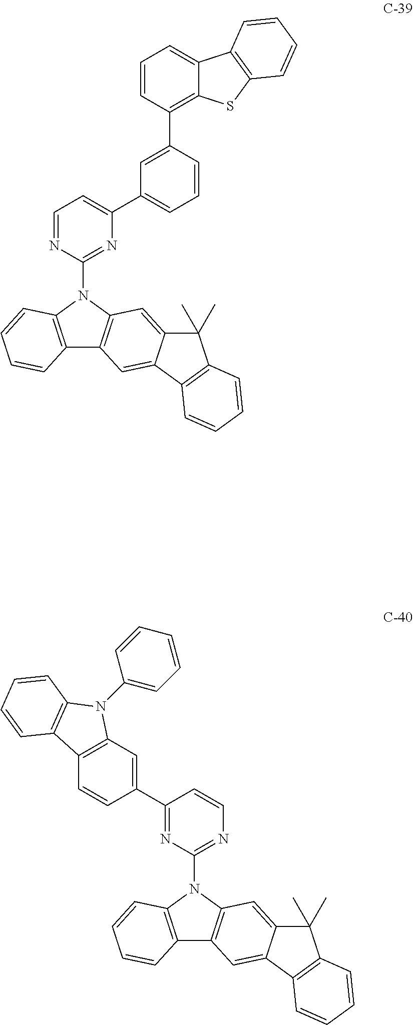 [SMILES: CC1(C)c2ccccc2-c2cc3c4ccccc4n(-c4nccc(-c5cccc(-c6cccc7c6sc6ccccc67)c5)n4)c3cc21 ; CC1(C)c2ccccc2-c2cc3c4ccccc4n(-c4nccc(-c5ccc6c7ccccc7n(-c7ccccc7)c6c5)n4)c3cc21]

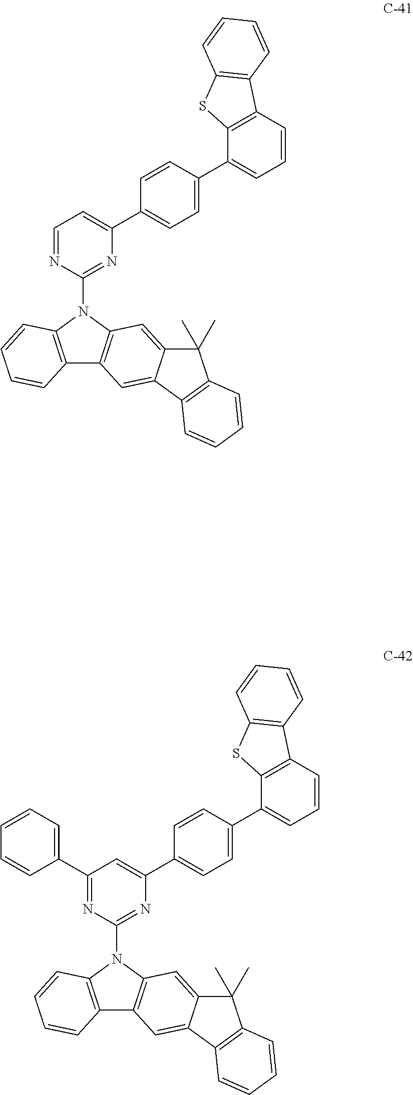 [SMILES: CC1(C)c2ccccc2-c2cc3c4ccccc4n(-c4nccc(-c5ccc(-c6cccc7c6sc6ccccc67)cc5)n4)c3cc21 ; CC1(C)c2ccccc2-c2cc3c4ccccc4n(-c4nc(-c5ccccc5)cc(-c5ccc(-c6cccc7c6sc6ccccc67)cc5)n4)c3cc21]

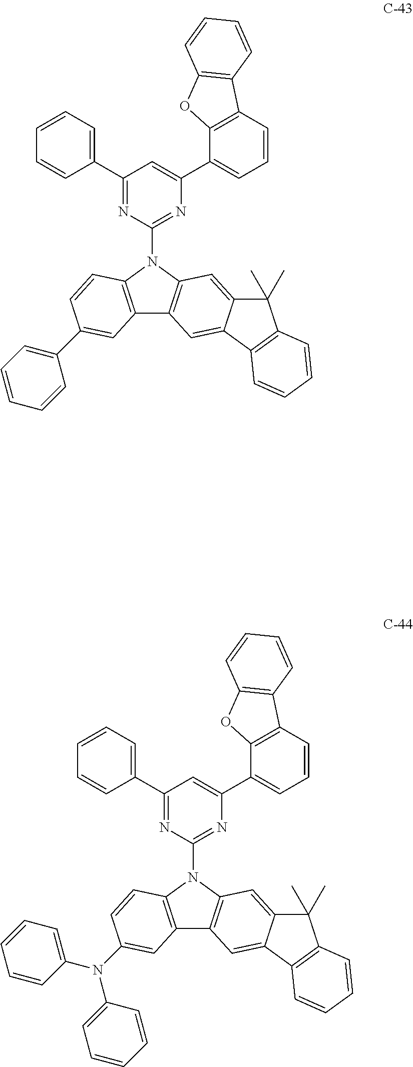 [SMILES: CC1(C)c2ccccc2-c2cc3c4cc(-c5ccccc5)ccc4n(-c4nc(-c5ccccc5)cc(-c5cccc6c5oc5ccccc56)n4)c3cc21 ; CC1(C)c2ccccc2-c2cc3c4cc(N(c5ccccc5)c5ccccc5)ccc4n(-c4nc(-c5ccccc5)cc(-c5cccc6c5oc5ccccc56)n4)c3cc21]

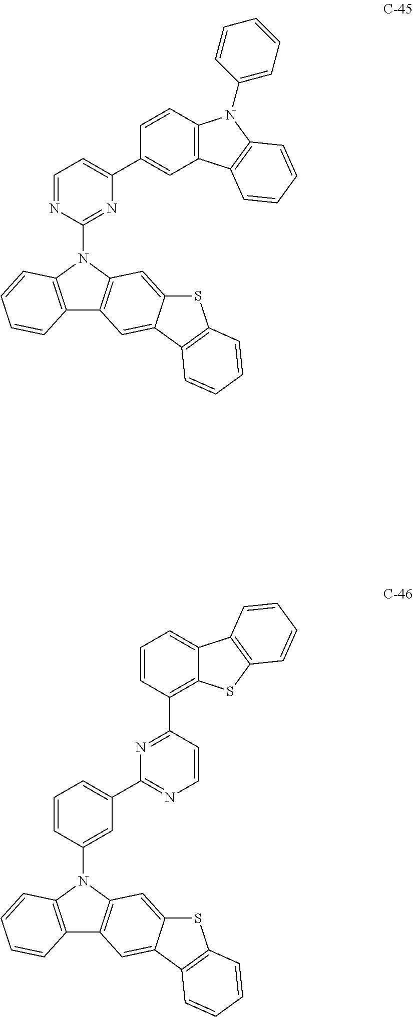 [SMILES: c1ccc(-n2c3ccccc3c3cc(-c4ccnc(-n5c6ccccc6c6cc7c(cc65)sc5ccccc57)n4)ccc32)cc1 ; c1cc(-c2nccc(-c3cccc4c3sc3ccccc34)n2)cc(-n2c3ccccc3c3cc4c(cc32)sc2ccccc24)c1]

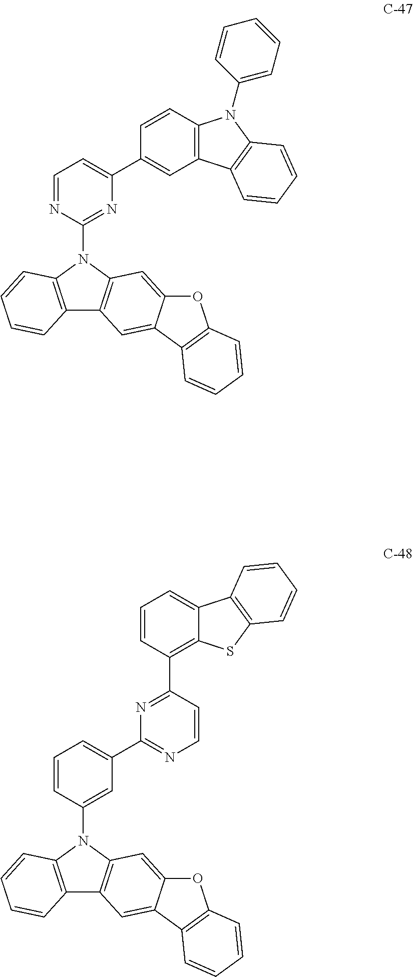 [SMILES: c1ccc(-n2c3ccccc3c3cc(-c4ccnc(-n5c6ccccc6c6cc7c(cc65)oc5ccccc57)n4)ccc32)cc1 ; c1cc(-c2nccc(-c3cccc4c3sc3ccccc34)n2)cc(-n2c3ccccc3c3cc4c(cc32)oc2ccccc24)c1]

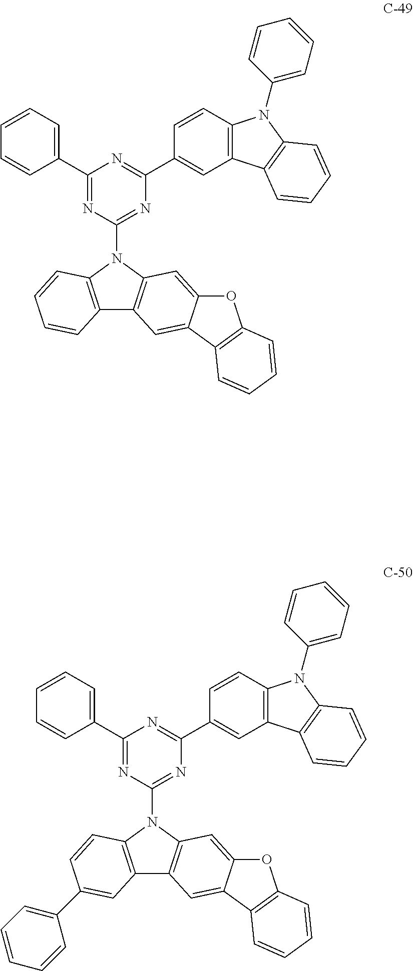 [SMILES: c1ccc(-c2nc(-c3ccc4c(c3)c3ccccc3n4-c3ccccc3)nc(-n3c4ccccc4c4cc5c(cc43)oc3ccccc35)n2)cc1 ; c1ccc(-c2ccc3c(c2)c2cc4c(cc2n3-c2nc(-c3ccccc3)nc(-c3ccc5c(c3)c3ccccc3n5-c3ccccc3)n2)oc2ccccc24)cc1]

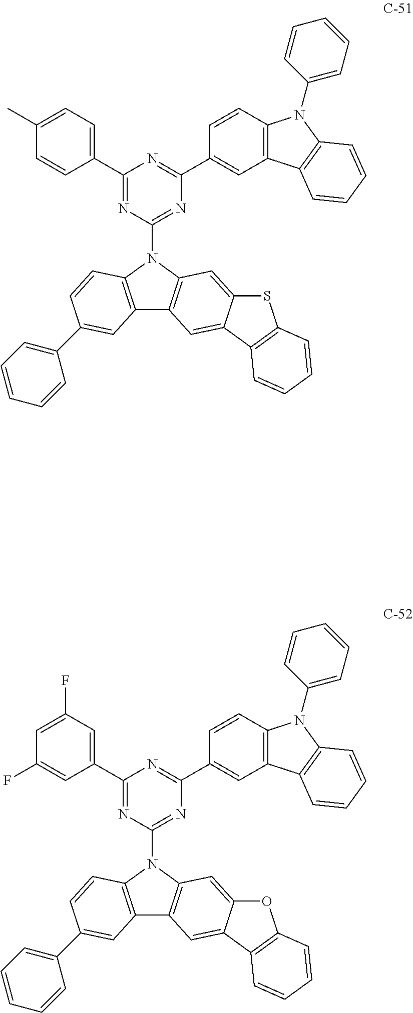 [SMILES: Cc1ccc(-c2nc(-c3ccc4c(c3)c3ccccc3n4-c3ccccc3)nc(-n3c4ccc(-c5ccccc5)cc4c4cc5c(cc43)sc3ccccc35)n2)cc1 ; Fc1cc(F)cc(-c2nc(-c3ccc4c(c3)c3ccccc3n4-c3ccccc3)nc(-n3c4ccc(-c5ccccc5)cc4c4cc5c(cc43)oc3ccccc35)n2)c1]

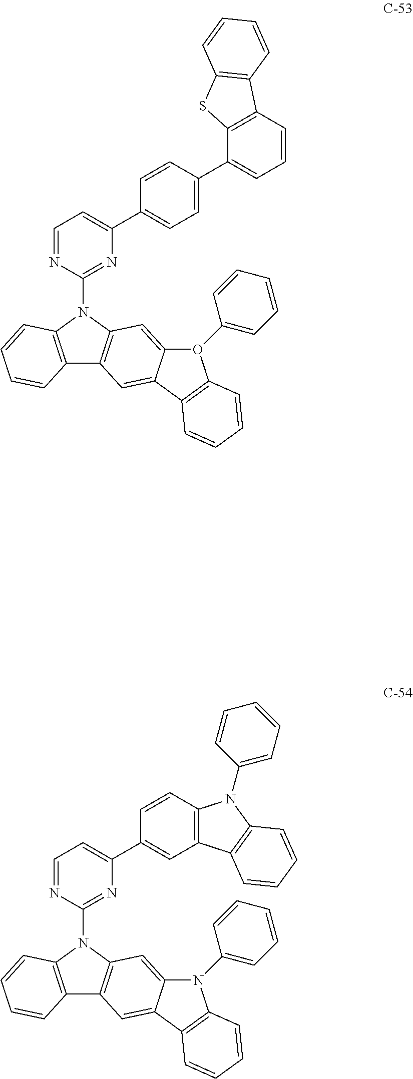

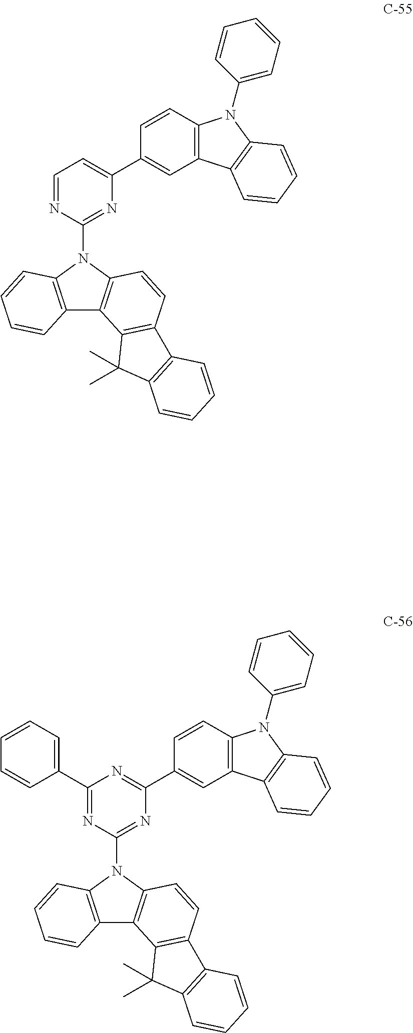 [SMILES: CC1(C)c2ccccc2-c2ccc3c(c21)c1ccccc1n3-c1nccc(-c2ccc3c(c2)c2ccccc2n3-c2ccccc2)n1 ; CC1(C)c2ccccc2-c2ccc3c(c21)c1ccccc1n3-c1nc(-c2ccccc2)nc(-c2ccc3c(c2)c2ccccc2n3-c2ccccc2)n1]

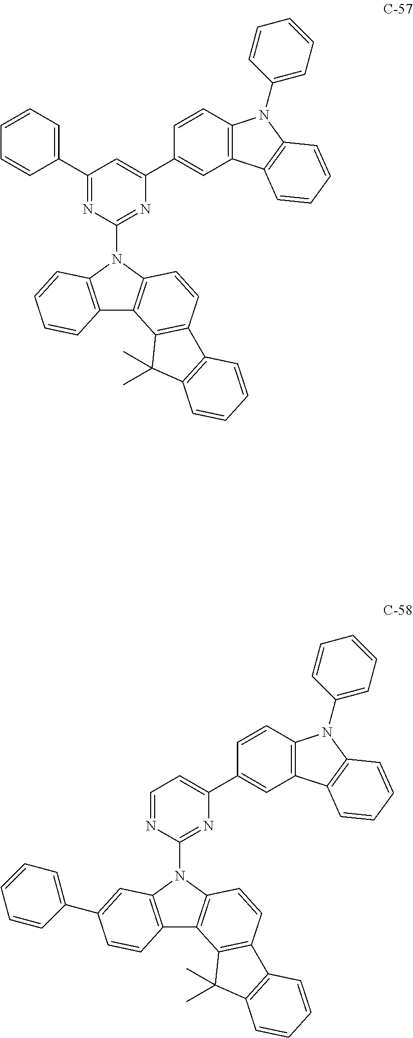 [SMILES: CC1(C)c2ccccc2-c2ccc3c(c21)c1ccccc1n3-c1nc(-c2ccccc2)cc(-c2ccc3c(c2)c2ccccc2n3-c2ccccc2)n1 ; CC1(C)c2ccccc2-c2ccc3c(c21)c1ccc(-c2ccccc2)cc1n3-c1nccc(-c2ccc3c(c2)c2ccccc2n3-c2ccccc2)n1]

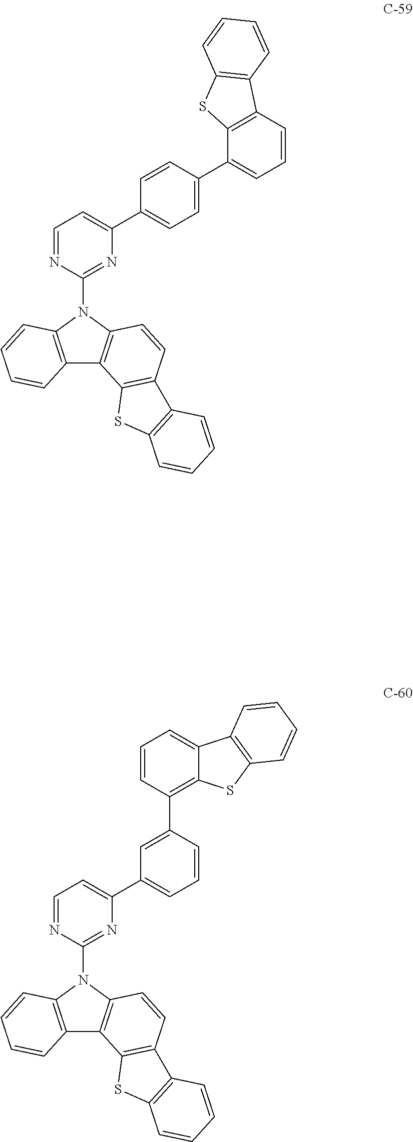 [SMILES: c1ccc2c(c1)sc1c(-c3ccc(-c4ccnc(-n5c6ccccc6c6c7sc8ccccc8c7ccc65)n4)cc3)cccc12 ; c1cc(-c2ccnc(-n3c4ccccc4c4c5sc6ccccc6c5ccc43)n2)cc(-c2cccc3c2sc2ccccc23)c1]

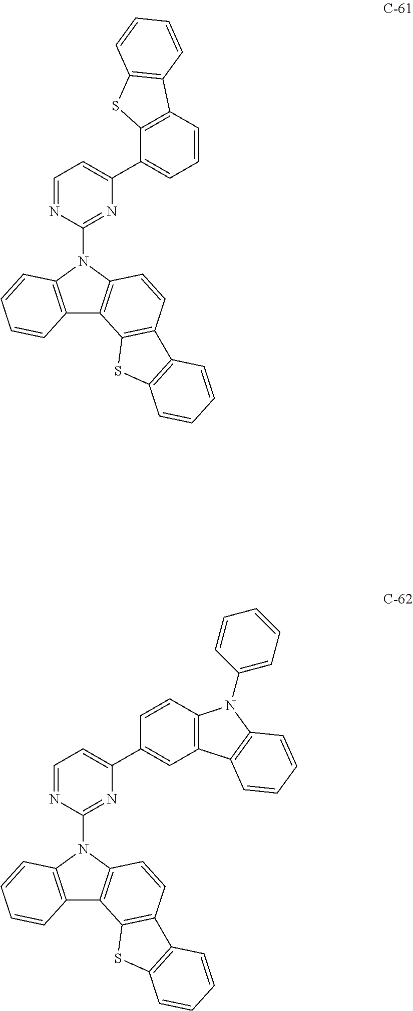 [SMILES: c1ccc2c(c1)sc1c(-c3ccnc(-n4c5ccccc5c5c6sc7ccccc7c6ccc54)n3)cccc12 ; c1ccc(-n2c3ccccc3c3cc(-c4ccnc(-n5c6ccccc6c6c7sc8ccccc8c7ccc65)n4)ccc32)cc1]

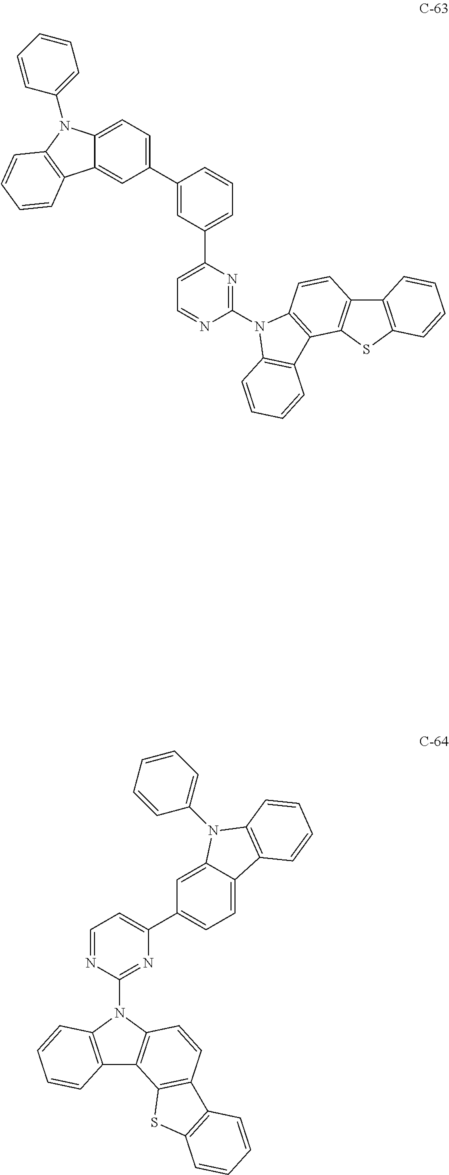 [SMILES: c1ccc(-n2c3ccccc3c3cc(-c4cccc(-c5ccnc(-n6c7ccccc7c7c8sc9ccccc9c8ccc76)n5)c4)ccc32)cc1 ; c1ccc(-n2c3ccccc3c3ccc(-c4ccnc(-n5c6ccccc6c6c7sc8ccccc8c7ccc65)n4)cc32)cc1]

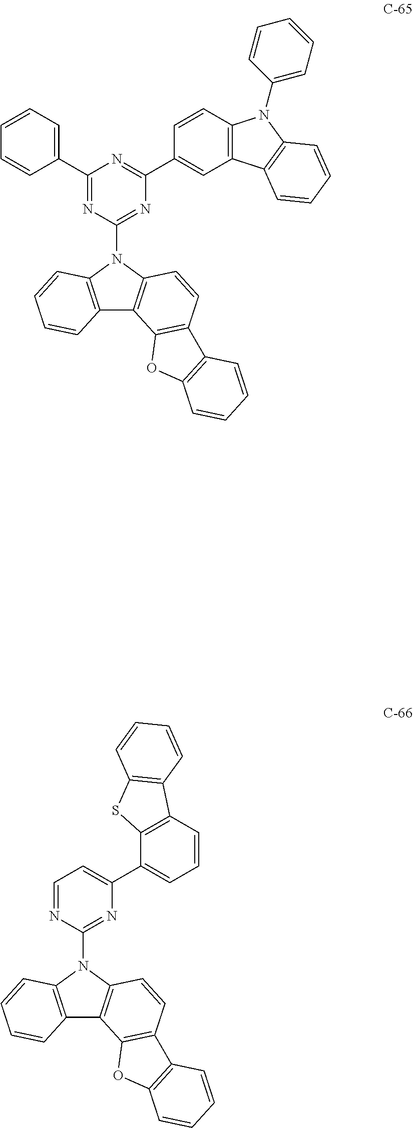 [SMILES: c1ccc(-c2nc(-c3ccc4c(c3)c3ccccc3n4-c3ccccc3)nc(-n3c4ccccc4c4c5oc6ccccc6c5ccc43)n2)cc1 ; c1ccc2c(c1)oc1c2ccc2c1c1ccccc1n2-c1nccc(-c2cccc3c2sc2ccccc23)n1]

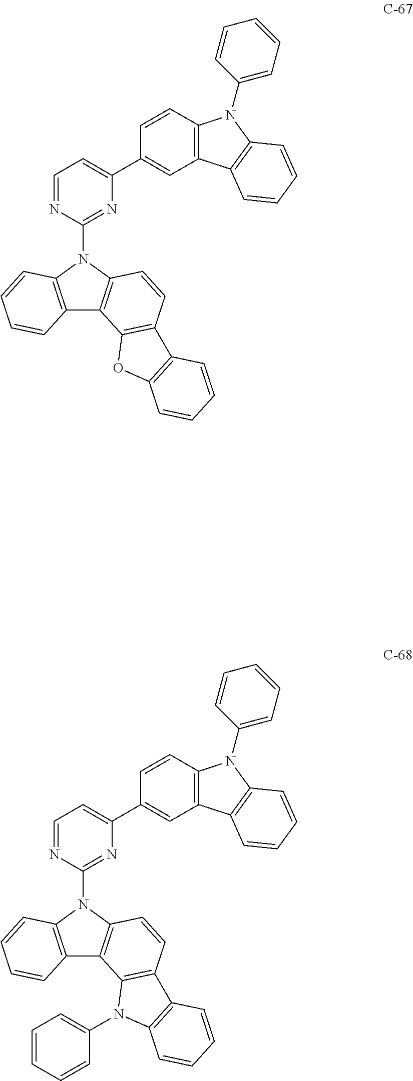 [SMILES: c1ccc(-n2c3ccccc3c3cc(-c4ccnc(-n5c6ccccc6c6c7oc8ccccc8c7ccc65)n4)ccc32)cc1 ; c1ccc(-n2c3ccccc3c3cc(-c4ccnc(-n5c6ccccc6c6c5ccc5c7ccccc7n(-c7ccccc7)c56)n4)ccc32)cc1]

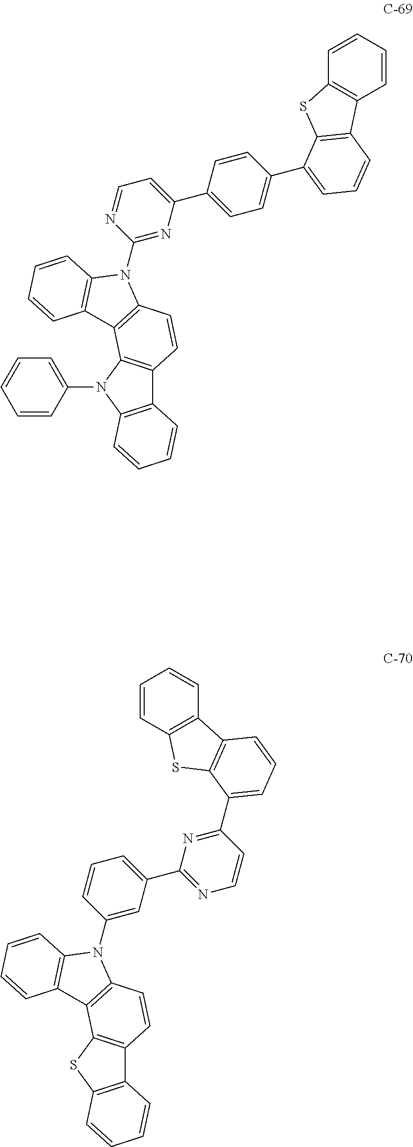 [SMILES: c1ccc(-n2c3ccccc3c3ccc4c(c5ccccc5n4-c4nccc(-c5ccc(-c6cccc7c6sc6ccccc67)cc5)n4)c32)cc1 ; c1cc(-c2nccc(-c3cccc4c3sc3ccccc34)n2)cc(-n2c3ccccc3c3c4sc5ccccc5c4ccc32)c1]

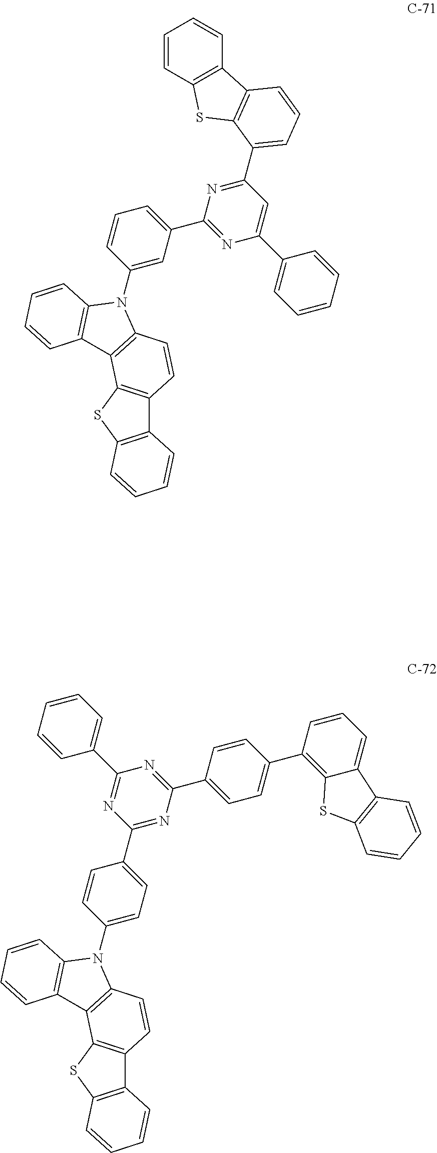 [SMILES: c1ccc(-c2cc(-c3cccc4c3sc3ccccc34)nc(-c3cccc(-n4c5ccccc5c5c6sc7ccccc7c6ccc54)c3)n2)cc1 ; c1ccc(-c2nc(-c3ccc(-c4cccc5c4sc4ccccc45)cc3)nc(-c3ccc(-n4c5ccccc5c5c6sc7ccccc7c6ccc54)cc3)n2)cc1]

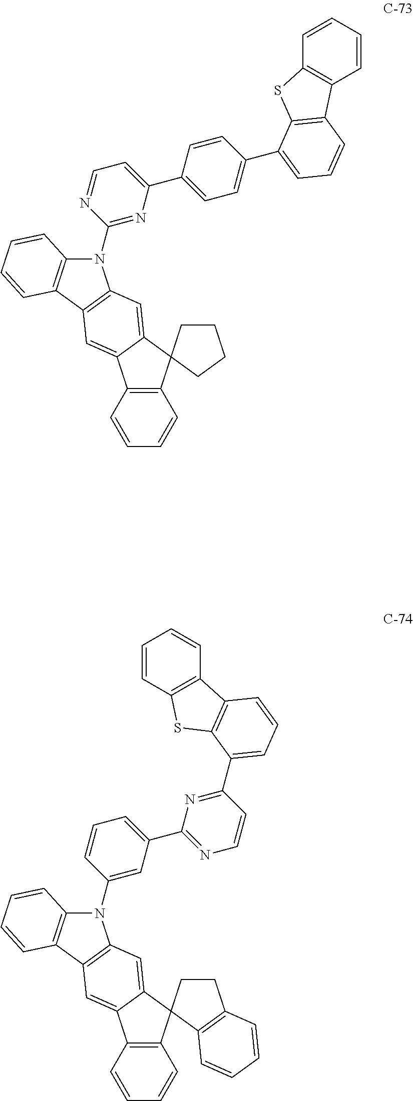 [SMILES: c1ccc2c(c1)-c1cc3c4ccccc4n(-c4nccc(-c5ccc(-c6cccc7c6sc6ccccc67)cc5)n4)c3cc1C21CCCC1 ; c1cc(-c2nccc(-c3cccc4c3sc3ccccc34)n2)cc(-n2c3ccccc3c3cc4c(cc32)C2(CCc3ccccc32)c2ccccc2-4)c1]

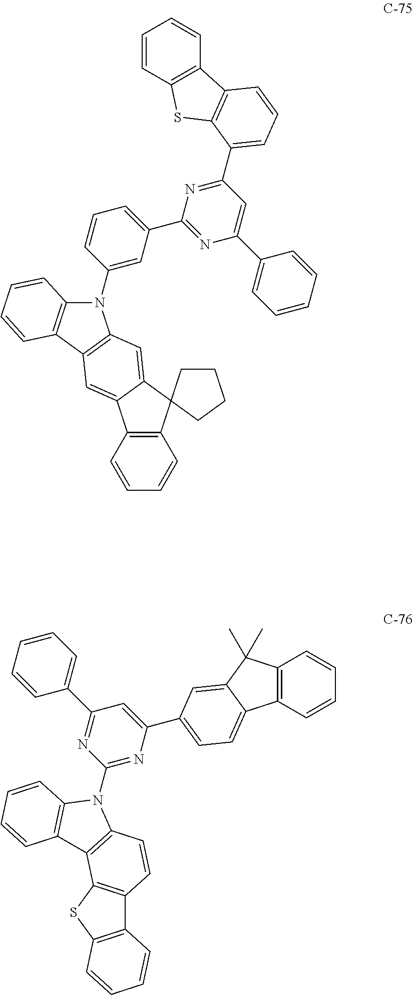 [SMILES: c1ccc(-c2cc(-c3cccc4c3sc3ccccc34)nc(-c3cccc(-n4c5ccccc5c5cc6c(cc54)C4(CCCC4)c4ccccc4-6)c3)n2)cc1 ; CC1(C)c2ccccc2-c2ccc(-c3cc(-c4ccccc4)nc(-n4c5ccccc5c5c6sc7ccccc7c6ccc54)n3)cc21]

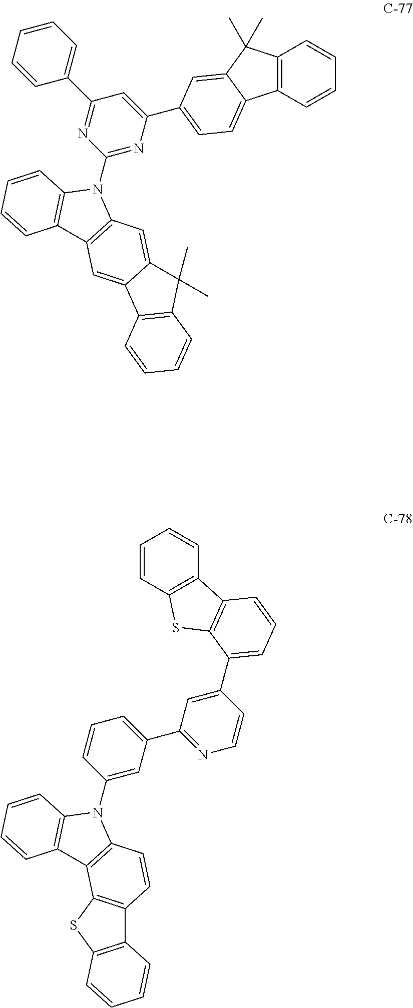 [SMILES: CC1(C)c2ccccc2-c2ccc(-c3cc(-c4ccccc4)nc(-n4c5ccccc5c5cc6c(cc54)C(C)(C)c4ccccc4-6)n3)cc21 ; c1cc(-c2cc(-c3cccc4c3sc3ccccc34)ccn2)cc(-n2c3ccccc3c3c4sc5ccccc5c4ccc32)c1]

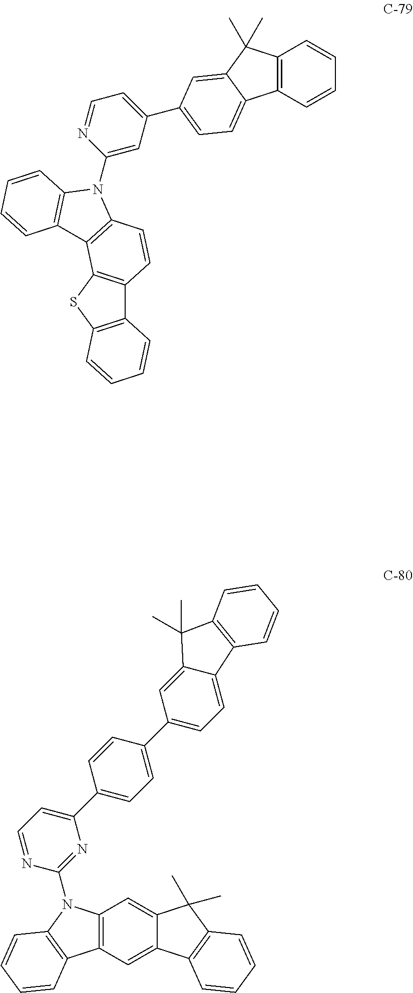 [SMILES: CC1(C)c2ccccc2-c2ccc(-c3ccnc(-n4c5ccccc5c5c6sc7ccccc7c6ccc54)c3)cc21 ; CC1(C)c2ccccc2-c2ccc(-c3ccc(-c4ccnc(-n5c6ccccc6c6cc7c(cc65)C(C)(C)c5ccccc5-7)n4)cc3)cc21]

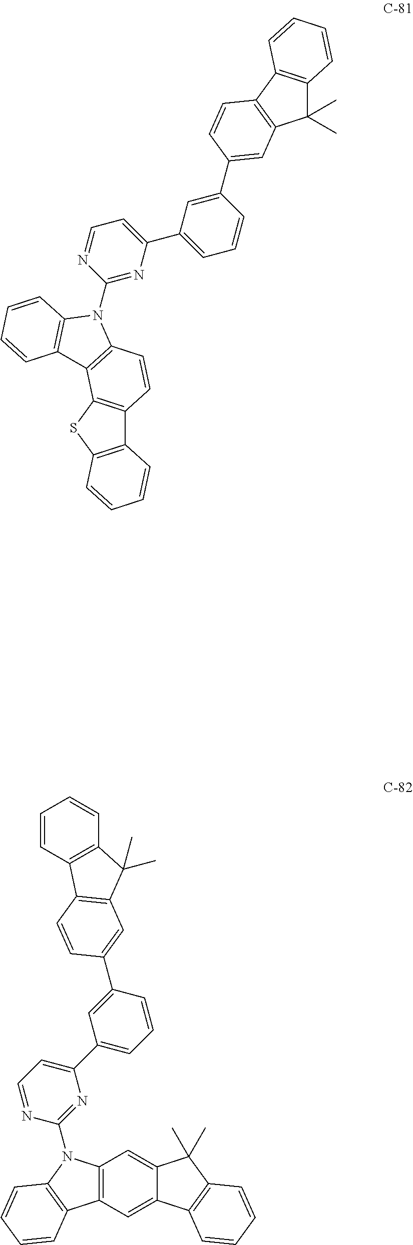 [SMILES: CC1(C)c2ccccc2-c2ccc(-c3cccc(-c4ccnc(-n5c6ccccc6c6c7sc8ccccc8c7ccc65)n4)c3)cc21 ; CC1(C)c2ccccc2-c2ccc(-c3cccc(-c4ccnc(-n5c6ccccc6c6cc7c(cc65)C(C)(C)c5ccccc5-7)n4)c3)cc21]

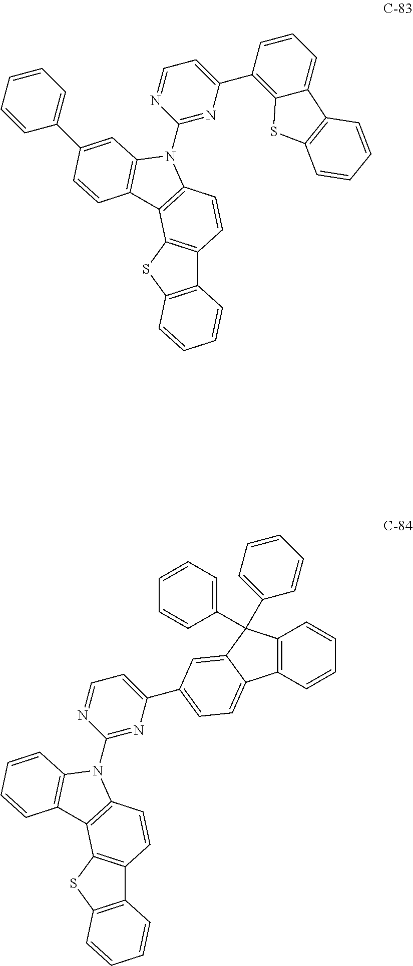 [SMILES: c1ccc(-c2ccc3c4c5sc6ccccc6c5ccc4n(-c4nccc(-c5cccc6c5sc5ccccc56)n4)c3c2)cc1 ; c1ccc(C2(c3ccccc3)c3ccccc3-c3ccc(-c4ccnc(-n5c6ccccc6c6c7sc8ccccc8c7ccc65)n4)cc32)cc1]

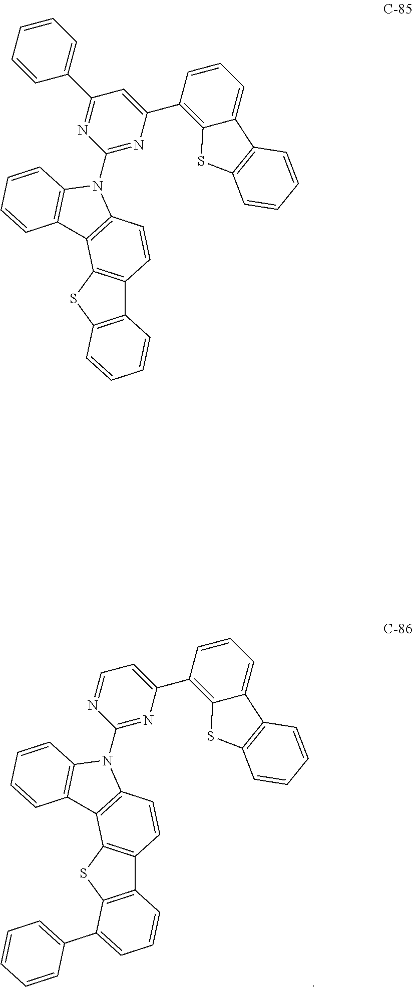 [SMILES: c1ccc(-c2cc(-c3cccc4c3sc3ccccc34)nc(-n3c4ccccc4c4c5sc6ccccc6c5ccc43)n2)cc1 ; c1ccc(-c2cccc3c2sc2c3ccc3c2c2ccccc2n3-c2nccc(-c3cccc4c3sc3ccccc34)n2)cc1]

6. An organic electroluminescent device comprising the organic electroluminescent compound according to claim 1.
